(19) United States
(12) Patent Application Publication
(10) Pub. No.: US 2017/0268095 A1
(43) Pub. Date: Sep. 21, 2017

(54) Physical vapor deposition on doublet airfoil substrates:controlling the coating thickness

(71) Applicant: University of Virginia Patent Foundation, Charlottesville, VA (US)

(72) Inventors: Haydn N.G. WADLEY, Keswick, VA (US); Theron M. RODGERS, Charlottesville, VA (US)

(21) Appl. No.: 14/999,415

(22) Filed: May 4, 2016

Related U.S. Application Data
(60) Provisional application No. 62/156,459, filed on May 4, 2015.

(51) Int. Cl. C23C 14/22; C23C 14/54

(52) U.S. Cl. CPC C23C 14/221; C23C 14/54; F01D 9/02

(57) ABSTRACT

A method and system of depositing a coating on a substrate and/or simulating depositing a coating on a substrate.

### FIELD

The present invention is directed to methods and systems of depositing coatings on curved substrates, for example, engine parts such as aircraft engine parts.

### BACKGROUND

Ongoing efforts to increase the efficiency of gas turbine engines are driving combustion gas temperatures well above the melting points of their metallic components. This has led to the adoption of thermal protection concepts that combine internal air-cooling of components with thermal barrier coating (TBC) systems to impede heat flow (and thermal damage) to the component surface. TBC systems typically consist of a metal alloy bond coat deposited on the surface of the metallic component to delay oxidation and hot corrosion, and an outer, low thermal conductivity ceramic layer.

Numerous methods have been proposed for the deposition of these coatings including liquid droplet processes such as air or vacuum plasma spray (VPS), and electron beam-physical vapor deposition (EB-PVD) concepts that create an atomically dispersed vapor plume, which is condensed on the substrate surface. More recently hybrid techniques have been also proposed including Plasma Spray-PVD (PS-PVD), which uses a high power plasma to evaporate liquid droplets in a high-pressure gas jet, and electron beam-directed vapor deposition (EB-DVD) In which an electron beam is used to evaporate a source material located in the throat of a helium gas jet forming nozzle.

The thermal protection provided by ceramic coatings, and their durability in the engine environment, are both strongly influenced by the thickness and structure of the coating. In a ceramic layer deposited by PVD, the coating thickness, pore volume fraction (porosity) and inclination of the growth columns (and pores) govern the thermal resistance. Coatings applied by one of the PVD methods are usually used for components subjected to severe thermal cycling, since they have a columnar structure leading to a low in-plane modulus (a consequence of the many intercolumnar pores oriented perpendicular to the substrate surface), and increased delamination resistance. Their expansion and contraction partially accommodates the substantial thermal strain during thermal cycling without creating stored (elastic) strain energy sufficient to drive delamination cracks. While thicker coatings could give increased thermal protection, the stored elastic strain energy in a coating is proportional to its thickness, and therefore thick coatings are subject to an increased risk of delamination. It is therefore important to balance the coating's thickness to achieve the required temperature drop without overly increasing the risk of delamination.

The pore structures in TBCs deposited by EB-PVD (and its higher-pressure, EB-DVD counterpart) occur on several length-scales: large intercolumnar pores surround typically ˜10 μm diameter growth columns, while smaller micron-scale pores, and isolated nano-scale pores exist within the columns. While the large intercolumnar pores reduce coating strain energy by accommodating mismatches in thermal expansion, the micron-scale pores provide a significant reduction in coating thermal conductivity in the heat-flux propagation direction. Nano-scale pores in many “as-deposited” coatings also reduce coating conductivity by increasing phonon scattering, but are quickly removed by sintering during operation of the engine.

A critical challenge posed by the use any of the PVD methods for TBC deposition is the requirement to deposit coatings onto complex shaped engine components such as turbine blades, vanes and nozzles. Uniform deposition with the low-pressure EB-PVD method is not possible on substrates with non-planar surfaces unless they are rotated during deposition. Sophisticated substrate translation and rotation schemes have been designed to improve the coating thickness uniformity on these components. The EB-DVD process utilizes a higher deposition chamber pressure (typically 1-45 Pa) and a gas jet to partially overcome this limitation by enabling the incident vapor to flow over the entire substrate surface; eliminating sharp coating thickness discontinuities in line-of-sight limited, low-pressure EB-PVD coatings. The EB-DVD method has been used to deposit coatings on several non-line-of-sight substrates including fibers, polymer foam templates, and stationary airfoil shaped substrates. A similar capability has been reported for the PS-PVD method, which operates with chamber pressures in the 100-1,000 Pa range.

Vapor condensation onto a non-planar substrate geometry affects both coating growth behavior during deposition and in-service performance of the ensuing coating. For example, the delamination resistance of a TBC appears to depend on the curvature of the substrate to which it is applied. Steinbrech et al. (Ceramics International 37, 363 (2011)) have shown that the lifetime of coatings applied to the outer surface of cylindrical tubes increased with the cylindrical substrate's radius. Other investigations of the failure modes of coated airfoils removed from gas turbine engines have shown the failure mode to vary with location on the airfoil surface. This arises from a complex combination of factors including; spatial variations of both the temperature and thermal stress experienced by the coating, the local substrate curvature, and the probability of impact by small or larger particles leading to erosion or foreign object damage.

The coating's thickness and structure (such as its porosity or columnar growth angle) can affect its susceptibility to these degradation mechanisms. For instance, columnar coatings containing highly inclined growth columns are thought to be more susceptible to impact damage, while those that are highly porous can better resist thermo-cyclic failure modes, but may be more vulnerable to failure by the infiltration of liquid glasses (calcium magnesium aluminum silicates) that can accumulate on the hottest regions of the airfoil. Variation of the columnar growth angle has also been found to influence the through thickness thermal resistance, as well as the rate of intercolumnar sintering, and therefore stiffening of the top coat. If methods were developed to manipulate the local coating thickness and structure over the surface of the airfoil during the coating process, it might be possible to delay some failure modes, thereby significantly extending the lifetimes of thermal barrier coatings.

A numerical simulation of coating deposition provides an efficient means of exploring the relationships between the local coating thickness, its structure and the conditions used for its deposition. In principle, molecular dynamics provides a means for this, but the computational expense is prohibitive for coatings that are typically 100 μm thick and deposited at rates of a few microns per minute. The alternatives are more computationally efficient (but more approximate) atomistic kinetic Monte Carlo (kMC) techniques, continuum-based methods such as the level-set method, or finite element based methods. Of these, only the kMC technique can address structure at both the atomic and coating thickness scales. Advanced kMC methods have been developed with built in controllers to manipulate surface roughness and site occupancy, and even account for material elasticity. An overview of these methods has been recently published.

Here we use a combination of kMC modeling for simulating atomic assembly and a direct simulation Monte Carlo (DSMC) technique for vapor transport to investigate the deposition of a coating on a model airfoil-shaped substrate. Deposition onto both stationary and rotated substrates is investigated as the background pressure, gas jet velocity (via the changes to the pressure ratio across the nozzle used for its formation) and the homologous coating temperature are varied. Experimental coatings on both stationary and rotated airfoils are also deposited to assess the validity of the modeling approach. The dependence of the local coating thickness, columnar growth angle and porosity are reported as a function of the deposition conditions, and opportunities to control the spatial variation of these parameters are discussed.

Further, the temperature limitations of materials used to make airfoils for the hottest sections of gas turbine engines have led to the development thermal management systems which incorporate interior and surface film air cooling combined with insulating (ceramic) thermal barrier coatings (TBCs). The ceramic coating is designed to contain pores that disrupt heat flow through its thickness, and for the most thermally cycled airfoils, intercolumnar pores that accommodate thermal expansion due to differences in the coefficients of thermal expansion of the coating and substrate and the presence of steep temperature gradients.

Additional efforts to improve engine efficiency by reducing the leakage of combustion gases through gaps (seams) between engine components, has led to the growing use of doublet guide vanes (where pairs of airfoils are fabricated as a single solid piece) for the first row of stator vanes directly after the combustor. Since the inner and exterior doublet surfaces are expected to experience similar in-service environments, they require similar performance defining TBC thicknesses and microstructures. However, some doublet guide vane structures have non-line-of-sight (NLS) surface regions, and cannot be coated by conventional low-pressure physical vapor deposition (PVD) processes.

In addition, many industrial coating applications require coatings to be applied to non-planar substrates. Examples include the application of thermal barrier coatings to gas turbine components, wear-resistant coatings for cutting tools, and bio-compatible coatings applied to medical implants. These applications often require relatively thick (10-100μm) coatings, which necessitates use of high deposition rate methods. These requirements have led to the development of several novel growth techniques. They range from liquid to vapor phase, and from chemical reaction based to purely physical mechanisms. Here, the potential use of an electron beam-directed vapor deposition (EB-DVD) technique is analyzed using the coating of a doublet guide vane substrate with nickel to illuminate the fundamental issues.

Numerous vapor-phase deposition methods have been used to create many categories of coating. These coating methods are valued for their high deposition rates, good coating quality, and low impurity concentrations. However, they use low deposition chamber pressures to prevent particle formation and ensure atom-by-atom coating growth. At these low pressures, vapor species travel in free flight without undergoing interparticle collisions from the evaporation source to the substrate. Even though the vapor travels in straight lines, high-vacuum (low pressure) physical vapor deposition techniques such as electron beam physical vapor deposition (EB-PVD) can deposit coatings on many complex substrate shapes by careful optimization of substrate motion and source material emission rate. However, substrates with interior surfaces, such as doublet guide vanes used to control gas flow in gas turbine engines, have regions that are hidden from sight of the vapor source at all substrate orientations. In order for vapor molecules to access these hidden regions during PVD, the mean free path (MFP) between gas molecule collisions must be smaller than the length of the opening to the inner substrate surfaces. The variation of MFP with pressure for helium at 300 K can be calculated from kinetic theory for an ideal gas,²⁶ and is shown in FIG. 37, together with characteristic lengths for several substrate types and the operating pressure ranges of several deposition methods.

Chemical-reaction based methods, including chemical vapor deposition (CVD) or atomic layer deposition (ALD), can be used when the MFP is significantly larger than the substrate's characteristic length due to the low sticking coefficient of the vapor on the substrate surface. In these methods, vapor molecules can collide with the substrate surface many times before reacting and depositing. Vapor can propagate into non-line-of-sight (NLS) regions by multiple reflections off of the substrate surface without gas-phase collisions (ballistic transport). Due to the low sticking coefficient, deposition rates are typically low for these methods. In ALD, coatings grow at a rate of ˜1-5 å per cycle, each of which takes several seconds, precluding its economical use for thick coatings. In many cases, the complex coating composition and structure also preclude the use of chemical vapor deposition approaches.

Gas jet assisted PVD methods offer the possibility of non-line-of-sight deposition while retaining the high deposition rates achievable with electron beam or sputter evaporation methods. However, these processes require careful manipulation of deposition parameters to ensure acceptable coating properties and to prevent gas-phase vapor cluster formation which increases rapidly at pressures above 60 Pa. The plasma spray-physical vapor deposition (PS-PVD) method has shown the ability to deposit TBC coatings onto model doublet guide-vane substrates similar to those used here. However, the gap between the airfoils was large enough that the substrates contained no regions that remained permanently shadowed when the substrate was rotated during deposition and the variation of coating properties with deposition conditions was not investigated. The higher chamber pressure (100-1,000 Pa) used in the PS-PVD process also increases the propensity of cluster formation, which must be managed to ensure acceptable coating microstructures.

Here we apply a recently developed atomistic simulation method to investigate the use of a directed vapor deposition approach for depositing columnar coatings on the surfaces of doublet guide vane substrates containing regions that are never in line of sight of the vapor source. The study focuses upon the thickness uniformity over these surfaces and its variation with deposition conditions including the pressure at which deposition is conducted. The study first examines the gas-phase environment near the substrate and its variation with both substrate orientation and deposition conditions. It then simulates the deposition of coatings under several conditions and compares their thickness distributions to experimental results for coatings deposited with the same conditions. Finally, the uniformity in coating thickness is investigated as the process environment is systematically changed from conditions found in high vacuum EB-PVD to high pressure PS-PVD.

### SUMMARY

The presently described subject matter is directed to a method and system of depositing coating on substrates, in particular curved substrates.

The presently described subject matter is directed to a method and system of conducting simulations of depositing coatings on complex shaped substrates such as engine component.

The presently described subject matter is directed to a method and system comprising or consisting of conducting simulations of depositing coatings on rotated substrates yielding multiple variables that subsequently govern a thickness and structure variation across the rotated substrate.

The presently described subject matter is directed to a method and system comprising or consisting of conducting simulations of depositing coatings on rotated substrates yielding multiple variables that subsequently govern a thickness and structure variation across the rotated substrate, and selecting a thickness of a coating by balancing a thickness of a coating without increasing a risk of delamination using the simulations of deposition.

The presently described subject matter is directed to a method and system comprising or consisting of conducting simulations of depositing coatings on rotated substrates yielding multiple variables that subsequently govern a thickness and structure variation across the rotated substrate, and comparing the simulations of deposition on rotated substrate with depositions performed using an electron beam-physical vapor deposition (EP-DVD) method.

The presently described subject matter is directed to a method and system comprising or consisting of conducting simulations of depositing coatings on rotated substrates yielding multiple variables that subsequently govern a thickness and structure variation across the rotated substrate, wherein simulated and experimental columnar growth angles, φ, are plotted versus position on the substrate.

The presently described subject matter is directed to a method and system of depositing coating on substrates, in particular curved substrates, further comprising controlling the deposition to locally control the thickness and microstructure of the coating deposited on the substrate.

The presently described subject matter is directed to a method and system of depositing coating on substrates, in particular curved substrates, further comprising controlling the deposition to locally control the thickness and microstructure of the coating deposited on the substrate, wherein the deposition is controlled by modifying an evaporation rate, controlling a dwell time at each substrate orientation, or controlling a standoff distance.

The presently described subject matter is directed to a method and system of depositing coating on substrates, in particular curved substrates, further comprising controlling the deposition to locally control the thickness and microstructure of the coating deposited on the substrate, wherein the evaporation rate is controlled by modulating an electron beam power.

The presently described subject matter is directed to a method and system of depositing coating on substrates, in particular curved substrates, further comprising controlling the deposition to locally control the thickness and microstructure of the coating deposited on the substrate, wherein the dwell time is controlled to provide a variable rotation rate.

The presently described subject matter is directed to a method and system of depositing coating on substrates, in particular curved substrates, further comprising controlling the deposition to locally control the thickness and microstructure of the coating deposited on the substrate, wherein the standoff distance is controlled by eccentric substrate rotation.

The presently described subject matter is directed to a method and system of depositing coating on substrates, in particular curved substrates, further comprising controlling the deposition to locally control the thickness and microstructure of the coating deposited on the substrate, wherein the deposition is controlled by rapidly varying parameters of a jet flow, including pressure ratio or gas composition.

The presently described subject matter is directed to a method and system of depositing coating on substrates, in particular curved substrates, further comprising controlling the deposition to locally control the thickness and microstructure of the coating deposited on the substrate, wherein the dwell time at specific angles of substrate rotation are varied for eliminating a difference in coating thickness between concave and convex surfaces of an airfoil substrate.

The presently described subject matter is directed to a method and system of depositing coating on substrates, in particular curved substrates, further comprising controlling the deposition to locally control the thickness and microstructure of the coating deposited on the substrate, further comprising optimizing a local coating by varying the dwell time at specific angles of airfoil rotation for eliminating the difference in coating thickness between the concave and convex surfaces of the airfoil substrate,

The presently described subject matter is directed to a method and system of depositing coating on substrates, in particular curved substrates, further comprising controlling the deposition to locally control the thickness and microstructure of the coating deposited on the substrate, wherein multiple variables including a local deposition rate and an incident angle distribution (IAD) of vapor atoms are used to control the deposition.

The presently described subject matter is directed to a method and system of simulating depositing coating on substrates, in particular curved substrates, wherein simulations of deposition on a rotated substrate is performed by sequentially combining data from a set of stationary direct simulation Monte Carlo (DSMC) simulations with substrate orientation specified by an angle α.

The presently described subject matter is directed to a method and system of simulating depositing coating on substrates, in particular curved substrates, wherein simulations of deposition on a rotated substrate is performed by sequentially combining data from a set of stationary direct simulation Monte Carlo (DSMC) simulations with substrate orientation specified by an angle α.

The presently described subject matter is directed to a method and system of simulating depositing coating on substrates, in particular curved substrates, wherein simulations of deposition on a rotated substrate is performed by sequentially combining data from a set of stationary direct simulation Monte Carlo (DSMC) simulations with substrate orientation specified by an angle α, wherein the DSMC simulations are each separated by 45° of rotation, used as input for each rotated kinetic Monte Carlo (kMC) simulation.

The presently described subject matter is directed to a method and system of conducting simulations of depositing coatings on complex shaped substrates such as engine component, including simulating a vapor deposition of the coating to permit prediction of a thickness and microstructure of a coating grown at realistic deposition rates, angle of atom impacts, and substrate temperatures.

The presently described subject matter is directed to a method and system of conducting simulations of depositing coatings on complex shaped substrates such as engine component, wherein the simulation is conducted by a kinetic Monte Carlo (kMC) method.

The presently described subject matter is directed to a method and system of conducting simulations of depositing coatings on complex shaped substrates such as engine component, wherein the simulation is conducted by a direct simulation Monte Carlo (DSMC) method.

Thermal barrier coating methods and systems consisting of a metallic bond coat and ceramic over layer are widely used to extend the life of gas turbine engine components. They are applied using either high-vacuum physical vapor deposition techniques in which vapor atoms rarely experience scattering collisions during propagation to a substrate, or by gas jet assisted (low-vacuum) vapor deposition techniques that utilize scattering from streamlines to enable non-line-of-sight deposition. Both approaches require substrate motion to coat a substrate of complex shape. Here, direct simulation Monte Carlo and kinetic Monte Carlo simulation methods are combined to simulate the deposition of a nickel coating over the concave and convex surfaces of a model airfoil, and the simulation results are compared with those from experimental depositions. The simulation method successfully predicted variations in coating thickness, columnar growth angle, and porosity during both stationary and substrate rotated deposition. It was then used to investigate a wide range of vapor deposition conditions spanning high-vacuum physical vapor deposition to low-vacuum gas jet assisted vapor deposition. The average coating thickness was found to increase initially with gas pressure reaching a maximum at a chamber pressure of 8-10 Pa, but the most uniform coating thickness was achieved under high vacuum deposition conditions. However, high vacuum conditions increased the variation in the coatings pore volume fraction over the surface of the airfoil. The simulation approach was combined with an optimization algorithm and used to investigate novel deposition concepts to locally tailor the coating thickness.

Gas jet assisted physical vapor deposition (PVD) techniques operate at higher pressures than conventional PVD processes, and have shown promise for coating complex shaped substrates including those with non-line-of-sight (NLS) surface regions. Compared to regions of the same substrate that are in line-of-sight (LS) of the vapor source, NLS regions receive a broader vapor atom incident angular distribution at a lower flux. The coatings thickness and microstructure deposited upon these two types of surface region are therefore likely to different, and this could significantly affect coating behavior. To investigate such effects, the thickness and microstructure variation along the inner (curved channel) surfaces of a model doublet airfoil substrate containing NLS regions has been investigated. Results from atomistic simulations are first compared to those of experiments, and confirm that the coating's thickness in flux-shadowed regions is thinner than other regions. They also indicated that the coatings columnar microstructure and pore volume fraction vary slowly with surface location through the LS to NLS transition zone of airfoil surface. A substrate rotation strategy for optimizing the thickness over the entire doublet airfoil surface is also investigated, and resulted in identification of process conditions that incurred a small variation of coating thickness along all doublet airfoil surfaces with only a small change to the columnar growth angle and pore volume fraction.

Until recently, physical vapor deposition methods have been limited to the coating of substrates whose surface was in line-of-site (LS) of the vapor source. Since the absence of gas-phase scattering collisions during low-pressure deposition results in straight vapor atom trajectories, attempts to use physical vapor deposition to uniformly coat shaped substrates requires complex substrate manipulation schemes. Deposition on surfaces that are never visible to the source was not possible. Gas jet assisted deposition techniques that operate at higher chamber pressures offer the promise of non-line-of-sight (NLS) deposition. A combined simulation and experimental approach is used to investigate vapor deposition onto model doublet guide vane substrates found in gas turbine engines. Particular attention is given to coatings on interior surfaces, which are only accessible through the leading and trailing openings of the doublet airfoil substrate. Deposition of nickel is simulated for several flow conditions and vane separation distances, using a direct simulation Monte Carlo method. The simulated coating thickness results are then verified with experimental depositions of nickel coatings. Coating uniformity along interior surfaces was found to be highly sensitive to deposition conditions and to the separation distance between the pair of airfoils. Coating thickness on these surfaces was also found to vary with the ratio of laminar flow distance through the inter-airfoil channel to transverse diffusion across the channel gap; a parameter which can be applied to coating of any channel-like substrate.

### BRIEF DESCRIPTION OF DRAWINGS

FIG. 1 is a schematic illustration of the model 2D airfoil substrate and the axis of rotation used for simulations and deposition experiments. During stationary deposition, the airfoil was aligned with the gas jet flow direction and for the other simulations and experiments it was rotated clockwise about the center of rotation. (All dimensions are in mm).

FIG. 2 is a schematic illustration of the deposition configuration used for simulations and experiments.

FIG. 3A is a schematic illustration and definition of the incidence angle, θ of a vapor atom relative to the local surface normal.

FIG. 3B is a schematic illustration and definition the orientation of the airfoil substrate, α relative to the jet flow axis

FIG. 3C is a graph showing an example of an incident vapor atom angle probability distribution (θₘ=20°, θ_{w}=87°) calculated by simulating jet flow near a tilted substrate (□=45°) at a chamber pressure of 22 Pa and a pressure ratio of 5.45. The distribution was recorded at a location 15 mm along the convex side of the airfoil.

FIG. 4A is a graph showing a DSMC predicted parameters of the IAD along surfaces of a stationary airfoil oriented at α=0°. Results were calculated for a chamber pressure of 22 Pa and pressure ratio of 5.45. The shaded regions were not in the line-of-sight of the vapor source.

FIG. 4B is a graph showing a DSMC predicted parameters of the IAD along surfaces of a stationary airfoil oriented at α=0°. Results were calculated for a chamber pressure of 22 Pa and pressure ratio of 5.45. The shaded regions were not in the line-of-sight of the vapor source.

FIG. 4C is a graph showing a DSMC predicted parameters of the IAD along surfaces of a stationary airfoil oriented at α=0°. Results were calculated for a chamber pressure of 22 Pa and pressure ratio of 5.45. The shaded regions were not in the line-of-sight of the vapor source.

FIG. 4D is a graph showing a DSMC predicted parameters of the IAD along surfaces of a stationary airfoil oriented at α=0°. Results were calculated for a chamber pressure of 22 Pa and pressure ratio of 5.45. The shaded regions were not in the line-of-sight of the vapor source.

FIG. 5 is a detailed cross-sectional view of the airfoil showing simulated coating microstructures at six locations on a stationary airfoil substrate. The chamber pressure was 22 Pa, the pressure ratio was 5.45, and the source evaporation rate was 8.8×10²⁰ atoms m⁻²s⁻¹. The substrate's homologous temperature, T/Tₘ=0.243, and the highest deposition rate shown (at the subplot f location) was 2.5×10²⁰ atoms m⁻²s⁻¹.

FIG. 6A is a graph showing a comparison between experimental and simulation results for a stationary airfoil (□=0°). FIG. 6A shows the simulated and experimental thickness profiles (normalized by the thickness at the origin of the concave surface).

FIG. 6B is a graph showing a comparison between experimental and simulation results for a stationary airfoil (□=0°). FIG. 6B shows the simulated and experimental thickness profiles (normalized by the thickness at the origin of the concave surface).

FIG. 6C is a graph showing a comparison between experimental and simulation results for a stationary airfoil (□=0°). FIG. 6C shows the columnar growth angles along with those predicted by the Tangent rule.

FIG. 6D is a graph showing a comparison between experimental and simulation results for a stationary airfoil (□=0°). FIG. 6D shows the columnar growth angles along with those predicted by the Tangent rule.

FIG. 6E is a graph showing a comparison between experimental and simulation results for a stationary airfoil (□=0°). FIG. 6E shows the simulated total pore volume fraction together with the intracolumnar and intercolumnar components of the total porosity.

FIG. 6F is a graph showing a comparison between experimental and simulation results for a stationary airfoil (□=0°). FIG. 6F shows the simulated total pore volume fraction together with the intracolumnar and intercolumnar components of the total porosity.

FIG. 7 is a schematic illustration of helium gas jet streamlines and pressure contours at the eight orientations used to simulate deposition onto a rotated substrate. Simulations were performed at a chamber pressure of 22 Pa and pressure ratio of 5.45.

FIG. 7A is a schematic illustration of helium gas jet streamlines and pressure contours at the eight orientations used to simulate deposition onto a rotated substrate. Simulations were performed at a chamber pressure of 22 Pa and pressure ratio of 5.45.

FIG. 7B is a schematic illustration of helium gas jet streamlines and pressure contours at the eight orientations used to simulate deposition onto a rotated substrate. Simulations were performed at a chamber pressure of 22 Pa and pressure ratio of 5.45.

FIG. 7C is a schematic illustration of helium gas jet streamlines and pressure contours at the eight orientations used to simulate deposition onto a rotated substrate. Simulations were performed at a chamber pressure of 22 Pa and pressure ratio of 5.45.

FIG. 7D is a schematic illustration of helium gas jet streamlines and pressure contours at the eight orientations used to simulate deposition onto a rotated substrate. Simulations were performed at a chamber pressure of 22 Pa and pressure ratio of 5.45.

FIG. 7E is a schematic illustration of helium gas jet streamlines and pressure contours at the eight orientations used to simulate deposition onto a rotated substrate. Simulations were performed at a chamber pressure of 22 Pa and pressure ratio of 5.45.

FIG. 7F is a schematic illustration of helium gas jet streamlines and pressure contours at the eight orientations used to simulate deposition onto a rotated substrate. Simulations were performed at a chamber pressure of 22 Pa and pressure ratio of 5.45.

FIG. 7G is a schematic illustration of helium gas jet streamlines and pressure contours at the eight orientations used to simulate deposition onto a rotated substrate. Simulations were performed at a chamber pressure of 22 Pa and pressure ratio of 5.45.

FIG. 7H is a schematic illustration of helium gas jet streamlines and pressure contours at the eight orientations used to simulate deposition onto a rotated substrate. Simulations were performed at a chamber pressure of 22 Pa and pressure ratio of 5.45.

FIG. 8 is a schematic illustration of nickel vapor atom streamlines and concentration contour plots at the eight orientations used to simulate deposition on a rotated substrate. Simulations were performed at a chamber pressure of 22 Pa and pressure ratio of 5.45.

FIG. 8A is a schematic illustration of nickel vapor atom streamlines and concentration contour plots at the eight orientations used to simulate deposition on a rotated substrate. Simulations were performed at a chamber pressure of 22 Pa and pressure ratio of 5.45.

FIG. 8B is a schematic illustration of nickel vapor atom streamlines and concentration contour plots at the eight orientations used to simulate deposition on a rotated substrate. Simulations were performed at a chamber pressure of 22 Pa and pressure ratio of 5.45.

FIG. 8C is a schematic illustration of nickel vapor atom streamlines and concentration contour plots at the eight orientations used to simulate deposition on a rotated substrate. Simulations were performed at a chamber pressure of 22 Pa and pressure ratio of 5.45.

FIG. 8D is a schematic illustration of nickel vapor atom streamlines and concentration contour plots at the eight orientations used to simulate deposition on a rotated substrate. Simulations were performed at a chamber pressure of 22 Pa and pressure ratio of 5.45.

FIG. 8E is a schematic illustration of nickel vapor atom streamlines and concentration contour plots at the eight orientations used to simulate deposition on a rotated substrate. Simulations were performed at a chamber pressure of 22 Pa and pressure ratio of 5.45.

FIG. 8F is a schematic illustration of nickel vapor atom streamlines and concentration contour plots at the eight orientations used to simulate deposition on a rotated substrate. Simulations were performed at a chamber pressure of 22 Pa and pressure ratio of 5.45.

FIG. 8G is a schematic illustration of nickel vapor atom streamlines and concentration contour plots at the eight orientations used to simulate deposition on a rotated substrate. Simulations were performed at a chamber pressure of 22 Pa and pressure ratio of 5.45.

FIG. 8H is a schematic illustration of nickel vapor atom streamlines and concentration contour plots at the eight orientations used to simulate deposition on a rotated substrate. Simulations were performed at a chamber pressure of 22 Pa and pressure ratio of 5.45.

FIG. 9 is a schematic illustration of nickel vapor particle incidence angle distributions used to simulate rotated deposition at the center of the concave side of the airfoil. Simulations were performed at a chamber pressure of 22 Pa and pressure ratio of 5.45.

FIG. 9A is a schematic illustration of nickel vapor particle incidence angle distributions used to simulate rotated deposition at the center of the concave side of the airfoil. Simulations were performed at a chamber pressure of 22 Pa and pressure ratio of 5.45.

FIG. 9B is a schematic illustration of nickel vapor particle incidence angle distributions used to simulate rotated deposition at the center of the concave side of the airfoil. Simulations were performed at a chamber pressure of 22 Pa and pressure ratio of 5.45.

FIG. 9C is a schematic illustration of nickel vapor particle incidence angle distributions used to simulate rotated deposition at the center of the concave side of the airfoil. Simulations were performed at a chamber pressure of 22 Pa and pressure ratio of 5.45.

FIG. 9D is a schematic illustration of nickel vapor particle incidence angle distributions used to simulate rotated deposition at the center of the concave side of the airfoil. Simulations were performed at a chamber pressure of 22 Pa and pressure ratio of 5.45.

FIG. 9E is a schematic illustration of nickel vapor particle incidence angle distributions used to simulate rotated deposition at the center of the concave side of the airfoil. Simulations were performed at a chamber pressure of 22 Pa and pressure ratio of 5.45.

FIG. 9F is a schematic illustration of nickel vapor particle incidence angle distributions used to simulate rotated deposition at the center of the concave side of the airfoil. Simulations were performed at a chamber pressure of 22 Pa and pressure ratio of 5.45.

FIG. 9G is a schematic illustration of nickel vapor particle incidence angle distributions used to simulate rotated deposition at the center of the concave side of the airfoil. Simulations were performed at a chamber pressure of 22 Pa and pressure ratio of 5.45.

FIG. 9H is a schematic illustration of nickel vapor particle incidence angle distributions used to simulate rotated deposition at the center of the concave side of the airfoil. Simulations were performed at a chamber pressure of 22 Pa and pressure ratio of 5.45.

FIG. 10 is a schematic illustration of simulated coating microstructures at six locations on the surface of a rotated substrate. Simulations were performed at a rotation rate of 6 rpm, a chamber pressure of 22 Pa, a pressure ratio of 5.45, a substrate temperature T/Tₘ=0.243, and an evaporation rate of 8.8×10²⁰ atoms m⁻²s⁻¹ (baseline DVD conditions).

FIG. 11 is a schematic illustration of SEM images of experimentally deposited nickel coatings at various locations on a rotated substrate. Coatings were deposited using a rotation rate of 6 rpm, a chamber pressure of 22 Pa, a pressure ratio of 5.45, and a substrate homologous temperature T/Tₘ=0.243. The 12.5 mm diameter source rod was evaporated at a rate of approximately 0.1 mm/min, which corresponds to an atomic evaporation rate of approximately 7.48×10¹⁹ atoms m⁻²s⁻¹.

FIG. 12A is a graph showing a comparison between experimental and simulation results for deposition of nickel on a rotated substrate. FIG. 12A shows the simulated and experimental thickness profiles (normalized by the thickness at the origin of the convex surface). The simulated coatings were deposited under baseline DVD conditions.

FIG. 12B is a graph showing a comparison between experimental and simulation results for deposition of nickel on a rotated substrate. FIG. 1BA shows the simulated and experimental thickness profiles (normalized by the thickness at the origin of the convex surface). The simulated coatings were deposited under baseline DVD conditions.

FIG. 12C is a graph showing a comparison between experimental and simulation results for deposition of nickel on a rotated substrate. FIG. 12C shows the columnar growth angles. The simulated coatings were deposited under baseline DVD conditions.

FIG. 12D is a graph showing a comparison between experimental and simulation results for deposition of nickel on a rotated substrate. FIG. 12D shows the columnar growth angles. The simulated coatings were deposited under baseline DVD conditions.

FIG. 12E is a graph showing a comparison between experimental and simulation results for deposition of nickel on a rotated substrate. FIG. 12E shows the simulated porosity along the surfaces, including intracolumnar and intercolumnar components of the total porosity. The simulated coatings were deposited under baseline DVD conditions.

FIG. 12F is a graph showing a comparison between experimental and simulation results for deposition of nickel on a rotated substrate. FIG. 12F shows the simulated porosity along the surfaces, including intracolumnar and intercolumnar components of the total porosity. The simulated coatings were deposited under baseline DVD conditions.

FIG. 13A is a graph showing the pore volume fractions midway along the convex airfoil surface.

FIG. 13B shows a simulated variation of coating porosity with substrate temperature for a rotated deposition (a) along with simulated microstructures at three temperatures (b-d). Depositions were performed using a chamber pressure of 22 Pa and a pressure ratio of 5.45. The data was calculated at the midpoint of the convex surface. An almost identical trend was found at the midpoint of the concave surface.

FIG. 13C shows a simulated variation of coating porosity with substrate temperature for a rotated deposition (a) along with simulated microstructures at three temperatures (b-d). Depositions were performed using a chamber pressure of 22 Pa and a pressure ratio of 5.45. The data was calculated at the midpoint of the convex surface. An almost identical trend was found at the midpoint of the concave surface.

FIG. 13D shows a simulated variation of coating porosity with substrate temperature for a rotated deposition (a) along with simulated microstructures at three temperatures (b-d). Depositions were performed using a chamber pressure of 22 Pa and a pressure ratio of 5.45. The data was calculated at the midpoint of the convex surface. An almost identical trend was found at the midpoint of the concave surface.

FIG. 14 shows the simulated microstructure for rotated deposition under PVD like conditions (a chamber pressure of 0.015 Pa, a pressure ratio of 1.0, a substrate temperature T/Tₘ=0.243, and an evaporation rate of 8.8×10²⁰ atoms m⁻²s⁻¹).

FIG. 15A is a graph showing the variation of deposition efficiency profiles (15A, and 15B), columnar growth angle (15C, and 15D), and pore fraction (15E and 15F) along the convex (left column) and concave (right column) surfaces of the airfoil for several chamber pressure conditions using a pressure ratio of 5.0. Coating depositions were simulated at a homologous temperature T/T_{M}=0.243 and a substrate rotation rate of 6 rpm.

FIG. 15B is a graph showing the variation of deposition efficiency profiles (15A, and 15B), columnar growth angle (15C, and 15D), and pore fraction (15E and 15F) along the convex (left column) and concave (right column) surfaces of the airfoil for several chamber pressure conditions using a pressure ratio of 5.0. Coating depositions were simulated at a homologous temperature T/T_{M}=0.243 and a substrate rotation rate of 6 rpm.

FIG. 15C is a graph showing the variation of deposition efficiency profiles (15A, and 15B), columnar growth angle (15C, and 15D), and pore fraction (15E and 15F) along the convex (left column) and concave (right column) surfaces of the airfoil for several chamber pressure conditions using a pressure ratio of 5.0. Coating depositions were simulated at a homologous temperature T/T_{M}=0.243 and a substrate rotation rate of 6 rpm.

FIG. 15D is a graph showing the variation of deposition efficiency profiles (15A, and 15B), columnar growth angle (15C, and 15D), and pore fraction (15E and 15F) along the convex (left column) and concave (right column) surfaces of the airfoil for several chamber pressure conditions using a pressure ratio of 5.0. Coating depositions were simulated at a homologous temperature T/T_{M}=0.243 and a substrate rotation rate of 6 rpm.

FIG. 15E is a graph showing the variation of deposition efficiency profiles (15A, and 15B), columnar growth angle (15C, and 15D), and pore fraction (15E and 15F) along the convex (left column) and concave (right column) surfaces of the airfoil for several chamber pressure conditions using a pressure ratio of 5.0. Coating depositions were simulated at a homologous temperature T/T_{M}=0.243 and a substrate rotation rate of 6 rpm.

FIG. 15E is a graph showing the variation of deposition efficiency profiles (15A, and 15B), columnar growth angle (15C, and 15D), and pore fraction (15E and 15F) along the convex (left column) and concave (right column) surfaces of the airfoil for several chamber pressure conditions using a pressure ratio of 5.0. Coating depositions were simulated at a homologous temperature T/T_{M}=0.243 and a substrate rotation rate of 6 rpm.

FIG. 16A is a graph showing the deposition efficiency at the mid-point locations on (16A) the convex and (16B) concave surfaces of the airfoil (atoms deposited divided by atoms evaporated). The figures show that coating deposition rate at the substrate midpoints was maximized at a chamber pressure of 8-10 Pa. The upstream/downstream pressure ratio only slightly influenced the amount of vapor flux received at these locations. 16C shows the ratio of the deposition efficiency (thickness) at the midpoint of the concave and convex surfaces. The coating thickness ratio decreased from unity with increasing chamber pressure.

FIG. 16B is a graph showing the deposition efficiency at the mid-point locations on (16A) the convex and (16B) concave surfaces of the airfoil (atoms deposited divided by atoms evaporated). The figures show that coating deposition rate at the substrate midpoints was maximized at a chamber pressure of 8-10 Pa. The upstream/downstream pressure ratio only slightly influenced the amount of vapor flux received at these locations. 16C shows the ratio of the deposition efficiency (thickness) at the midpoint of the concave and convex surfaces. The coating thickness ratio decreased from unity with increasing chamber pressure.

FIG. 16C is a graph showing the deposition efficiency at the mid-point locations on (16A) the convex and (16B) concave surfaces of the airfoil (atoms deposited divided by atoms evaporated). The figures show that coating deposition rate at the substrate midpoints was maximized at a chamber pressure of 8-10 Pa. The upstream/downstream pressure ratio only slightly influenced the amount of vapor flux received at these locations. 16C shows the ratio of the deposition efficiency (thickness) at the midpoint of the concave and convex surfaces. The coating thickness ratio decreased from unity with increasing chamber pressure.

FIG. 17A is a diagrammatic view showing a target coating thickness profile.

FIG. 17B is a graph showing the optimization-generated thickness profiles at two deposition conditions. (15B and 15C) show the objective and optimization procedure generated flux profiles incident upon the convex and concave surfaces. (15D and 15E) show the dwell fraction and evaporation rate sequences that came closest to achieving the objective profiles. A chamber pressure of 0.015 Pa and pressure ratio of 1.0 was used in subplots (15B) and (15E) while a chamber pressure of 22 Pa and pressure ratio of 5.45 was used for subplots (15C) and (15E). The ability to match the desired flux profile decreased with increasing chamber pressure.

FIG. 17C is a graph showing the optimization-generated thickness profiles at two deposition conditions. (15B and 15C) show the objective and optimization procedure generated flux profiles incident upon the convex and concave surfaces. (15D and 15E) show the dwell fraction and evaporation rate sequences that came closest to achieving the objective profiles. A chamber pressure of 0.015 Pa and pressure ratio of 1.0 was used in subplots (15B) and (15E) while a chamber pressure of 22 Pa and pressure ratio of 5.45 was used for subplots (15C) and (15E). The ability to match the desired flux profile decreased with increasing chamber pressure.

FIG. 17D is a graph showing the optimization-generated thickness profiles at two deposition conditions. (15B and 15C) show the objective and optimization procedure generated flux profiles incident upon the convex and concave surfaces. (15D and 15E) show the dwell fraction and evaporation rate sequences that came closest to achieving the objective profiles. A chamber pressure of 0.015 Pa and pressure ratio of 1.0 was used in subplots (15B) and (15E) while a chamber pressure of 22 Pa and pressure ratio of 5.45 was used for subplots (15C) and (15E). The ability to match the desired flux profile decreased with increasing chamber pressure.

FIG. 17E is a graph showing the optimization-generated thickness profiles at two deposition conditions. (15B and 15C) show the objective and optimization procedure generated flux profiles incident upon the convex and concave surfaces. (15D and 15E) show the dwell fraction and evaporation rate sequences that came closest to achieving the objective profiles. A chamber pressure of 0.015 Pa and pressure ratio of 1.0 was used in subplots (15B) and (15E) while a chamber pressure of 22 Pa and pressure ratio of 5.45 was used for subplots (15C) and (15E). The ability to match the desired flux profile decreased with increasing chamber pressure.

FIG. 18 is a table showing the ratio of the number of deposited to evaporate atoms on the concave, convex, leading edge and entire airfoil surface for rotated deposition at a pressure ratio of 5.0 and a standoff distance of 21 cm.

FIG. 19 is a table showing the dwell fraction during a rotation to ensure identical coating thickness on concave and convex surface mid-points for deposition at various pressures. A constant rotation rate had a dwell fraction of 0.125 of the rotation period. The dwell fraction was bounded so that the maximum rotation rate was up to 8 times the minimum at each deposition.

FIG. 20A is a schematic illustration of a model doublet guide vane substrate used for simulations and experiments.

FIG. 20B shows a definition of the channel width separating the two airfoils and the non-line of sight (NLS) region created on the inner convex surface. All dimensions are in mm.

FIG. 21A shows a definition of the incidence angle, θ of a vapor atom relative to the airfoil substrate's local surface normal, and the orientation of the substrate, a relative to the jet flow axis.

FIG. 21B is a schematic illustration of the coordinate system of the model 2D doublet airfoil substrate. During stationary deposition, the airfoil was aligned with the gas jet flow direction and for the other simulations and experiments it was rotated clockwise about the center of rotation. (All dimensions are in mm).

FIG. 22 is a schematic illustration of the source and substrate configuration used for simulation and experiment.

FIG. 23 is a graph showing the incident angle distribution (IAD) experienced on an inner concave surface region 6.36 mm from the leading edge at a substrate orientation, α=0. The chamber pressure was 16 Pa, the pressure ratio was 5, and channel width was 8 mm.

FIG. 24A is a graph showing the variation of maximum incident angle θₘ with substrate orientation along the inner convex surface. Each data point represents the average over a third of the surface's length. The results were obtained from simulations performed for a chamber pressure of 22 Pa and a pressure ratio of 5.45. The substrate's channel width was 16 mm.

FIG. 24B is a graph showing the variation of maximum incident angle θₘ with substrate orientation along the inner concave surface. Each data point represents the average over a third of the surface's length. The results were obtained from simulations performed for a chamber pressure of 22 Pa and a pressure ratio of 5.45. The substrate's channel width was 16 mm.

FIG. 24C is a graph showing the IAD full width at half maximum, θ_{w} is also shown along the inner convex and inner convex surfaces. The results were obtained from simulations performed for a chamber pressure of 22 Pa and a pressure ratio of 5.45. The substrate's channel width was 16 mm.

FIG. 24D is a graph showing the IAD full width at half maximum, θ_{w} is also shown along the inner concave surfaces. The results were obtained from simulations performed for a chamber pressure of 22 Pa and a pressure ratio of 5.45. The substrate's channel width was 16 mm.

FIG. 25 is a simulated microstructures along the inner surfaces of a doublet airfoil substrate. The coatings were deposited at a chamber pressure of 22 Pa using a pressure ratio of 5.45, a substrate homologous temperature T/Tₘ=0.243, a channel width of 16 mm.

FIG. 26 is an experimental nickel coatings deposited at a chamber pressure of 22 Pa, pressure ratio of 5.45, rotation rate of 6 rpm, and channel width of 16 mm. The substrate temperature was T/Tₘ=0.243 during deposition. The columnar growth angle is defined in (f).

FIG. 27A is a graph showing the experimental and simulated columnar growth angles along the inner doublet surfaces. Both studies were performed at a chamber pressure of 22 Pa, pressure ratio of 5.45 and channel width of 16 mm.

FIG. 27B is a graph showing the experimental and simulated columnar growth angles along the inner doublet surfaces. Both studies were performed at a chamber pressure of 22 Pa, pressure ratio of 5.45 and channel width of 16 mm.

FIG. 28A is a graph showing the variation of inner surface deposition efficiency, columnar growth angle, and pore fraction with channel width for the two interior surfaces of the doublet airfoil using a chamber pressure of 16 Pa and a pressure ratio of 5.0.

FIG. 28B is a graph showing the variation of inner surface deposition efficiency, columnar growth angle, and pore fraction with channel width for the two interior surfaces of the doublet airfoil using a chamber pressure of 16 Pa and a pressure ratio of 5.0.

FIG. 28C is a graph showing the variation of inner surface deposition efficiency, columnar growth angle, and pore fraction with channel width for the two interior surfaces of the doublet airfoil using a chamber pressure of 16 Pa and a pressure ratio of 5.0.

FIG. 28D is a graph showing the variation of inner surface deposition efficiency, columnar growth angle, and pore fraction with channel width for the two interior surfaces of the doublet airfoil using a chamber pressure of 16 Pa and a pressure ratio of 5.0.

FIG. 28E is a graph showing the variation of inner surface deposition efficiency, columnar growth angle, and pore fraction with channel width for the two interior surfaces of the doublet airfoil using a chamber pressure of 16 Pa and a pressure ratio of 5.0.

FIG. 28F is a graph showing the variation of inner surface deposition efficiency, columnar growth angle, and pore fraction with channel width for the two interior surfaces of the doublet airfoil using a chamber pressure of 16 Pa and a pressure ratio of 5.0.

FIG. 29A is a graph showing the deposition efficiency, columnar growth angle, and total pore fraction along the interior surfaces of the doublet airfoil as the chamber pressure was varied. The channel width was 12 mm and a pressure ratio of 5.0 was used for all the calculations. At 1 Pa, the mean free path became comparable to the channel width, resulting in a sudden transition of coating properties.

FIG. 29B is a graph showing the deposition efficiency, columnar growth angle, and total pore fraction along the interior surfaces of the doublet airfoil as the chamber pressure was varied. The channel width was 12 mm and a pressure ratio of 5.0 was used for all the calculations. At 1 Pa, the mean free path became comparable to the channel width, resulting in a sudden transition of coating properties.

FIG. 29C is a graph showing the deposition efficiency, columnar growth angle, and total pore fraction along the interior surfaces of the doublet airfoil as the chamber pressure was varied. The channel width was 12 mm and a pressure ratio of 5.0 was used for all the calculations. At 1 Pa, the mean free path became comparable to the channel width, resulting in a sudden transition of coating properties.

FIG. 29D is a graph showing the deposition efficiency, columnar growth angle, and total pore fraction along the interior surfaces of the doublet airfoil as the chamber pressure was varied. The channel width was 12 mm and a pressure ratio of 5.0 was used for all the calculations. At 1 Pa, the mean free path became comparable to the channel width, resulting in a sudden transition of coating properties.

FIG. 29E is a graph showing the deposition efficiency, columnar growth angle, and total pore fraction along the interior surfaces of the doublet airfoil as the chamber pressure was varied. The channel width was 12 mm and a pressure ratio of 5.0 was used for all the calculations. At 1 Pa, the mean free path became comparable to the channel width, resulting in a sudden transition of coating properties.

FIG. 29F is a graph showing the deposition efficiency, columnar growth angle, and total pore fraction along the interior surfaces of the doublet airfoil as the chamber pressure was varied. The channel width was 12 mm and a pressure ratio of 5.0 was used for all the calculations. At 1 Pa, the mean free path became comparable to the channel width, resulting in a sudden transition of coating properties.

FIG. 30A is a graph showing the incidence angle distributions at the eight simulation orientations at the inner convex surface midpoint. Simulations were performed at a pressure ratio of 5 and channel width of 12 mm.

FIG. 30B is a graph showing the incidence angle distributions at the eight simulation orientations at the inner convex surface midpoint. Simulations were performed at a pressure ratio of 5 and channel width of 12 mm.

FIG. 31 shows the simulated microstructures for coatings deposited at a chamber pressure 7.5 Pa, a pressure ratio of 5, and a channel width of 12 mm.

FIG. 32 shows the simulated coatings for depositions performed at a chamber pressure of 1 Pa, a pressure ratio of 5, and a channel width of 12 mm.

FIG. 33A is a graph showing the deposition efficiency, columnar growth angle, and total pore fraction profiles on the interior surfaces of the substrate as the pressure ratio was varied. Simulations were performed at a chamber pressure of 45 Pa and a channel width of 12 mm.

FIG. 33B is a graph showing the deposition efficiency, columnar growth angle, and total pore fraction profiles on the interior surfaces of the substrate as the pressure ratio was varied. Simulations were performed at a chamber pressure of 45 Pa and a channel width of 12 mm.

FIG. 33C is a graph showing the deposition efficiency, columnar growth angle, and total pore fraction profiles on the interior surfaces of the substrate as the pressure ratio was varied. Simulations were performed at a chamber pressure of 45 Pa and a channel width of 12 mm.

FIG. 33D is a graph showing the deposition efficiency, columnar growth angle, and total pore fraction profiles on the interior surfaces of the substrate as the pressure ratio was varied. Simulations were performed at a chamber pressure of 45 Pa and a channel width of 12 mm.

FIG. 33E is a graph showing the deposition efficiency, columnar growth angle, and total pore fraction profiles on the interior surfaces of the substrate as the pressure ratio was varied. Simulations were performed at a chamber pressure of 45 Pa and a channel width of 12 mm.

FIG. 33F is a graph showing the deposition efficiency, columnar growth angle, and total pore fraction profiles on the interior surfaces of the substrate as the pressure ratio was varied. Simulations were performed at a chamber pressure of 45 Pa and a channel width of 12 mm.

FIG. 34A is a graph showing the comparison of deposition efficiency, columnar growth angle, and total pore fraction for optimized (solid lines) and constant rotation (dashed lines) simulated deposition around a doublet substrate. The simulations were performed at a chamber pressure of 45 Pa, a pressure ratio of 5 and a separation width of 12 mm.

FIG. 34B is a graph showing the comparison of deposition efficiency, columnar growth angle, and total pore fraction for optimized (solid lines) and constant rotation (dashed lines) simulated deposition around a doublet substrate. The simulations were performed at a chamber pressure of 45 Pa, a pressure ratio of 5 and a separation width of 12 mm.

FIG. 34C is a graph showing the comparison of deposition efficiency, columnar growth angle, and total pore fraction for optimized (solid lines) and constant rotation (dashed lines) simulated deposition around a doublet substrate. The simulations were performed at a chamber pressure of 45 Pa, a pressure ratio of 5 and a separation width of 12 mm.

FIG. 34D is a graph showing the comparison of deposition efficiency, columnar growth angle, and total pore fraction for optimized (solid lines) and constant rotation (dashed lines) simulated deposition around a doublet substrate. The simulations were performed at a chamber pressure of 45 Pa, a pressure ratio of 5 and a separation width of 12 mm.

FIG. 34E is a graph showing the comparison of deposition efficiency, columnar growth angle, and total pore fraction for optimized (solid lines) and constant rotation (dashed lines) simulated deposition around a doublet substrate. The simulations were performed at a chamber pressure of 45 Pa, a pressure ratio of 5 and a separation width of 12 mm.

FIG. 34F is a graph showing the comparison of deposition efficiency, columnar growth angle, and total pore fraction for optimized (solid lines) and constant rotation (dashed lines) simulated deposition around a doublet substrate. The simulations were performed at a chamber pressure of 45 Pa, a pressure ratio of 5 and a separation width of 12 mm.

FIG. 35 shows a simulated microstructures at the four surface midpoints using the optimized rotation inputs. Simulations were performed at a chamber pressure of 45, a pressure ratio of 5, and a channel width of 12 mm.

FIG. 36 is a table showing the optimized dwell times during rotation segments for a channel width of 12 mm, chamber pressure of 45 Pa, and a pressure ratio of 5.0.

FIG. 37 is a graph showing the calculated variation of mean free path between binary collisions with helium pressure at 300 K from kinetic theory for an ideal gas. The pressure ranges of several deposition methods are indicated, along with approximate characteristic length scales of several substrate classes.

FIG. 38A is a schematic illustration of the doublet airfoil substrate geometry used in experiments and simulations. The center of its rotation was the geometric center of the encompassing rectangle that contained the doublet substrate.

FIG. 38B shows a definition of the orientation angle, a, between the substrate axis and gas jet centerline. All dimensions are in mm.

FIG. 39 is a schematic illustration of the source and substrate configuration used for simulation and experiment.

FIG. 40 is schematic illustration showing a grid used for DSMC simulations with a substrate orientation □=0°. The inlet pressure ratio was defined as the ratio of the gas inlet pressure upstream of the nozzle to that within the chamber. The cell size was iteratively refined until convergence of the jet flow was achieved.

FIG. 41 is a diagram showing the chamber pressure contour plots near the substrate with helium gas jet streamlines overlaid for a channel width of 16 mm, a chamber pressure of 22 Pa, and pressure ratio of 5.45. The gas entering the inlet nozzle had an initial temperature of 300 K. Laminar flow was maintained around the airfoils at all orientations.

FIG. 41A is a diagram showing the chamber pressure contour plots near the substrate with helium gas jet streamlines overlaid for a channel width of 16 mm, a chamber pressure of 22 Pa, and pressure ratio of 5.45. The gas entering the inlet nozzle had an initial temperature of 300 K. Laminar flow was maintained around the airfoils at all orientations.

FIG. 41B is a diagram graph showing the chamber pressure contour plots near the substrate with helium gas jet streamlines overlaid for a channel width of 16 mm, a chamber pressure of 22 Pa, and pressure ratio of 5.45. The gas entering the inlet nozzle had an initial temperature of 300 K. Laminar flow was maintained around the airfoils at all orientations.

FIG. 41C is a diagram showing the chamber pressure contour plots near the substrate with helium gas jet streamlines overlaid for a channel width of 16 mm, a chamber pressure of 22 Pa, and pressure ratio of 5.45. The gas entering the inlet nozzle had an initial temperature of 300 K. Laminar flow was maintained around the airfoils at all orientations.

FIG. 41D is a diagram showing the chamber pressure contour plots near the substrate with helium gas jet streamlines overlaid for a channel width of 16 mm, a chamber pressure of 22 Pa, and pressure ratio of 5.45. The gas entering the inlet nozzle had an initial temperature of 300 K. Laminar flow was maintained around the airfoils at all orientations.

FIG. 41E is a diagram showing the chamber pressure contour plots near the substrate with helium gas jet streamlines overlaid for a channel width of 16 mm, a chamber pressure of 22 Pa, and pressure ratio of 5.45. The gas entering the inlet nozzle had an initial temperature of 300 K. Laminar flow was maintained around the airfoils at all orientations.

FIG. 41F is a diagram showing the chamber pressure contour plots near the substrate with helium gas jet streamlines overlaid for a channel width of 16 mm, a chamber pressure of 22 Pa, and pressure ratio of 5.45. The gas entering the inlet nozzle had an initial temperature of 300 K. Laminar flow was maintained around the airfoils at all orientations.

FIG. 41G is a diagram showing the chamber pressure contour plots near the substrate with helium gas jet streamlines overlaid for a channel width of 16 mm, a chamber pressure of 22 Pa, and pressure ratio of 5.45. The gas entering the inlet nozzle had an initial temperature of 300 K. Laminar flow was maintained around the airfoils at all orientations.

FIG. 41H is a diagram showing the chamber pressure contour plots near the substrate with helium gas jet streamlines overlaid for a channel width of 16 mm, a chamber pressure of 22 Pa, and pressure ratio of 5.45. The gas entering the inlet nozzle had an initial temperature of 300 K. Laminar flow was maintained around the airfoils at all orientations.

FIG. 42 is a diagram showing the vapor atom streamlines and concentration contour plots for a substrate with a 16 mm channel width, using a chamber pressure of 22 Pa and a pressure ratio of 5.45.

FIG. 42A is a diagram showing the vapor atom streamlines and concentration contour plots for a substrate with a 16 mm channel width, using a chamber pressure of 22 Pa and a pressure ratio of 5.45.

FIG. 42B is a diagram showing the vapor atom streamlines and concentration contour plots for a substrate with a 16 mm channel width, using a chamber pressure of 22 Pa and a pressure ratio of 5.45.

FIG. 42C is a diagram showing the vapor atom streamlines and concentration contour plots for a substrate with a 16 mm channel width, using a chamber pressure of 22 Pa and a pressure ratio of 5.45.

FIG. 42D is a diagram showing the vapor atom streamlines and concentration contour plots for a substrate with a 16 mm channel width, using a chamber pressure of 22 Pa and a pressure ratio of 5.45.

FIG. 42E is a diagram showing the vapor atom streamlines and concentration contour plots for a substrate with a 16 mm channel width, using a chamber pressure of 22 Pa and a pressure ratio of 5.45.

FIG. 42F is a diagram showing the vapor atom streamlines and concentration contour plots for a substrate with a 16 mm channel width, using a chamber pressure of 22 Pa and a pressure ratio of 5.45.

FIG. 42G is a diagram showing the vapor atom streamlines and concentration contour plots for a substrate with a 16 mm channel width, using a chamber pressure of 22 Pa and a pressure ratio of 5.45.

FIG. 42H is a diagram showing the vapor atom streamlines and concentration contour plots for a substrate with a 16 mm channel width, using a chamber pressure of 22 Pa and a pressure ratio of 5.45.

FIG. 43A is a diagram showing the vapor atom streamlines and concentration contour plots for a substrate orientation α=0° as the pressure ratio (rows) and chamber pressure (columns) were independently varied.

FIG. 43B is a diagram showing the vapor atom streamlines and concentration contour plots for a substrate orientation α=0° as the pressure ratio (rows) and chamber pressure (columns) were independently varied.

FIG. 43C is a diagram showing the vapor atom streamlines and concentration contour plots for a substrate orientation α=0° as the pressure ratio (rows) and chamber pressure (columns) were independently varied.

FIG. 43D is a diagram showing the vapor atom streamlines and concentration contour plots for a substrate orientation α=0° as the pressure ratio (rows) and chamber pressure (columns) were independently varied.

FIG. 43E is a diagram showing the vapor atom streamlines and concentration contour plots for a substrate orientation α=0° as the pressure ratio (rows) and chamber pressure (columns) were independently varied.

FIG. 43F is a diagram showing the vapor atom streamlines and concentration contour plots for a substrate orientation α=0° as the pressure ratio (rows) and chamber pressure (columns) were independently varied.

FIG. 43G is a diagram showing the vapor atom streamlines and concentration contour plots for a substrate orientation α=0° as the pressure ratio (rows) and chamber pressure (columns) were independently varied.

FIG. 43H is a diagram showing the vapor atom streamlines and concentration contour plots for a substrate orientation α=0° as the pressure ratio (rows) and chamber pressure (columns) were independently varied.

FIG. 43I is a diagram showing the vapor atom streamlines and concentration contour plots for a substrate orientation α=0° as the pressure ratio (rows) and chamber pressure (columns) were independently varied.

FIG. 44A is a diagram showing the vapor atom streamlines and concentration contour plots for a substrate orientation α=0° as the channel width was varied. Simulations were performed at a chamber pressure of 16 Pa and pressure ratio of 3.

FIG. 44B is a diagram showing the vapor atom streamlines and concentration contour plots for a substrate orientation α=0° as the channel width was varied. Simulations were performed at a chamber pressure of 16 Pa and pressure ratio of 3.

FIG. 44C is a diagram showing the vapor atom streamlines and concentration contour plots for a substrate orientation α=0° as the channel width was varied. Simulations were performed at a chamber pressure of 16 Pa and pressure ratio of 3.

FIG. 45A is a diagram showing the vapor atom streamlines and concentration contour plots for a substrate orientation α=0° as the channel width was varied. Simulations were performed at a chamber pressure of 45 Pa and pressure ratio of 5.

FIG. 45B is a diagram showing the vapor atom streamlines and concentration contour plots for a substrate orientation α=0° as the channel width was varied. Simulations were performed at a chamber pressure of 45 Pa and pressure ratio of 5.

FIG. 45C is a diagram showing the vapor atom streamlines and concentration contour plots for a substrate orientation α=0° as the channel width was varied. Simulations were performed at a chamber pressure of 45 Pa and pressure ratio of 5.

FIG. 46A is a graph showing a comparison of normalized experimental and simulation thick-ness profiles along the convex and concave airfoil surfaces with a channel width of 16 mm. The chamber pressure was 22 Pa and the pressure ratio was 5.45 in (46A) and (46B), while (46C) and (46D) used a chamber pressure of 43 Pa and pressure ratio of 4.5. The substrates were rotated at a rate of 6 rpm.

FIG. 46B is a graph showing a comparison of normalized experimental and simulation thick-ness profiles along the convex and concave airfoil surfaces with a channel width of 16 mm. The chamber pressure was 22 Pa and the pressure ratio was 5.45 in (46A) and (46B), while (46C) and (46D) used a chamber pressure of 43 Pa and pressure ratio of 4.5. The substrates were rotated at a rate of 6 rpm.

FIG. 46C is a graph showing a comparison of normalized experimental and simulation thick-ness profiles along the convex and concave airfoil surfaces with a channel width of 16 mm. The chamber pressure was 22 Pa and the pressure ratio was 5.45 in (46A) and (46B), while (46C) and (46D) used a chamber pressure of 43 Pa and pressure ratio of 4.5. The substrates were rotated at a rate of 6 rpm.

FIG. 46D is a graph showing a comparison of normalized experimental and simulation thick-ness profiles along the convex and concave airfoil surfaces with a channel width of 16 mm. The chamber pressure was 22 Pa and the pressure ratio was 5.45 in (46A) and (46B), while (46C) and (46D) used a chamber pressure of 43 Pa and pressure ratio of 4.5. The substrates were rotated at a rate of 6 rpm.

FIG. 47A is a graph showing the predicted local deposition efficiency (coating thickness) profiles along the 4 substrate surfaces of doublet airfoil substrates with channel widths of 8, 12 and 16 mm. Depositions were performed for a chamber pressure of 16 Pa and pressure ratio of 5.0.

FIG. 47B is a graph showing the predicted local deposition efficiency (coating thickness) profiles along the 4 substrate surfaces of doublet airfoil substrates with channel widths of 8, 12 and 16 mm. Depositions were performed for a chamber pressure of 16 Pa and pressure ratio of 5.0.

FIG. 47C is a graph showing the predicted local deposition efficiency (coating thickness) profiles along the 4 substrate surfaces of doublet airfoil substrates with channel widths of 8, 12 and 16 mm. Depositions were performed for a chamber pressure of 16 Pa and pressure ratio of 5.0.

FIG. 47D is a graph showing the predicted local deposition efficiency (coating thickness) profiles along the 4 substrate surfaces of doublet airfoil substrates with channel widths of 8, 12 and 16 mm. Depositions were performed for a chamber pressure of 16 Pa and pressure ratio of 5.0.

FIG. 48A is a graph showing the effect of pressure ratio upon the simulated local deposition efficiency profiles along the 4 substrate surfaces. Depositions were performed at a chamber pressure of 16 Pa and for a channel width of 12 mm.

FIG. 48B is a graph showing the effect of pressure ratio upon the simulated local deposition efficiency profiles along the 4 substrate surfaces. Depositions were performed at a chamber pressure of 16 Pa and for a channel width of 12 mm.

FIG. 48C is a graph showing the effect of pressure ratio upon the simulated local deposition efficiency profiles along the 4 substrate surfaces. Depositions were performed at a chamber pressure of 16 Pa and for a channel width of 12 mm.

FIG. 48D is a graph showing the effect of pressure ratio upon the simulated local deposition efficiency profiles along the 4 substrate surfaces. Depositions were performed at a chamber pressure of 16 Pa and for a channel width of 12 mm.

FIG. 49A is a graph showing the simulated deposition efficiency profiles along the 4 substrate surfaces for several chamber pressures. Depositions were performed at a pressure ratio of 5.0 and channel width of 12 mm.

FIG. 49B is a graph showing the simulated deposition efficiency profiles along the 4 substrate surfaces for several chamber pressures. Depositions were performed at a pressure ratio of 5.0 and channel width of 12 mm.

FIG. 49C is a graph showing the simulated deposition efficiency profiles along the 4 substrate surfaces for several chamber pressures. Depositions were performed at a pressure ratio of 5.0 and channel width of 12 mm

FIG. 49D is a graph showing the simulated deposition efficiency profiles along the 4 substrate surfaces for several chamber pressures. Depositions were performed at a pressure ratio of 5.0 and channel width of 12 mm.

FIG. 50A is a graph showing the variation of vapor deposition efficiencies at the midpoints of substrate surfaces with chamber pressure and pressure ratio. Subplots (a) and (b) show the deposition efficiency at the inner surface midpoints. Subplots (c) and (d) show the ratio of deposition efficiencies at the inner and outer surface midpoints. All simulations were performed with a channel width of 12 mm.

FIG. 50B is a graph showing the variation of vapor deposition efficiencies at the midpoints of substrate surfaces with chamber pressure and pressure ratio. Subplots (a) and (b) show the deposition efficiency at the inner surface midpoints. Subplots (c) and (d) show the ratio of deposition efficiencies at the inner and outer surface midpoints. All simulations were performed with a channel width of 12 mm.

FIG. 50C is a graph showing the variation of vapor deposition efficiencies at the midpoints of substrate surfaces with chamber pressure and pressure ratio. Subplots (a) and (b) show the deposition efficiency at the inner surface midpoints. Subplots (c) and (d) show the ratio of deposition efficiencies at the inner and outer surface midpoints. All simulations were performed with a channel width of 12 mm.

FIG. 50D is a graph showing the variation of vapor deposition efficiencies at the midpoints of substrate surfaces with chamber pressure and pressure ratio. Subplots (a) and (b) show the deposition efficiency at the inner surface midpoints. Subplots (c) and (d) show the ratio of deposition efficiencies at the inner and outer surface midpoints. All simulations were performed with a channel width of 12 mm.

FIG. 51 is a schematic view of vapor concentration depletion during flow through the substrate. Under ideal conditions, the vapor concentration is depleted just before reaching the end of the channel.

FIG. 52A is a graph showing the comparison of the transverse velocity v_{T} of (a & b) carrier gas and (c & d) vapor atoms for variations in chamber pressure, location, and carrier gas species. Simulations were performed for stationary α=0° airfoil orientation with a pressure ratio of 5.0 and channel width of 12 mm.

FIG. 52B is a graph showing the comparison of the transverse velocity v_{T} of (a & b) carrier gas and (c & d) vapor atoms for variations in chamber pressure, location, and carrier gas species. Simulations were performed for stationary α=0° airfoil orientation with a pressure ratio of 5.0 and channel width of 12 mm.

FIG. 52C is a graph showing the comparison of the transverse velocity v_{T} of (a & b) carrier gas and (c & d) vapor atoms for variations in chamber pressure, location, and carrier gas species. Simulations were performed for stationary α=0° airfoil orientation with a pressure ratio of 5.0 and channel width of 12 mm.

FIG. 52D is a graph showing the comparison of the transverse velocity v_{T} of (a & b) carrier gas and (c & d) vapor atoms for variations in chamber pressure, location, and carrier gas species. Simulations were performed for stationary α=0° airfoil orientation with a pressure ratio of 5.0 and channel width of 12 mm.

FIG. 53A is a graph showing the simulated deposition efficiency profiles for constant (solid lines) and optimized (dashed lines) substrate rotation along the inner and outer surfaces. Simulations were performed at a chamber pressure of 45 Pa, a pressure ratio of 5.0, and a channel width of 12 mm.

FIG. 53B is a graph showing the simulated deposition efficiency profiles for constant (solid lines) and optimized (dashed lines) substrate rotation along the inner and outer surfaces. Simulations were performed at a chamber pressure of 45 Pa, a pressure ratio of 5.0, and a channel width of 12 mm.

FIG. 54A is a graph showing the optimized results showing the difference between the total deposition efficiency along the inner and outer convex and concave surfaces for optimized and constant dwell fraction simulations.

FIG. 54B is a graph showing the ratio of optimized to constant deposition efficiency along the inner and outer convex surfaces. All simulations were performed with a channel width of 12 mm and a pressure ratio of 5.

FIG. 55A is a graph showing the variation of total deposition difference with pressure at channel widths of (a) 8 mm, (b) 12 mm, and (c) 16 mm. Simulations were performed at a pressure ratio of 5.

FIG. 55B is a graph showing the variation of total deposition difference with pressure at channel widths of (a) 8 mm, (b) 12 mm, and (c) 16 mm. Simulations were performed at a pressure ratio of 5.

FIG. 55C is a graph showing the variation of total deposition difference with pressure at channel widths of (a) 8 mm, (b) 12 mm, and (c) 16 mm. Simulations were performed at a pressure ratio of 5.

FIG. 56 is a table showing the comparison of calculated and simulated gas jet velocities.

FIG. 57 is a table showing the midpoint deposition efficiencies along each surface at several chamber pressures. The deposition efficiency on the outer surfaces decreased with increasing chamber pressure. Depositions were performed for a pressure ratio of 5 and a channel width of 12 mm.

FIG. 58 is a table showing the optimized dwell times during rotation segments for several chamber pressures. Simulations were performed for a channel width of 12 mm and a pressure ratio of 5.0.

### DETAILED DESCRIPTION

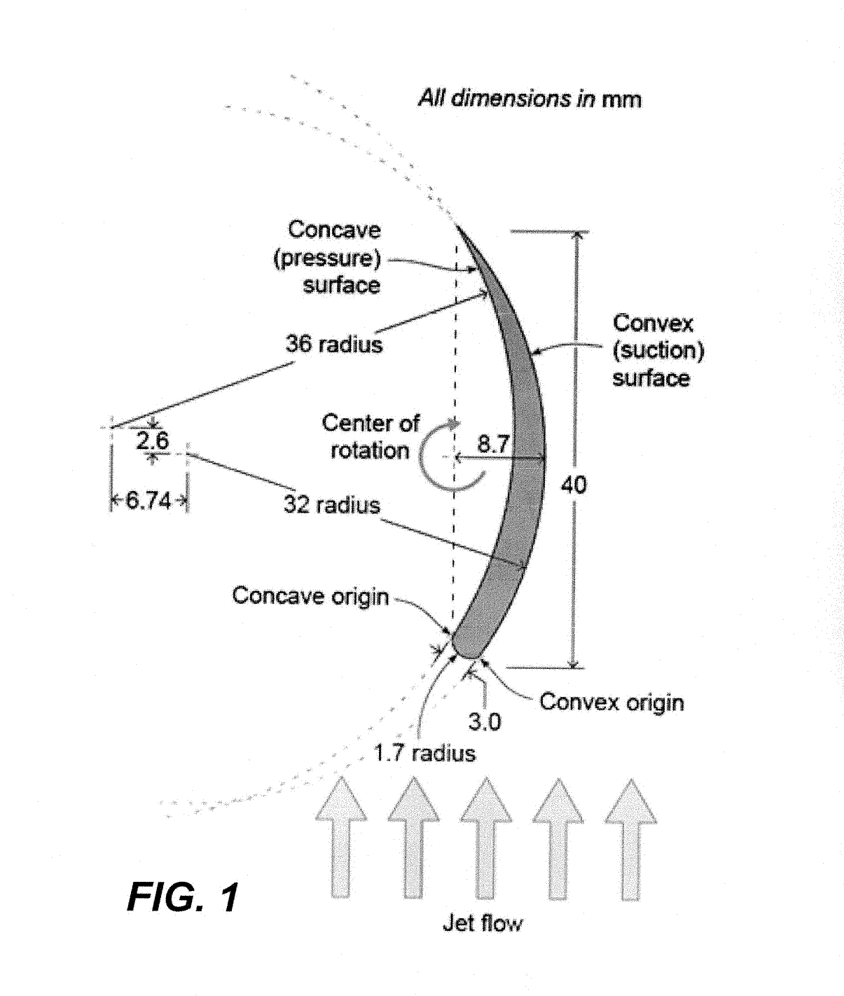

The airfoil substrate used for experimental and simulated depositions is shown in FIG. 1. The airfoil's exterior surface shape was defined by three quadratic surfaces with varying radii and centers of curvature. To allow for the use of two-dimensional simulations, the airfoil's cross-section remained constant through its thickness (i.e. it had no twist). Simulation airfoils were considered perfectly two-dimensional, while experimental airfoils had a width of 12.7 mm and were mounted to a thin backing plate during deposition. During stationary deposition, the substrate was aligned with the airfoil's chord parallel to the gas jet flow direction, and oriented with the leading edge nearest to the vapor source, as shown in FIG. 1.

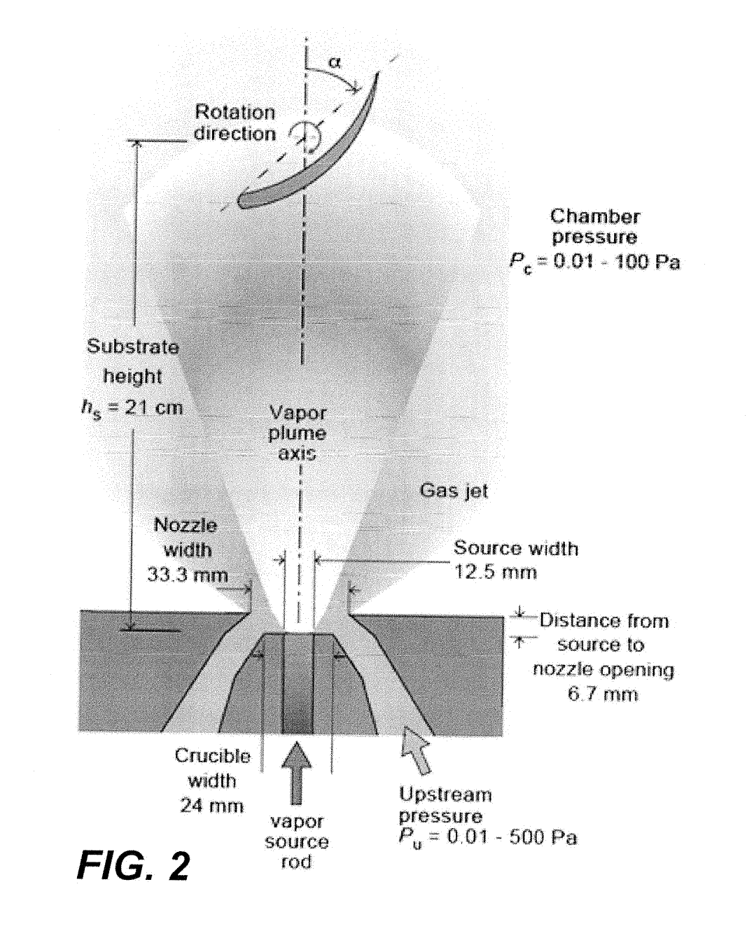

A schematic of the deposition geometry is shown in FIG. 2. The substrate was positioned in the vacuum chamber with the center of rotation located 21 cm above the center of the 12.5 mm wide vapor source. The evaporation rate of a model nickel source was set at 8.8×10 atoms m⁻²s⁻¹ for all simulations. A coaxial gas jet was formed around the vapor source by expansion of a 90 at. % He and 10 at. % O₂ gas mixture through a choked nozzle, as show in FIG. 2. The velocity of the rarefied gas jet was governed by the ratio of the gas pressure up and downstream of the nozzle, the ratio of specific heats of the gas, and its initial temperature (taken to be 300 K here).

A two-step simulation method was used to encompass the range of length and time scales relevant to the deposition process. First, the rarefied gas dynamics within a deposition chamber was simulated with a DSMC method described in detail elsewhere. The vapor species was taken to be nickel with scattering parameters calculated using the method of Venkattraman. The local nickel atom flux incident on a surface, and its incidence angle distribution (IAD) obtained from these simulations were used as the input to a 2D on-lattice kMC method, which simulated atomic assembly and growth of the coating. The kMC method used here has been previously used to simulate the vapor deposition of porous coatings and microelectronic trench filling. The method simulates the deposition of individual vapor atoms on the substrate surface and links the deposition rate to single-atom diffusional jumps between lattice sites within, or on the surface of the existing coating. The energy barriers used to determine diffusion kinetics of nickel were pre-calculated using the embedded atom method and are tabulated in Hass.

The kMC method is well suited for simulation of the vapor deposition of a coating since it is sufficiently computational efficient to permit prediction of the thickness and microstructure of a coating grown at realistic deposition rates, angle of atom impacts, and substrate temperatures. The relationship between deposition rate and surface diffusion is determined by linking the sum of all single atom diffusional jump probabilities with the vapor atom arrival rate obtained from the DSMC simulation. The probability of a diffusional jump occurring is determined by the jump attempt frequency, the activation energy of the jump and the temperature.

For a jump over a barrier with activation energy Eᵢ, the successful probability is given by:

Pᵢ=vₒe^{-E}^{_{i/kT}} (1)

where vₒ is the effective vibrational frequency of atoms in the solid (fixed at 5×10¹² s⁻¹ in this study), Eᵢ is the activation barrier for the specific jump/in Ev (tabulated in ⁴⁴), k is Boltzmann's constant in Ev/K, and T is the absolute temperature in kelvin. The simulation advances by adding (ΣPⁱ)⁻¹ to the simulation time after each jump is performed. When the elapsed simulation time is greater than the time interval between vapor atom arrivals (the inverse of the deposition rate), an additional vapor atom is added to the simulation and the cycle repeats until the desired number of atoms have been deposited.

During a simulation each occupied lattice site can possess several activation energies (and thus jump probabilities) corresponding to the different (atomic configuration dependent) diffusional pathways available to it. All possible pathways for a given lattice configuration are stored in memory, and a Monte Carlo algorithm is used to select a specific jump. The energy barrier values are stored in a binary tree to minimize computational effort when selecting a jump and updating the grid afterwards. A comprehensive discussion of the kMC procedure used here can be found in Yang (Y. Yang, The Monte Carlo Simulation of Physical Vapor Deposition, University of Virginia, 2000).

The convex and concave surfaces of the airfoil were divided into multiple independent kMC simulation regions (e.g. forty (40) independent kMC simulation regions) to allow for microstructure simulation along the entire substrate surface. Each simulation region was separated from the next (i.e. spaced apart) by a distance of 1.13 mm along the convex surface and 1.07 mm along the (shorter) concave surface. These kMC regions corresponded to the substrate surface elements used in the input DSMC simulations. Each kMC region was assigned a width of 4,000 virtual lattice sites (˜1 μm wide). To reduce variability in columnar growth, an initial substrate roughness was used for the simulations. The effects of surface asperity size, shape, and spacing on simulated coating microstructure have been quantified in previous studies. The roughness used here consisted of flat-topped pyramidal asperities with a base width of 100 atoms, a height of 75 atoms, and a spacing of 256 lattice sites between asperity midpoints.

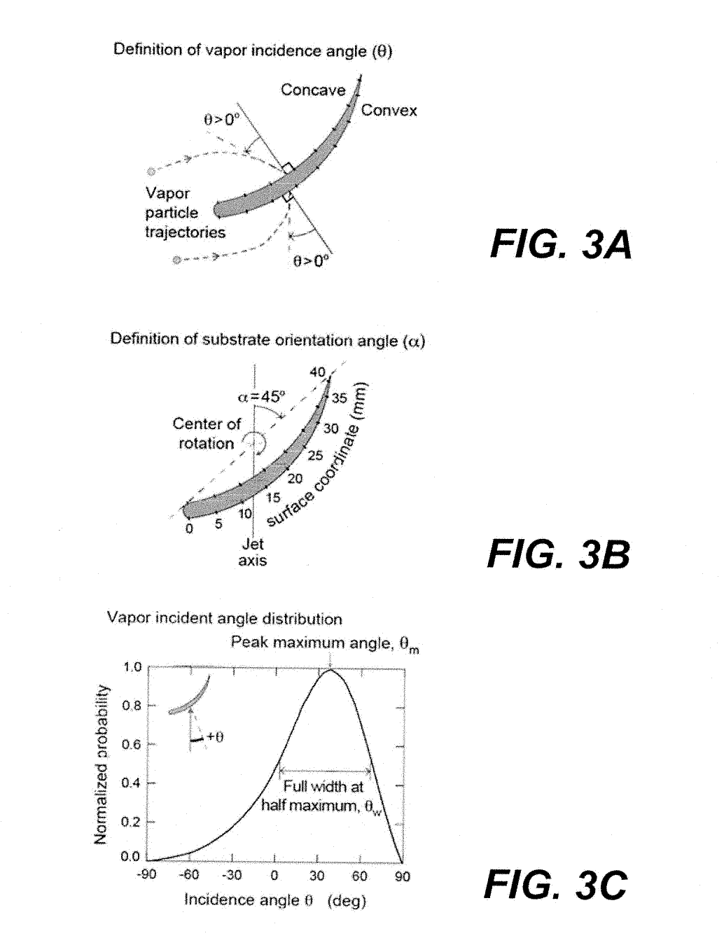

The DSMC simulations yielded two variables that subsequently govern the thickness and structure variation across the substrate: the local deposition rate and IAD of the vapor atoms. The deposition rate influences the number of diffusional jumps possible between vapor atom arrivals and the final thickness of a coating deposited in a fixed time. The IAD specifies the likelihood that an incident vapor atom impacts a substrate at a specific incidence angle, θ, measured from the local surface normal, as shown in FIG. 3A. Angles oriented towards the airfoil's leading edge were taken as positive, while those oriented towards the trailing edge were negative. Atoms arriving with similar trajectories that impact opposite sides of the substrate (convex or concave) will have θ values of identical sign. Oblique atom arrivals are susceptible to shadowing by growth surface protuberances, leading to the eventual formation of pores under conditions of insufficient thermally activated surface diffusion.

Simulations of deposition on rotated substrates were performed by sequentially combining data from a set of stationary DSMC simulations with substrate orientation specified by the angle α, as shown in FIG. 3B. Eight (8) stationary DSMC simulations, each separated by 45° of rotation, were used as input for each rotated kMC simulation. Substrate rotation was simulated by depositing a specified number of atoms (determined by the orientation-specific local deposition rate) from the IAD of each orientation. The eight orientations were cycled through until the desired total number of atoms had been deposited.

The kMC deposition rate was determined by assuming a maximum deposition rate of Dₘₐₓ=4.3 μm/min at the surface region with the highest deposition flux as calculated by DSMC. The deposition rate, D at each surface region along the remainder of the substrate was determined by normalizing the DSMC calculated fluxes by the maximum value:

D=Dₘₐₓ(f/fₘₐₓ) (2)

where f is the DSMC determined vapor flux at a surface region and fₘₐₓ is the maximum vapor flux at each orientation. When rotated deposition was simulated, D was calculated at each orientation. The total number of atoms deposited in each simulation region, N, was also scaled by the total DSMC flux:

N=Nₘₐₓ(f/fₘₐₓ) (3)

where Nₘₐₓ=9,000,000. During rotated deposition, f and fₘₐₓ were determined by summation of DSMC fluxes from all orientations.

An example of an IAD simulated at a distance 10 mm from the origin along the convex surface of a stationary airfoil is shown in FIG. 3C. The distribution is defined from the local substrate normal as shown in FIG. 3A. The IAD is typically well defined by the peak's maximum angle, θₘ, and the full width at half-maximum, θ_{w}. For a stationary deposition, the resulting coating microstructure is influenced by these two parameters. The columnar growth angle, φ, (which is defined identically to θ) is closely aligned (but smaller in magnitude) to θₘ. Coating porosity is influenced by both θ_{w} and θₘ as shadowing of the incident vapor increases with IAD width and incident angle. During substrate rotation, the local IAD constantly changed, and coating structure depended on the sequence in which atoms were deposited, not simply a time-averaged IAD.

The simulations were performed first using baseline DVD conditions consisting of a chamber pressure of 22 Pa, a pressure ratio of 5.45 and a substrate homologous temperature T/Tₘ=0.243 (where Tₘ is the absolute melting temperature of the deposited material, in this case nickel). The effects of varying these three baseline parameters were then systematically explored. When substrate rotation was modeled, the incident atom flux was scaled to simulate a rotation rate of 6 rpm. This was achieved by using the input variables from each orientation for a simulation time of 1.25 seconds and then advancing to the next orientation. Once simulations were completed, the columnar growth angles were measured by applying a Hough transformation to renderings of the simulation microstructure. The pore volume fraction was determined by measuring the fraction of occupied lattice sites in the inner 80% of the coating's thickness. The outer boundary was excluded to avoid spurious porosity from column tip roughness.

To test the validity of the simulation approach, experimental depositions were performed using the EB-DVD method. Nickel coatings were deposited onto grade 303 stainless steel substrates shaped by wire-cut electric discharge machining. The substrates surface was roughened before deposition by grit blasting. Both rotated and stationary depositions were performed for approximately 70 minutes. Rotated substrate depositions were performed at 6 rpm. The coatings were deposited without substrate heating. However, heat radiated from the electron beam's interaction with the vapor source resulted in a substrate temperature of 150° C., which corresponds to a homologous temperature, T/Tₘ=0.243; the same as that used during simulations. After deposition, the samples were cross-section, polished, and imaged in a scanning electron microscope (SEM) to determine their thickness and local columnar growth angle.

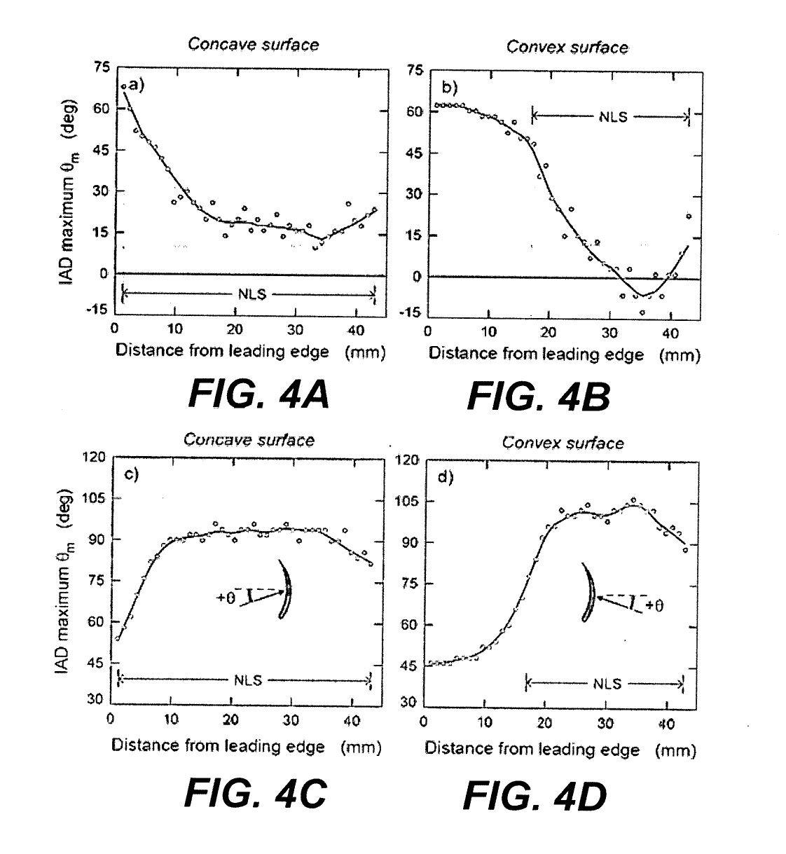

As indicated in FIG. 3C, two key parameters of an IAD are the location of the distribution's maximum (θₘ) and the distribution's full width at half maximum (θ_{w}). The variation of both parameters for deposition using the baseline EB-DVD conditions (a chamber pressure of 22 Pa, a pressure ratio of 5.45 and a substrate temperature T/T_{M}=0.243) is shown in FIGS. 4A-4D. The variation in maximum angle along the concave and convex surfaces is shown in FIGS. 4A and 4B, respectively. The change in full width at half maximum along the concave and convex surfaces is shown in subplots 4C and 4D, respectively. The plots show that the IAD varied significantly between line-of-sight regions near the airfoil's leading edge and the highly shadowed regions found closer to the trailing edge. In near line-of-sight regions (distance from leading edge <20 mm), the IAD was narrow with θₘ close to the incident angle of the carrier gas flow. Deposition in these regions was highly influenced by the carrier gas flow field.

In highly shadowed regions (substrate distance>20 mm on both surfaces), the IAD was broad with a maximum angle close to the local surface normal. Vapor atoms deposited in this region had undergone multiple scattering collisions with the background gas and made impact with the substrate from a wide range of incident angles, including from directions that were opposite to the flow direction of the carrier gas. Deposition in these regions was weakly correlated with the local carrier gas flow properties. These non-line-of-sight (NLS) substrate regions had much lower deposition rates than the line-of-sight areas, with vapor atom arrivals the result of substantial gas phase diffusion transverse to the flow direction.

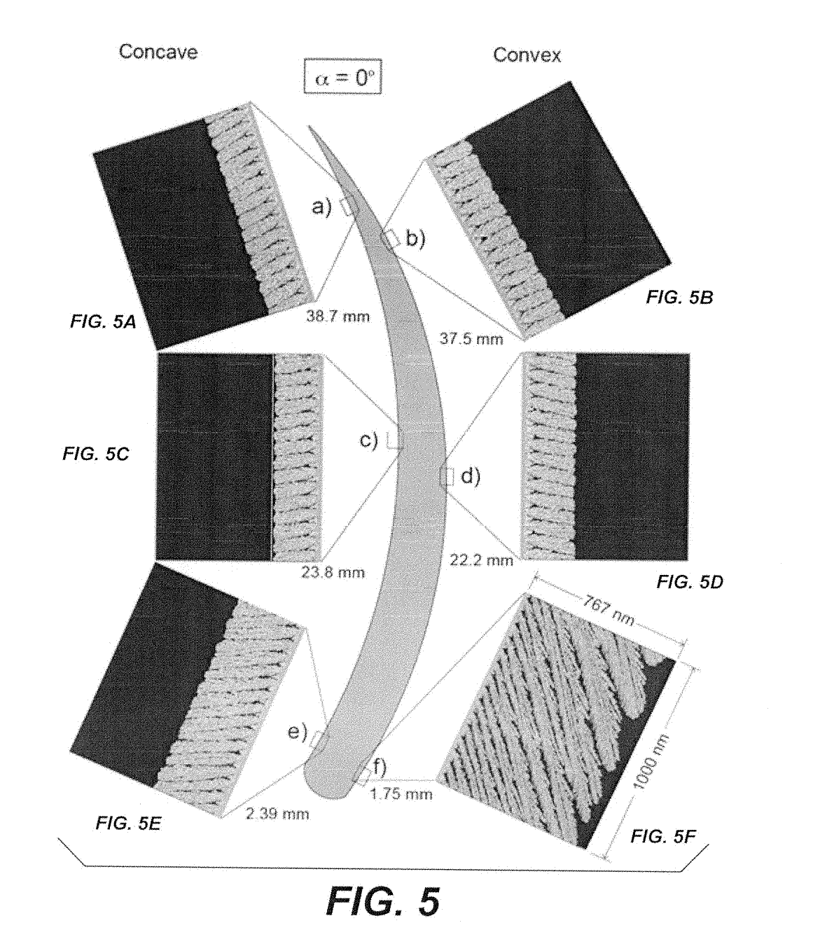

The kMC simulations were initially performed for a stationary substrate oriented at α=0°, using the baseline deposition conditions. FIG. 5 shows the thickness and structure of coatings that were deposited at six (6) representative locations on the airfoil under these conditions. It is evident that the coating had a significant variation in both its thickness and structure along each surface. Reduced, but significant vapor deposition occurred on NLS regions as shown in an earlier study of the same problem.

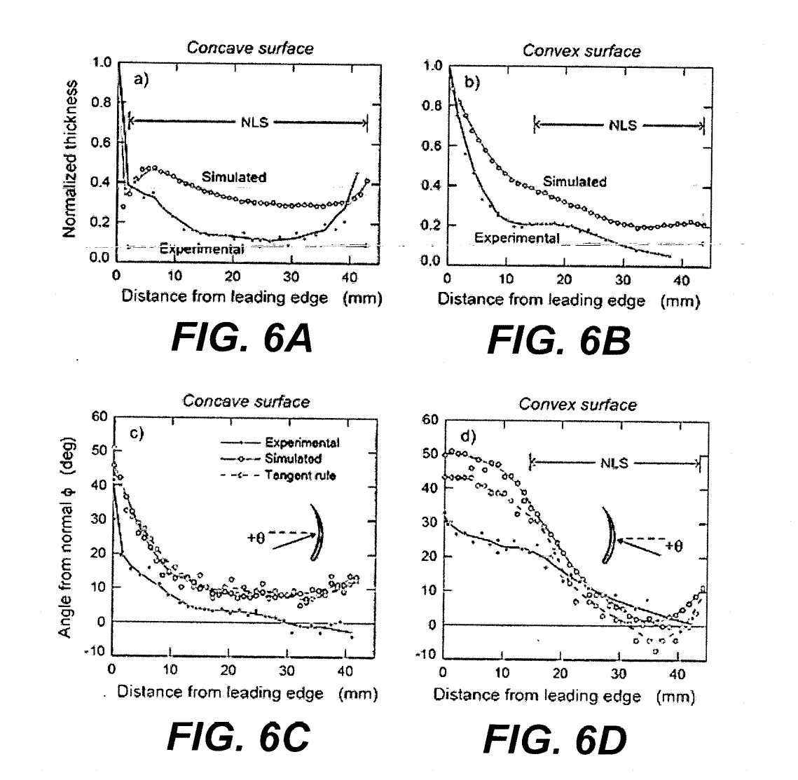

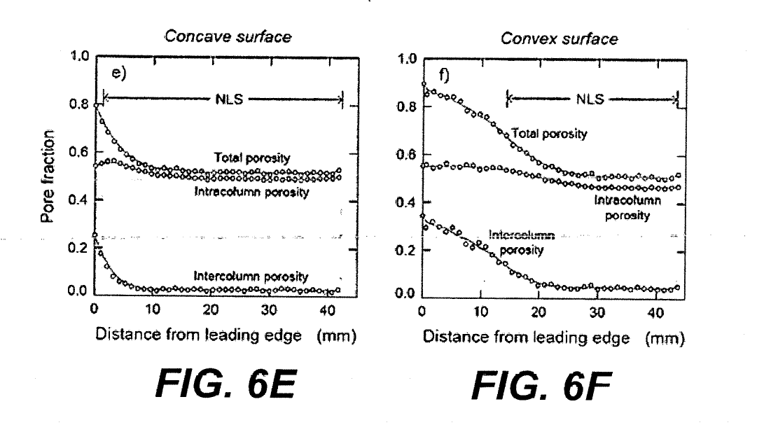

The simulated and experimental coating thickness, columnar growth angle, and pore volume fraction along the entire substrate surface are shown in FIGS. 6A-6F for the concave (left column) and convex (right column) surfaces of a stationary airfoil. The variation in simulated and experimental thickness along the concave and convex surfaces of the airfoil is shown in FIGS. 6A and 6B. The thickest coating on each surface was formed at the leading edge, as vapor was quickly depleted (by deposition) from the carrier gas streamlines that traveled closest to the stationary substrate surfaces. The concave surface shows an increased thickness near the trailing edge; a consequence of this section of substrate curving back into less vapor depleted regions of the carrier gas jet stream.

The simulated and experimental columnar growth angles, φ, are plotted versus position on the airfoil in FIGS. 6C and 6D for both surfaces. Near the leading edge of both surfaces, the coating had a feathery appearance due to nucleation of secondary growth columns, as shown in FIGS. 5E and 5F. The primary intercolumnar pores at these leading edge locations were oriented towards the leading edge. However, the magnitude of this angle gradually decreased along the surface, and eventually approached the local surface normal. In NLS regions such as (a-d) in FIG. 5, the columnar growth angles were smaller as the highly scattered vapor atoms were deposited with a broad range of incident angles.

Measurement of the columnar growth angle in experimentally deposited coatings gave orientation results with significant scatter; a consequence of the substrate's long wavelength surface roughness which caused local variation of the surface normal. The estimated standard deviation of the measured angle was 5°. Examination of FIGS. 6A-6D show that the simulation predicted column angles agreed reasonably with experimental values (to within ˜10° on the concave surface), as shown in FIG. 6C, and beyond a distance of ˜15 mm from the leading edge, as shown in FIG. 6D. However, the simulated growth angles were ˜20° higher than the experimentally measured values on the convex surface near the airfoil's leading edge. Recent work has shown that for highly-inclined incident angles, the instantaneous IAD experienced at the coating surface after formation of the feathery structure is significantly different to that experienced at the substrate surface during initial deposition. Improved simulation accuracy might be obtained in future simulations by using an IAD defined by the angle with the instantaneous column surface as the coating develops. Fortunately, these large growth angles do not develop on rotated substrates, and as shown below, the simulations were then better behaved.

The columnar inclination angle, φ, formed on flat substrates by condensation of a collimated, monoangular flux with an incident angle, θ can often be well fitted by a Tangent rule ⁵² given by:

2 tan φ=tan(θ). (4)

Using the IAD peak angle, θₘ for θ, the Tangent rule prediction has been plotted on FIGS. 6C and 6D, and correctly predicts that growth columns are tilted in the direction of the incident flux but with a columnar growth angle of smaller magnitude than the incidence angle. The Tangent rule growth column angle was found to agree reasonably with kMC simulations. It has been found that the predictive accuracy of the Tangent rule also decreases as the magnitude of the incidence angle increases beyond 70°. Several more complex empirical and semi-empirical approaches have been attempted, but no universal empirical approach has been successfully proposed for high incident angle fluxes.

The coating porosity was determined from the kMC simulations as function of location along the substrate surfaces, as shown in FIGS. 6E and 6F. The plots show the total pore fraction, the small length scale intracolumnar porosity and larger intercolumnar porosity. Along both surfaces, porosity is greatest at the leading edge and gradually decreases along the surface before reaching near-constant values in NLS surface regions. The total porosity variation results from changes to the intercolumnar porosity, as the width of the intercolumnar pores decreased with distance along the substrate surfaces. To understand these observations, it is helpful to examine the jet flow and vapor atom concentrations near the airfoil.

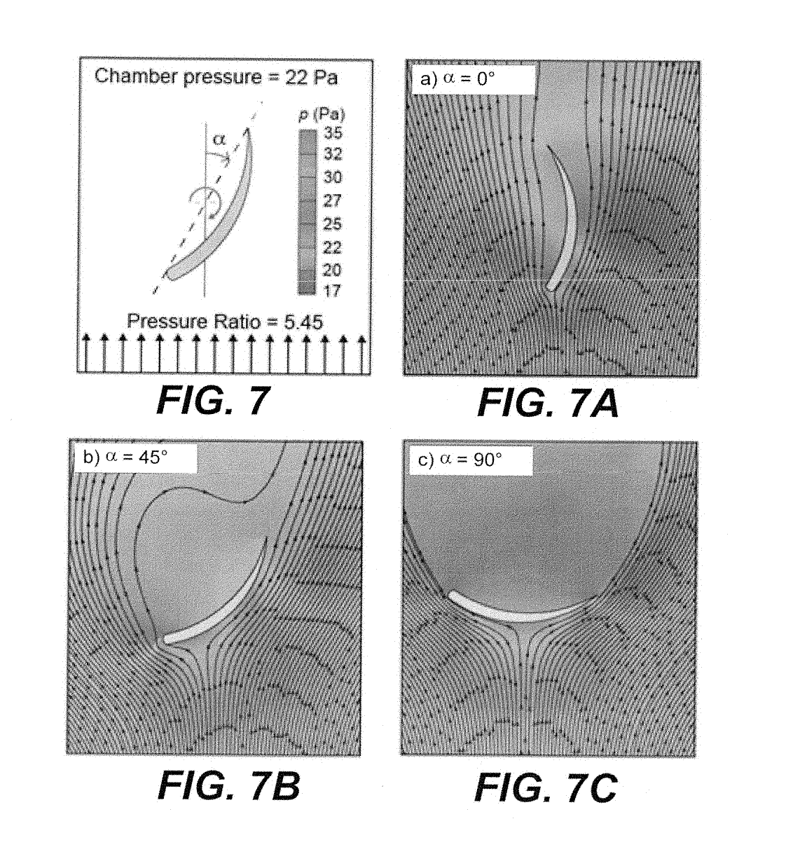

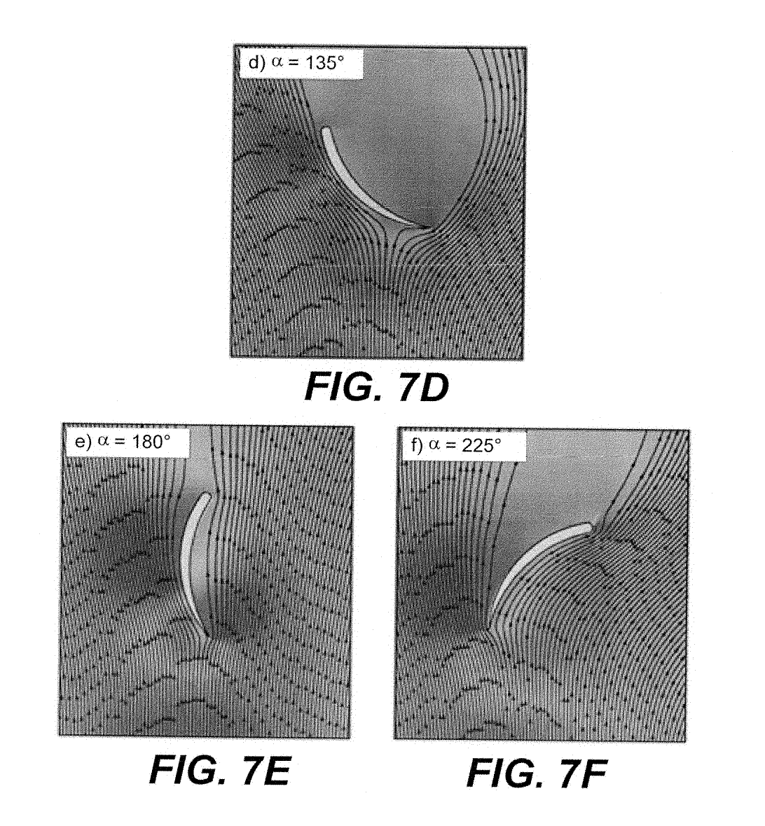

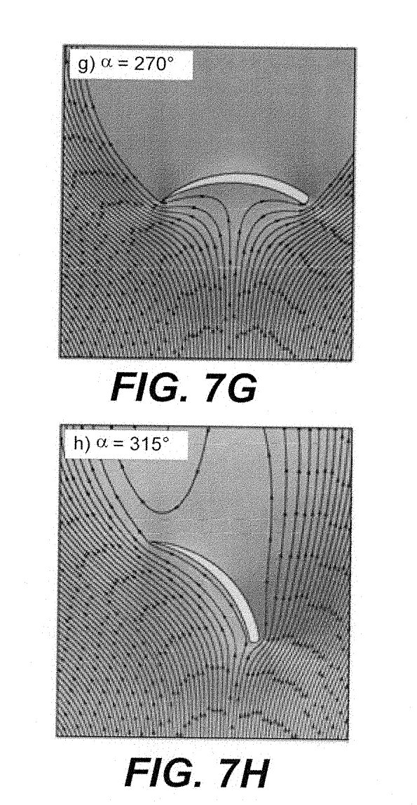

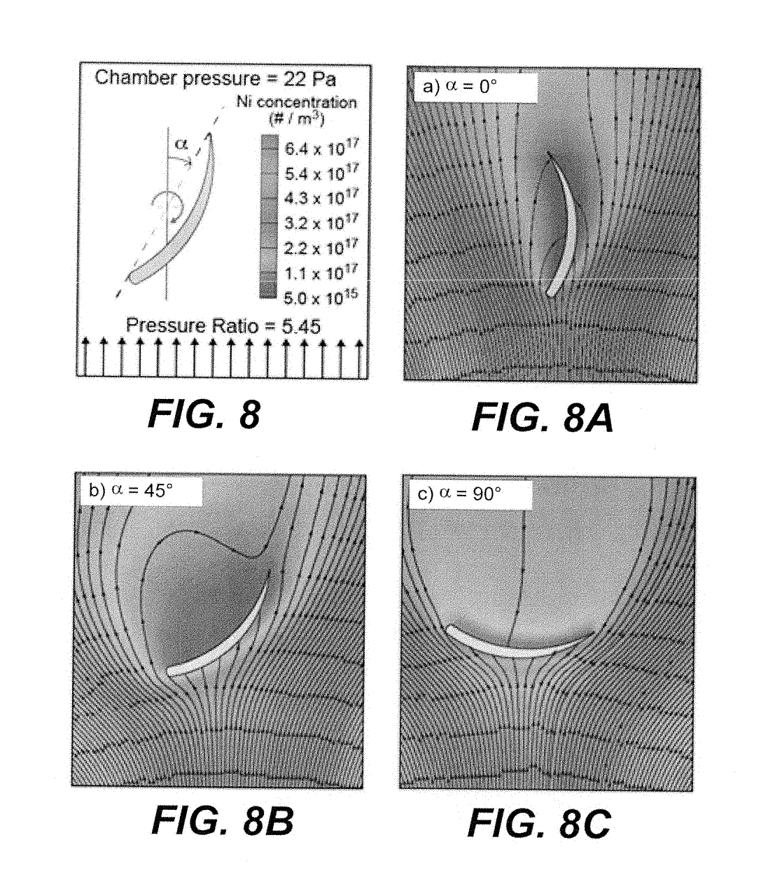

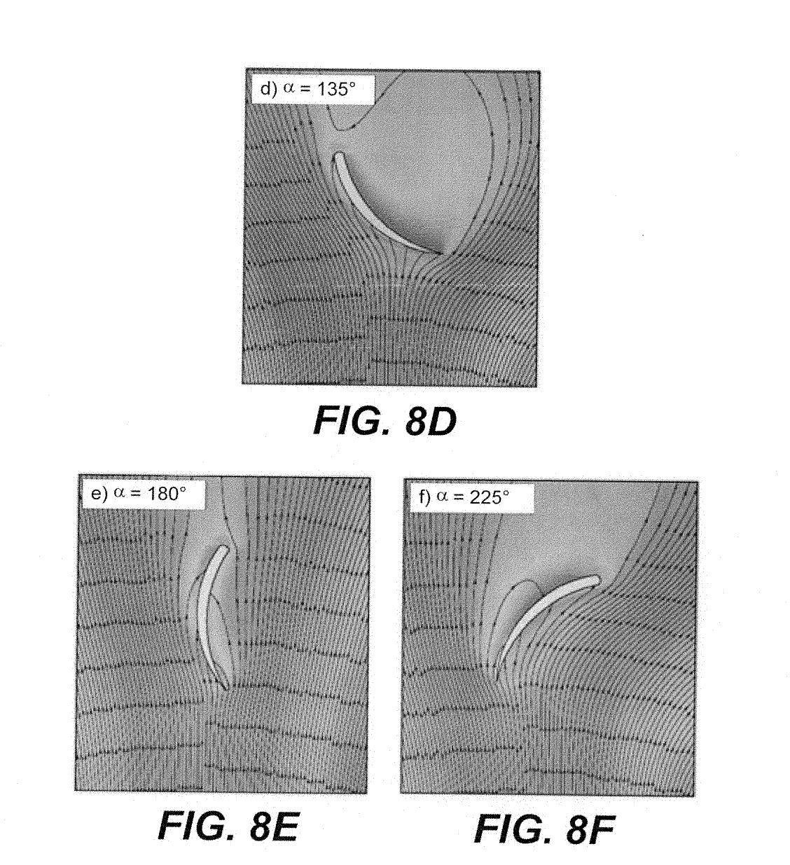

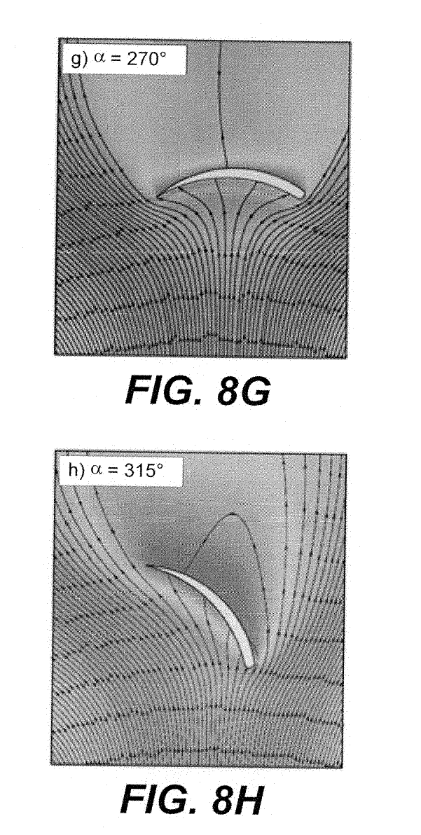

The flow field behavior, as characterized by the carrier gas streamlines and contours of pressure for this stationary simulated deposition condition is shown in FIGS. 7-7F. FIGS. 8-8H shows the corresponding vapor streamlines and concentration contours. The highest density of vapor particle streamlines terminated near the leading edge of convex side of the airfoil substrate, consistent with the thickness profile predicted by the simulation methodology. This region of highest deposition rate was within the line of sight of the vapor source and depleted the concentration of vapor in the gas jet flow that subsequently passed close to the airfoil surface. However, binary collisions between the vapor and gas jet atoms were able to scatter vapor atoms towards the substrate, resulting in significant (diffusive) coating of the NLS regions of the stationary airfoil.

The results above indicate that it is not possible to deposit a uniformly thick coating over all surfaces of a stationary airfoil substrate. Even though gas jet assisted deposition processes result in some deposition onto NLS surfaces, the thickest coatings form on regions within sight of the vapor source. However, rotation of such a substrate during deposition allows all areas of the substrate to spend some time within the line of sight of the vapor source, and results in improved coating uniformity.

The behavior of the gas jet near the substrate varies significantly during substrate rotation. This variation is shown by the carrier gas streamlines and pressure contour plots in FIGS. 7-7H for the baseline DVD simulation conditions. The figures show that flow remains laminar for all orientations. At orientations where the airfoil's chord was roughly parallel to the flow direction (α=0° and 180°), FIGS. 7A and 7E, the streamlines flow past the substrate with modest perturbation. However, isolated regions of stagnation that resulted in an elevated pressure (˜1.3 times the background) above the airfoil surface nearest to the vapor source. Greater increases in pressure (up to 1.5 times background) over larger areas of the airfoil's primary surfaces were observed when the airfoils were oriented at α=90° and 270° to the jet flow axis, FIGS. 7C and 7G. This again is a manifestation of stagnation against the airfoil surface. Intermediate orientations exhibited a transition between these two limiting scenarios.

The variation of gas flow near the airfoil shown in FIGS. 7-7H greatly affected the vapor atom streamlines near the substrate. The average vapor atom trajectories and contour plots of the vapor atom concentration are shown in FIGS. 8-8H for each simulated orientation. The results were also calculated at baseline simulation conditions. When the substrate was oriented in-line with the jet axis (α=0° and 180°), as shown in FIGS. 8A and 8E, both the convex and concave surfaces received a significant vapor flux. Surface regions closest to the vapor source (the leading edge at α=0° and trailing edge at α=180°) received the highest vapor fluxes. Airfoil regions downstream from the leading or trailing edge received a reduced flux because of earlier depletion from the gas jet streamlines by condensation onto the leading or trailing edges²³. When the substrate was oriented perpendicular to the jet axis (α=90° and 270°), as shown in FIGS. 8C and 8G, the surface facing the vapor source received a much higher vapor flux compared to that on the shadowed surface. At other intermediate substrate orientations, FIGS. 8B, 8D, 8F, and 8H, significant parts of one surface were in the line-of-sight of the vapor source while others were shadowed resulting in a strong spatial variation in the local flux incident upon the surface.

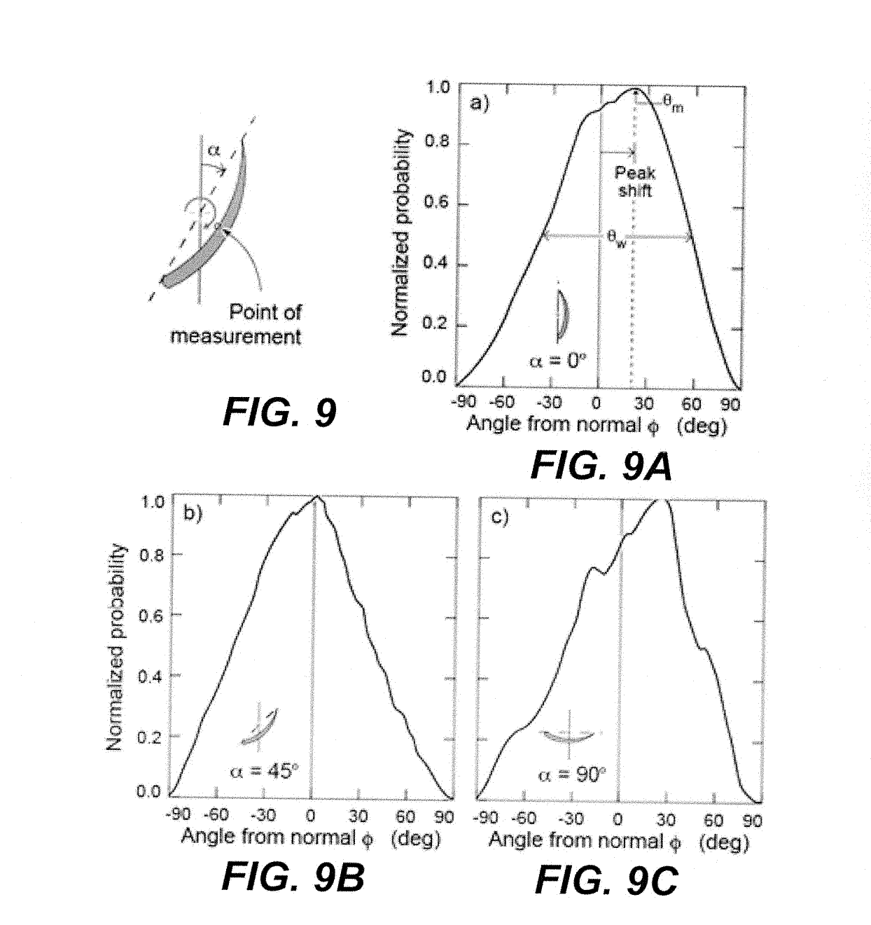

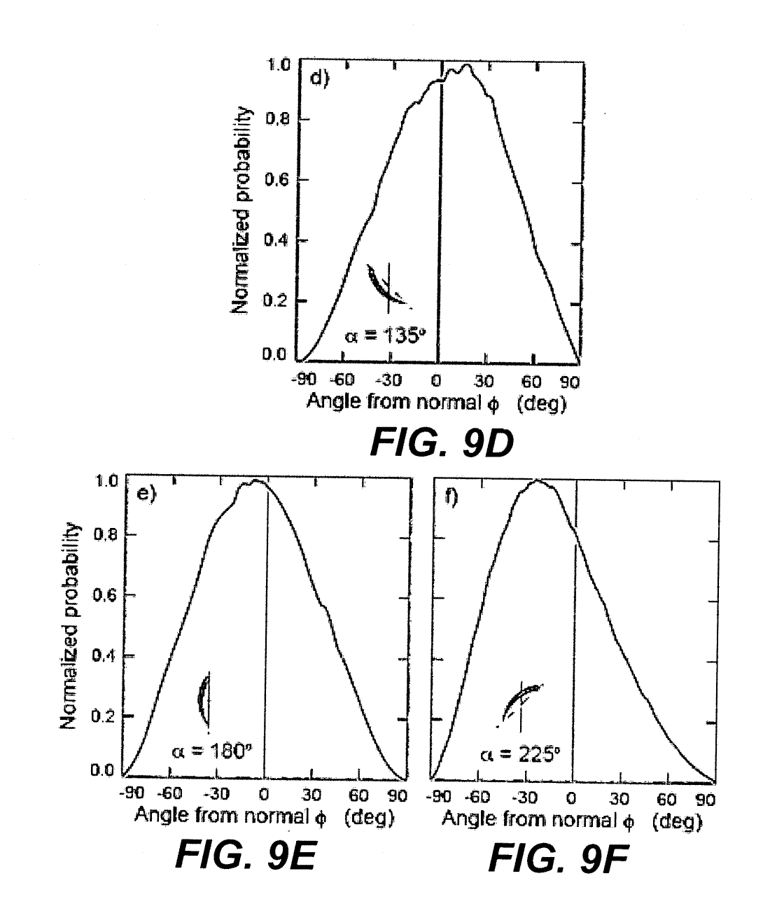

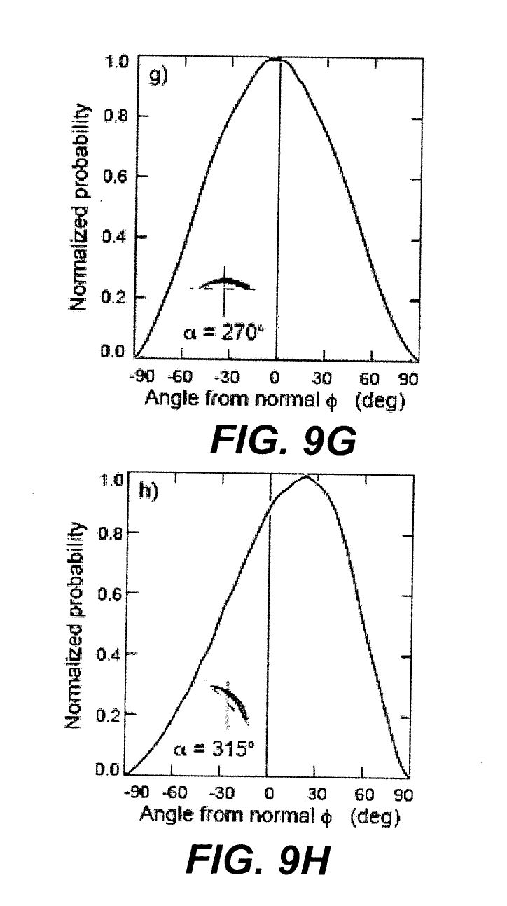

The orientation of the substrate also affected the IAD at all locations on the substrate. For example, FIGS. 9-9H shows the IAD at the midpoint of the concave surface for each angle of rotation. When the midpoint of the concave surface was in the line-of-sight of the gas jet origin, FIGS. 9F, 9G, and 9H, the distribution maximum angle was closely correlated with the angle between the local surface normal and the gas jet axis. However, when this midpoint location was in a NLS position, the IAD received a much more isotropic flux, as shown in FIGS. 9B and 9E, though in some cases with a still substantial shift in θₘ, from zero, as shown in FIG. 9A.

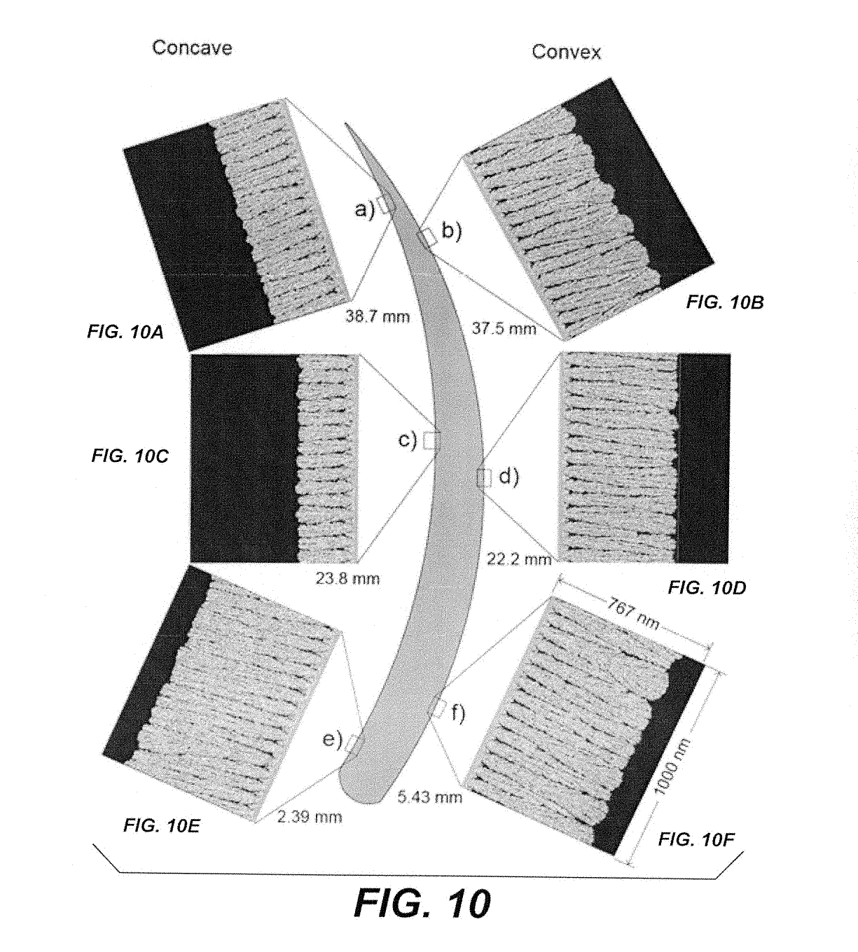

The kMC simulated coatings at six (6) locations on the substrate (the same locations used for stationary deposition, as shown in FIG. 5, using baseline deposition conditions) are shown in FIG. 10. The variations with location of the coating thickness, the columnar growth angle and the porosity were much reduced compared to the stationary case. As with coatings created by stationary deposition, each protuberance on the substrate acted as a nucleation site for columnar growth. On the concave surface, the growth columns typically extended through the entire coating thickness, and the number density of column tips on the coating's exterior surface was similar to the density of nucleation sites. Along the convex surface, the coating microstructure was comprised of wedge-shaped columns that increase in width as they grew out from the substrate surface. Many columns intersected with each other during this competitive growth process, and as a result, the coating surface was composed of fewer, wider column tips, each covering several nucleation sites.

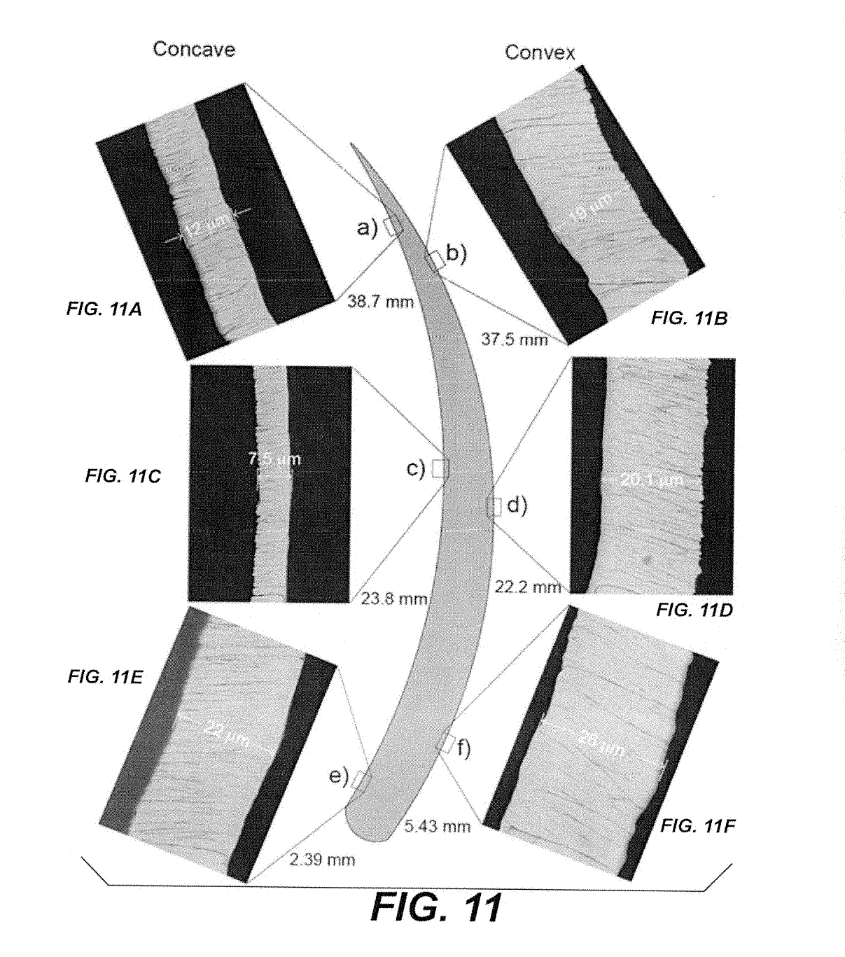

SEM micrographs of a nickel coating deposited on a rotated airfoil substrate using a chamber pressure of 22 Pa, a pressure ratio of 5.45 and a substrate temperature T/T_{M}=0.243 (the same as the simulations above), are shown in FIG. 11 for similar locations to those shown in FIG. 10. The experimental coatings exhibited generally similar trends in coating thickness, and columnar growth angle as the simulations. The experimental coatings also had similar variations of surface morphology to those found on the simulated coatings. Along the concave surface, the growth columns were narrower and neighboring columns typically grew parallel to each other with vertical sides. Along the convex surface, columns were often wider and more fan-like, with neighboring columns often intersecting each other during growth.

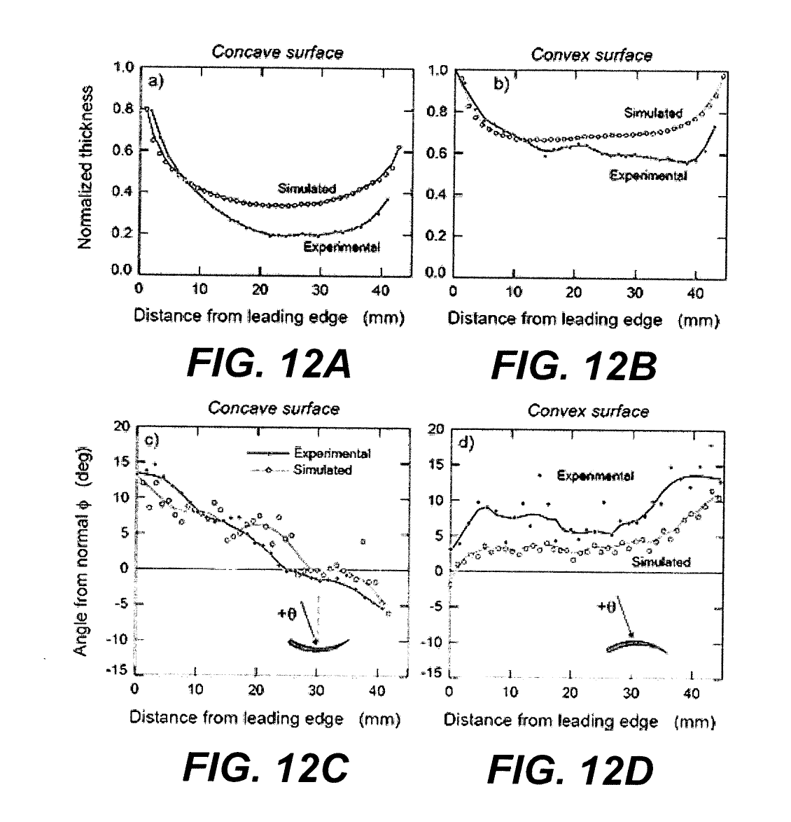

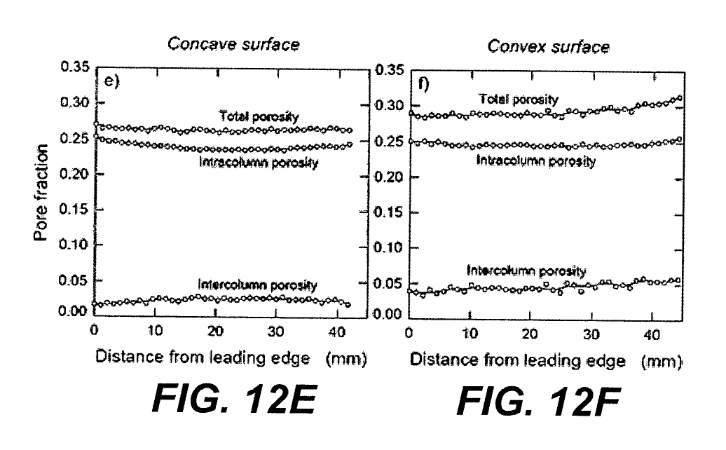

Rotation of the substrate greatly improved the uniformity of coating thickness along the concave surfaces, as shown in FIG. 12A, and along the convex surfaces, as shown in FIG. 12B compared to stationary deposition, as shown in FIGS. 6A and 6B. The experimental coating thickness is also plotted on FIGS. 12A and 12B and was in reasonable agreement with that simulated. Once again, the thickness profiles on both sides were normalized by the thickness at the convex surface's origin at the leading edge as shown in FIG. 3. The coatings located near the leading and trailing edges were thicker than at the center of the substrate surfaces. It is also evident that the coating on the concave side of the airfoil was thinner than that on the convex surface.

The growth column angle variation with location along the concave and convex substrate surfaces can be seen in FIGS. 12C and 12D. Comparison with FIGS. 6C and 6D for the stationary case, shows that substrate rotation greatly reduced the average growth angle and angle variation along both surfaces. For much of the substrate, the rotated coating's growth columns were almost normal to the local substrate surface. The most significant deviations (of 5° to 15°) from normal were confined to locations near the leading and trailing edges of the substrate. Agreement between simulated and experimental growth angles was also much improved.

The intracolumnar pores in the experimentally grown coatings were ˜10-100 nm in length while those between the growth columns had widths (intercolumnar gaps) of ˜1 μm and a length comparable (in some cases equal) to the coating thickness. The volume fraction of intracolumnar pores was typically independent of the initial roughness of the substrate, whereas the intercolumnar pore volume fraction was very sensitive to the surface topology of the substrate; especially during early stages of deposition when the gap width depended sensitively upon the surface asperity spacing.

The total porosity (and its two constituent types) of a coating simulated using the baseline DVD conditions is shown as a function of location along the concave and convex surfaces of a rotated airfoil in FIGS. 12E and 12F. Examination of the figure shows that the total, and two components of the pore volume fraction (for a rotated deposition using the baseline conditions) were approximately independent of position along the airfoil surface. However, while the intracolumnar porosity was approximately the same on both the concave and convex surfaces (with a pore fraction of ˜0.25), the intercolumnar component of porosity on the convex surface was almost twice that of the concave surface coating. By comparing FIGS. 10C and 10D, it can be seen that this difference resulted from the formation of wider intercolumnar pores on the convex surface of the rotated airfoil. This occurred because of the increased fraction of oblique atom trajectories that impact the convex surface. On the concave surface, the airfoil's leading edge and trailing end shadowed many of the atoms travelling along these highly inclined trajectories.

Porosity evolution during vapor deposition resulted from flux shadowing in combination with insufficient surface diffusion to replace the local adatom deficit. The surface roughness, and therefore pore fraction of a coating, is consequently temperature and deposition rate dependent since the rate of (thermally activated) surface diffusion is sensitive to the substrate's temperature during the deposition process. The porosity increased with deposition rate, due to the reduced interval of time available for surface diffusion between atom arrivals. However, coating porosity was less sensitive to deposition rate than to temperature since it has a linear effect on the degree of surface diffusion, while the temperature dependence is exponential (Equation 1). Simulations were performed at homologous temperatures, T/T_{M} from 0.2 to 0.515 to investigate the effects of temperature on the two components of the total porosity. The simulations were again performed using baseline DVD parameters for a rotated airfoil.

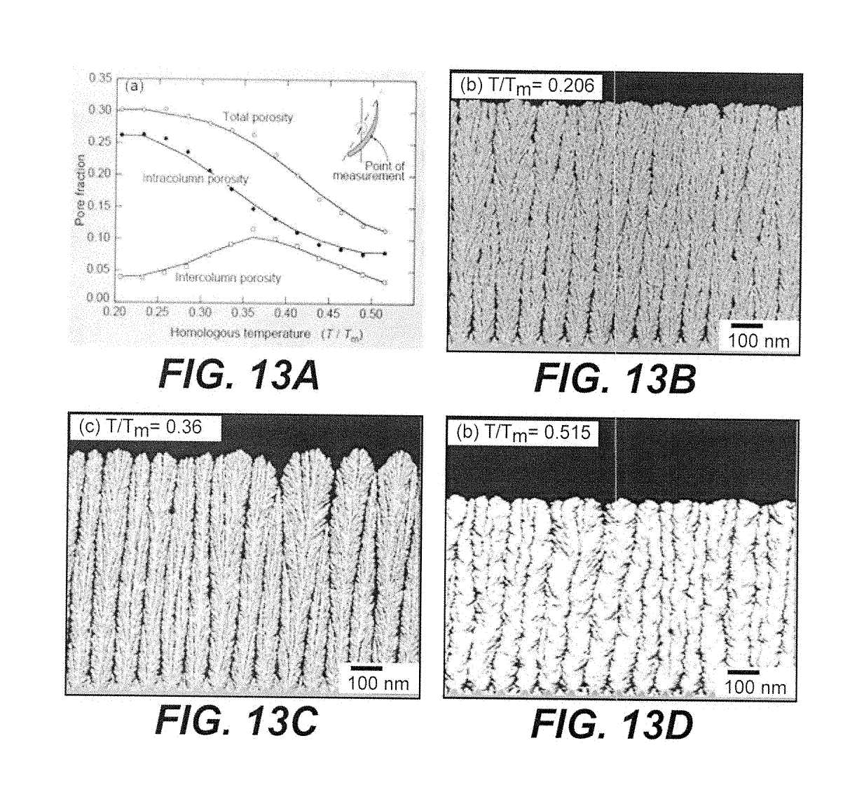

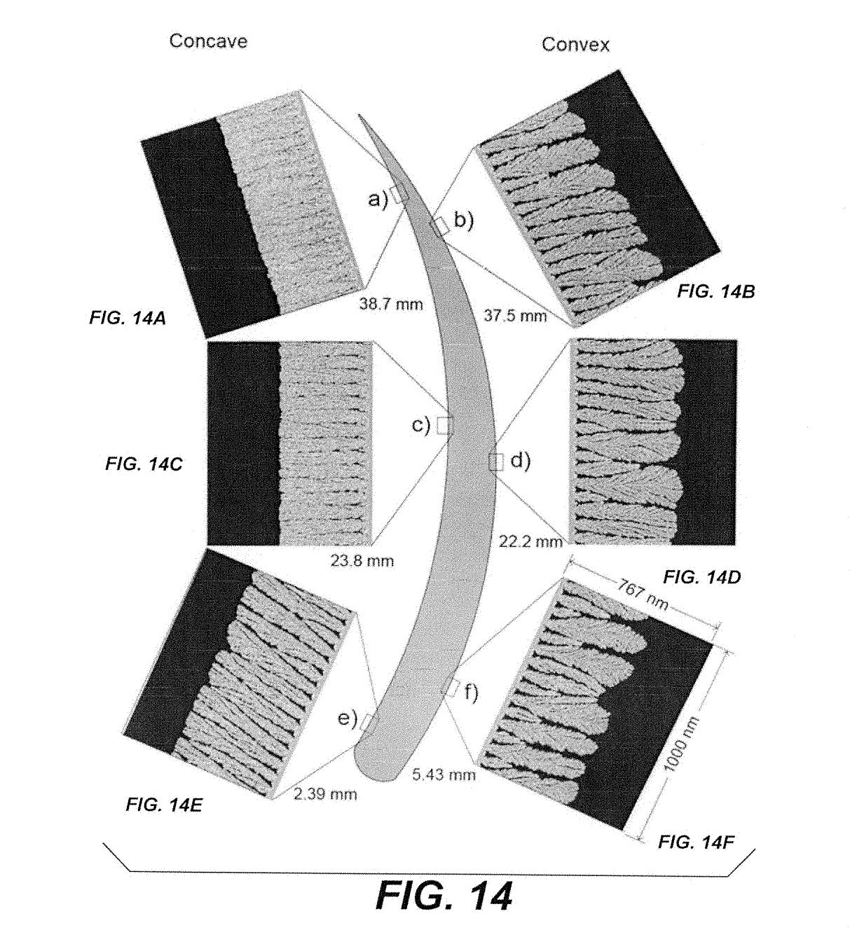

The pore volume fractions midway along the convex airfoil surface are shown in FIG. 13A (the trend at the midpoint of the concave surface was nearly identical and therefore not shown). Increasing the substrates temperature resulted in a rapid densification of the growth columns, as shown in FIG. 13B. The intracolumnar pore fraction decreased from ˜0.27 at T/T_{M}=0.206 to approximately 0.12 at T/T_{M}=0.515, consistent with increased surface diffusion during the deposition process. However, the intercolumnar porosity at first increased with increasing temperature before reaching a maximum at T/T_{M}=0.36 and then decreasing at higher temperatures. This was a result of a gradual increase in the width of the intercolumnar pores until T/T_{M}=0.36, as shown in FIG. 13C. Further increases in temperature resulted in more surface diffusion, the sintering of some growth columns and a reduction in the width of intercolumnar pores along the substrate surface, as shown in FIG. 14D.

The results above show that the local thickness, growth column inclination and pore volume fraction within a coating deposited on a rotated, airfoil shaped substrate are controlled by many parameters. The deposition temperature, vapor atom IAD (determined by vapor phase scattering, which in turn depends upon the pressure, flow field and scattering coefficients of colliding species), and deposition rate all significantly influence the structure, and therefore thermophysical and mechanical properties of the coatings. In order to investigate the effects of process conditions, simulations were performed at a broad range of conditions including a low chamber pressure of 0.015 Pa and a pressure ratio of unity (typical of an EB-PVD coating process). Additional simulations at chamber pressures of 1, 16 and 45 Pa (using a pressure ratio of 5.) typically accessible by an EB-DVD process were performed. Simulations using the much higher chamber pressure (of 100 Pa with a pressure ratio of 5) typical of a PS-PVD process were also performed. A substrate temperature, T/T_{M}=0.243 an evaporation rate of 8.8×10²⁰ atoms m⁻²s⁻¹ and a rotation rate of 6 rpm was used for all simulations. The effect of the chamber pressure upon the incident vapor flux (closely related to local coating thickness), growth column orientation and pore volume fraction were all investigated.

Simulated microstructures calculated for EB-PVD conditions are shown in FIG. 14 at identical locations to those in similar figures above. They show that the coating thickness uniformity was significantly better than for the high-pressure EB-DVD conditions. However, increased variation of coating porosity was evident around the substrate. The porosity was highest in regions that received a significant amount of flux from oblique incident angles, FIGS. 14B, 14D, 14E, and 14F). In these regions, the intercolumnar gaps were wide, and competitive growth between neighboring columns was found. In the regions near the trailing edge on the concave surface, FIGS. 14A and 14C, the microstructures were much denser with narrow intercolumnar pores. In these regions, oblique incident atom trajectories were shadowed by the airfoil's edges and most atoms were deposited from trajectories oriented near the surface normal.

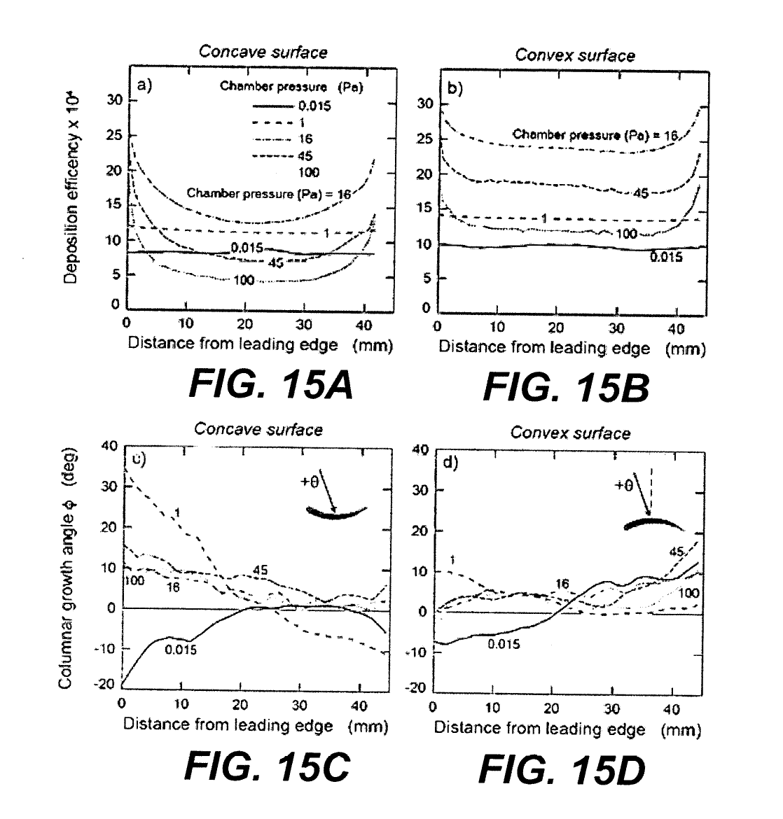

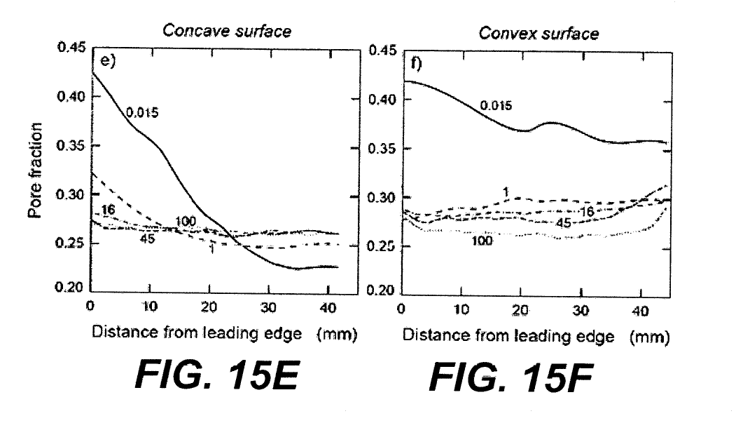

The ratio of the number of vapor atoms deposited in each (˜1 mm wide) simulation region to the total number of evaporated atoms (the deposition efficiency) is a key factor contributing to the local thickness of a coating. This local deposition efficiency is plotted as a function of the position on the two surfaces of a rotated airfoil in FIGS. 15A and 15B, and used as a surrogate for normalized coating thickness. Deposition under the lowest pressure (EB-PVD) conditions resulted in coatings of an almost constant thickness along each surface. Comparison of FIGS. 15A and 15B for this case also shows that the local deposition efficiency on the convex and concave sides were also identical, and varied little with position. However, the vapor flux incident on each 1 mm wide region was slightly less than 10⁻³ of the emitted vapor. When integrated over the 40, 1 mm-wide regions, this resulted in a deposition efficiency of 0.034 for the concave surface and 0.039 for the convex side. This deposition efficiency of ˜4% of the evaporated flux was due to lateral expansion of the vapor plume during propagation from the source, and would decrease further with increasing source to airfoil (standoff) distance. Increasing the chamber pressure to 1 Pa began to laterally confine the vapor plume, and increased the fraction of flux deposited on both surfaces, but with that deposited on the convex surface rising more rapidly. As the pressure was further increased, the deposition efficiency at first increased on both sides of the airfoil, but then reached a maximum before falling with further pressure increases. This drop in local efficiency was most dramatic on the concave surface, where the flux eventually decreased below that of the lowest pressure depositions. This phenomenon contributed to the development of a substantial difference in coating thicknesses on the two surfaces. Increasing the chamber pressure also increased the variation in deposited flux with location along each surface; the maxima in incident flux occurred at the ends of the airfoil, and increased relative to the minima at midpoint locations.

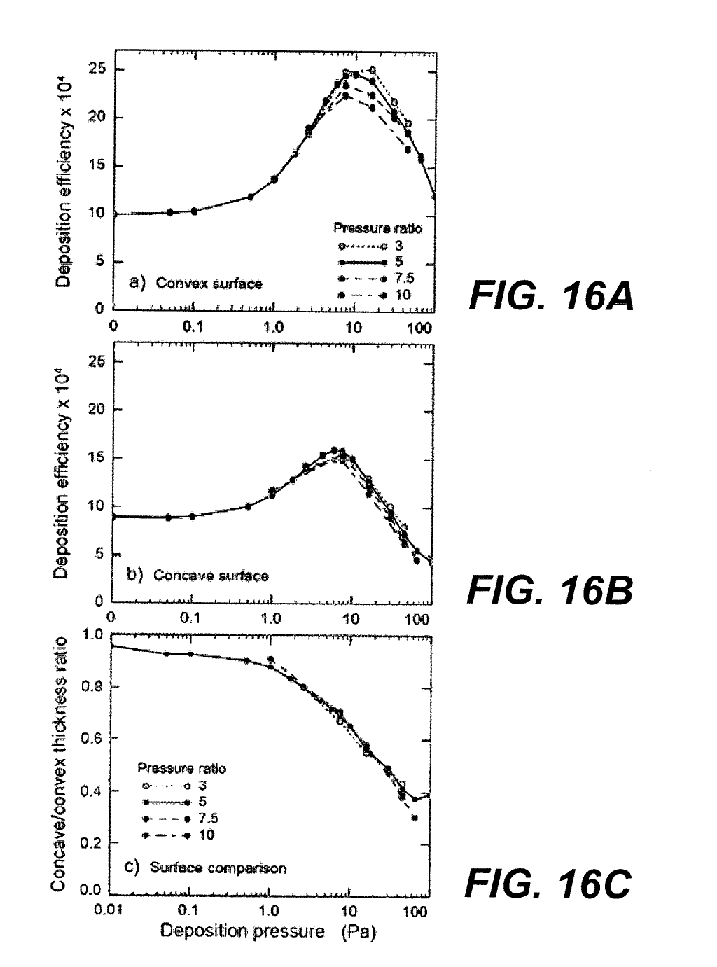

The effects of the chamber pressure and pressure ratio on the fraction of vapor that was deposited at the midpoints of the concave and convex surfaces can be seen in FIGS. 16A and 16B. An increase in pressure to 10 Pa was accompanied by a substantial increase in the fraction of the evaporated flux that condensed on the substrate. This increase in local deposition efficiency reached a maximum at a chamber pressure of ˜5 Pa, and was relatively insensitive to the pressure ratio. FIG. 16C shows the variation of the ratio of the concave to convex surface midpoint coating thicknesses for the same conditions. The asymmetry in coating thickness between concave and convex surfaces was small while the chamber pressure remained below about 1 Pa. Above this pressure, the thickness ratio dropped rapidly as the pressure was increased. Beyond a chamber pressure of 10 Pa, the deposition efficiency began to decrease, and both the deposition efficiency and concave/convex thickness ratio quickly decreased.

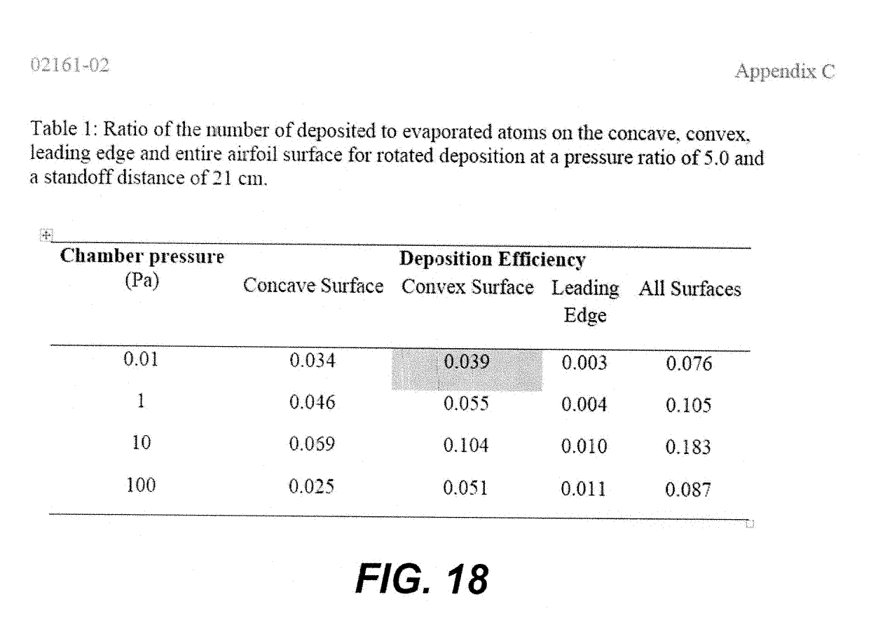

The trend in local deposition efficiency at the surface midpoints was quite similar to that for the overall deposition efficiency determined by integration of the local efficiency distribution over the entire substrate surface. FIG. 18 shows the ratio of the number of deposited atoms to the number evaporated along the concave, convex, leading edge, and entire substrate surface at several chamber pressures all at a pressure ratio of 5. Deposition efficiency along all of the surfaces increased with chamber pressure until it reached a maximum at 10 Pa of about 18.3% (compared with 7.6% at a pressure of 0.01 Pa). The total deposition efficiencies at 0.01 and 100 Pa were quite similar. While the 0.01 Pa efficiency was low due gas phase spreading, at high pressures, the low efficiency resulted from short diffusion distances of the vapor transverse to the vapor streamlines. This slow transverse diffusion resulted in many vapor atoms flowing past the substrate without impacting and condensing upon its surface.

Coatings deposited at a chamber pressure typical of EB-DVD conditions possessed thickness variations over the airfoil surface quite different to those deposited under EB-PVD-like conditions (FIGS. 15A-15F and 16A-16C). The differences were a result of two effects of the carrier gas jet: Deposition from gas streamlines close to a substrate edge and the creation of a wall jet for substrate orientations perpendicular to the gas jet. The influence of both effects increased with chamber pressure. Deposition from gas flow around a substrate edge was most significant when the airfoil was oriented with the leading edge nearest the vapor source, but slight inclined, as in FIG. 8F. Under low-pressure (0.015 Pa) conditions, no vapor was deposited onto the shadowed surface region (in this case, the convex surface). Although there is a significant concentration of vapor just above this surface region, no scattering collisions occurred to knock atoms from their straight-line trajectories, and onto the substrate surface. However, these collisions were present during DVD-like deposition, and significant amounts of vapor were deposited from the gas jet flow around the airfoil's edges. This contributed to thicker coatings near the airfoil edges under DVD conditions. The frequency of these collisions increased with chamber pressure, resulting in a higher deposition rate onto the shadowed surface.

Deposition onto the substrate ends was also enhanced when the substrate was oriented transverse to the gas jet (α=0° and 90°). At higher chamber pressures, the gas jet sensed the substrate and flowed around it. This created a wall jet that transported incident vapor parallel to the substrate surface, decreasing the amount that reached the substrate's midpoint, and increasing the amount able to impact near the substrates ends. As the chamber pressure increased, multiple scattering collisions in the boundary flow made it increasingly less likely for vapor to reach the substrate surface, and the overall deposition efficiency decreased. The low-pressure used in PVD deposition, resulted in the incident vapor plume being uninfluenced by the substrate's orientation, resulting in a uniform deposition rate along the entire line-of-sight region of surface. The PVD profiles have slight rises near the center of each surface, as these regions remain in the line-of-sight of the vapor source for a longer duration during rotated substrate deposition.

The variation in columnar growth angle, φ along the convex and concave surfaces is shown in FIGS. 15C and 15D. Deposition at the lowest chamber pressure (0.015 Pa) resulted in a substantial (˜20°) variation of the growth column orientation angle along the concave and convex surfaces. FIG. 15D shows that on the concave surface, columns grown near the leading edge at a pressure of 0.015 Pa were oriented away from the leading edge and gradually transitioned to perpendicular growth with increase in distance from the leading edge. On the convex surface near the leading edge, the 0.015 Pa growth column orientation angle was about 7° away from the leading edge, FIG. 15D, similar to that reported for EB-PVD coatings by Darolia. At the trailing end of the convex surface coating, the growth column angle was ˜12°, with the columns sloped towards the leading edge. Under the lowest pressure deposition condition, the column angle on the convex surface changed progressively between these two limits so that near the mid-point of the coating, the columns were oriented normal to the local substrate surface.

The use of a gas jet with chamber pressures up to 100 Pa led to significant changes to the angle of the growth columns. On the convex surface, coatings grown at higher pressures, FIG. 15D, formed columns that were oriented very nearly perpendicular to the surface except for regions within ˜5 mm of the convex origin and ˜10 mm of the trailing end. Between ˜5 and 35 mm from the convex origin, the columns were only slightly tilted (by about 5°) towards the leading edge. Near the trailing edge, the growth angle was more severely tilted towards the leading edge, reaching maximum angle of 10 to 20°. On the concave surface, FIG. 15C, the use of a higher chamber pressure resulted in column growth in the opposite orientation from those grown at 0.015 Pa between the leading edge and surface midpoint (i.e. they oriented towards the leading edge). From the midpoint to trailing edge, the coatings grew at an angle within 5° of the local surface. Columns grown at 1 Pa show a different pattern to those deposited at other conditions. These columns tended to point towards the nearest substrate edge. Unlike the lowest pressure (0.015 Pa) case, vapor experiences scattering collisions at this pressure. However, their frequency is insufficient to cause significant diffusion transverse to, or against the direction of the gas jet. Atoms therefore arrive at the surface from trajectories closely aligned to the local gas jet flow.

The columnar growth angle was significantly affected by the introduction of a gas jet into the deposition process. For EB-PVD conditions, growth angles were aligned to the least-shadowed directions, while the introduction of a carrier gas causes the columns to tilt towards the directions with the most incident gas flow. This is most apparent near the leading edge along the concave surface (FIG. 15C). Under EB-PVD-like conditions, this surface area is shadowed by the leading edge at many orientations. Thus, the majority of vapor arrives from the trailing edge direction, and the columns were tilted towards it. With introduction of a carrier gas, a significant amount of vapor flows around the leading edge and deposits on the nearby substrate surface. Vapor arriving from the trailing edge's direction must first flow along the concave surface, and is likely to deposit before reaching the leading edge. This resulted in columns that were oriented towards the leading edge.

The coating porosity is shown for both airfoil surfaces in FIGS. 15E and 15F. Deposition at the lowest pressure led to a pore volume fraction of ˜0.4 at the leading edge of both the convex and concave surfaces. This then progressively decreased towards the trailing edge of the coatings. This decrease occurred more rapidly with distance along the concave surface, and fell to a lower value (˜0.2) than on the convex side. Coatings deposited at chamber pressures of 16 Pa and above had a nearly uniform pore volume fraction of ˜0.27 on both sides of the airfoil. The porosity varied little with position along either airfoil surface. The porosity near the leading edge of the concave side initially decreased rapidly with pressure, but for pressures above 1 Pa, was independent of pressure. However, beyond a distance of the ˜25 mm from the leading edge, the porosity of the EB-PVD condition coating decreased below that of the high-pressure coatings. On the convex surface, increasing the pressure above 0.015 Pa resulted in a decrease in porosity. Above 1 Pa, the porosity continued to decrease with increasing pressure, but at a much slower rate. In this higher-pressure regime, the porosity was substantially less than that of an EB-PVD pressure coating.

The simulations above have revealed that the thickness of a coating and its microstructure vary with position on an airfoil surface in a manner that is sensitive to the deposition conditions. Usually these deposition conditions are fixed during the application of the coating. However, modifying the evaporation rate (by modulating the electron beam power), the dwell time at each airfoil orientation (with a variable rotation rate), or the standoff distance (by eccentric substrate rotation), could enable the deposition of coatings whose thickness and microstructure were locally controlled. This might provide a means to form coatings that provided protection against the most life limiting threat to each specific region of the substrate's surface. Rapidly varied parameters of the jet flow (pressure ratio or gas composition) could also be used for a similar purpose.

To investigate such an optimization, the dwell time at specific angles of airfoil rotation were varied with the objective of eliminating the difference in coating thickness between the concave and convex surfaces of an airfoil substrate. The simulated incident vapor fluxes at the eight stationary orientations used to simulate a rotation were each assigned a variable weight coefficient. The total flux incident on each surface region, j, was then given by:

j=Σₘ₌₁⁸aₘfₘ, (5)

where fₘ is the incident flux at each orientation, and aₘ is the orientation coefficient to be determined. The minimize function in the Scipy Python suite was then used to determine the aₘ resulting in the minimum total flux difference between the two airfoil surfaces expressed by:

ΔJ=Σₙ₌₁⁴⁰|j_{1,n}−j_{2,n}|, (6)

where j_{1,n} and j_{2,n} are the total flux at each of the n substrate regions along the concave and convex surfaces(n=1-40 surface regions). The summation began at the convex and concave surface origins (near the leading edge) and proceeded along each surface towards the trailing edge (increasing n). The coefficients were constrained so that each deposition had a maximum/minimum rotation rate ratio of 8 (the maximum allowable dwell coefficient was eight times larger than the minimum).

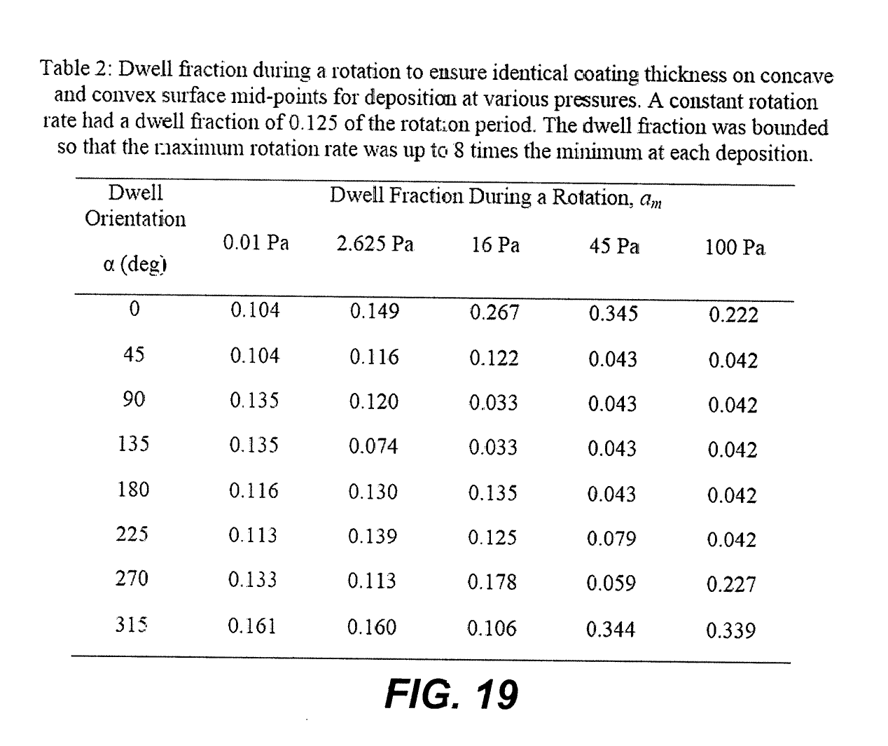

The resulting coatings obtained using the optimized rotation coefficients exhibited less than a 10% difference in flux (and thickness for a non-varying porosity) between the midpoint on their concave and convex surfaces, and combinations of coefficients could be found at all chamber pressures that maintained this level of resulting uniformity. The optimized coefficients are presented in FIG. 19 for depositions at 0.01, 2.625, 16, 45 and 100 Pa using a pressure ratio of 5 (except at 0.01 Pa where the ratio was 1). At the two lowest pressures, the coefficients varied only slightly from the coefficient for constant rotation (of 0.125). However, as the chamber pressure was increased, less uniform rotation patterns were required to achieve uniformity.

The total amount of flux incident on a substrate at each orientation can also be manipulated by adjusting the evaporation rate of the material source. In the current optimization design, this is mathematically equivalent to varying the rotation rate. In either case, a coefficient is used to adjust the deposition rate along the entire substrate surface. Optimizations in which both rotation and the evaporation rate are simultaneously adjusted can be implemented by using two, independent coefficients for each airfoil orientation. In that case Equation 5 is rewritten as:

j=Σₘ₌₁⁸aₘbₘjₘ, (7)

where aₘ is the dwell coefficient for variable rotation and bₘ is the coefficient for variable evaporation rate. The flux variation between the convex and concave surface can then be minimized by again using Equation 6. When the coefficients are unbounded, they can be represented by a single value. However, experimental depositions have a limited range of rotation rate and evaporation rate adjustment, and the use of both coefficients improved optimization.

The design of deposition strategies resulting in potentially beneficial, non-uniform thickness profiles can also be identified by this approach. For example, a thicker coating might be applied in regions prone to erosion or that require a larger drop in temperature across the coating to slow the growth rate of the bond coat's thermally grown oxide.

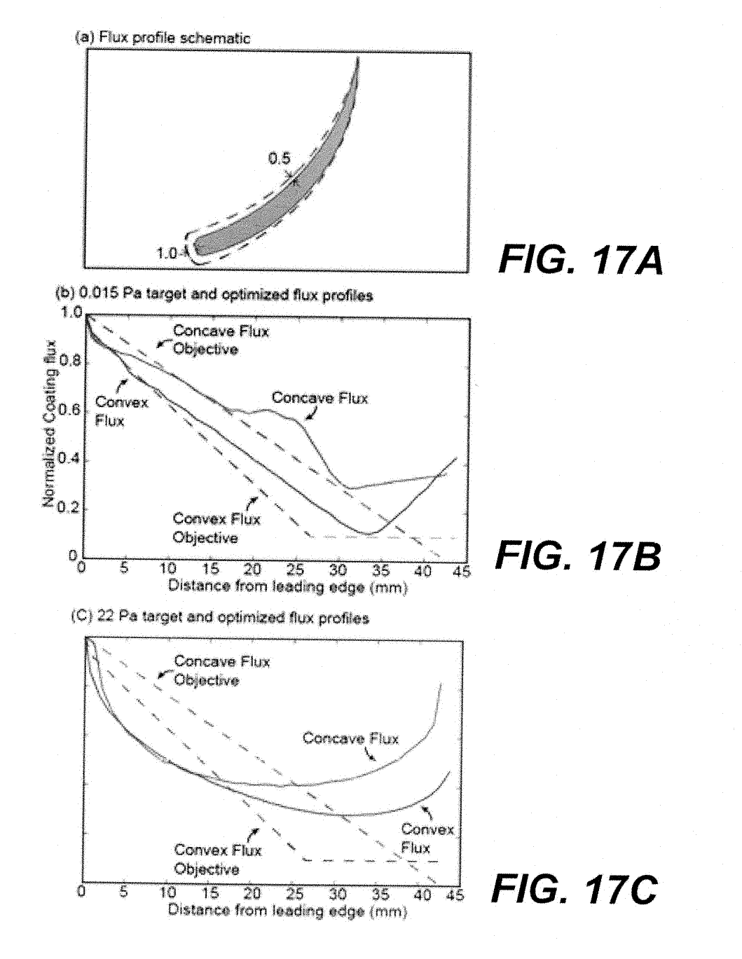

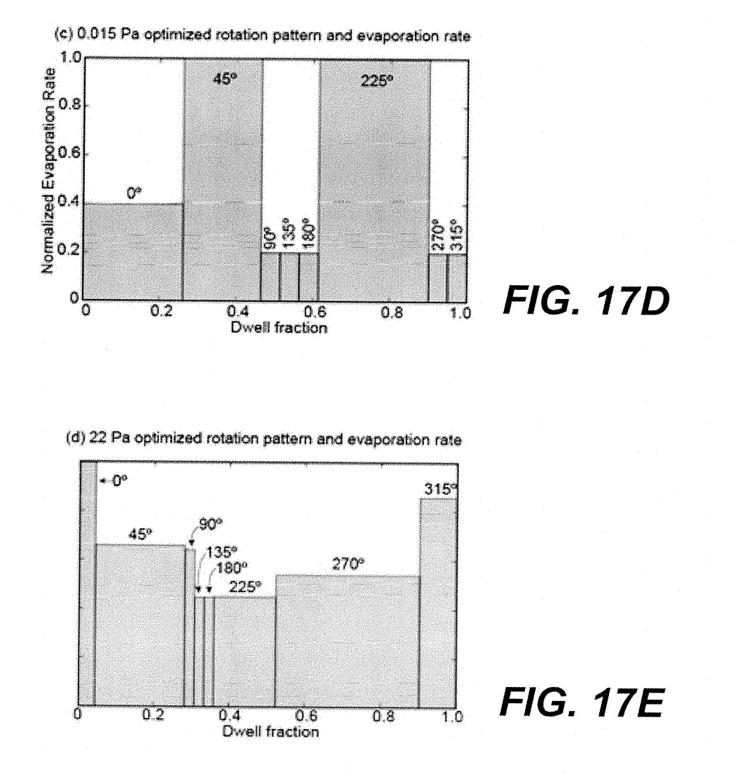

As an example, suppose the coating along the leading edge and concave (pressure) surfaces of an airfoil were designed to be thicker than that on the convex surface. The combined rotation/evaporation optimization method can be used to find a deposition sequence that achieves this. A target coating thickness profile that has a maximum at the leading edge and tapers to zero along the surfaces of the airfoil is schematically illustrated shown in FIG. 17A. For simplicity of presentation, the coating profile was defined so that the flux to the leading edge (defined between the concave and convex surface origins) had a constant value of unity and the target flux profile along the concave side was defined as:

j_{1T}(x)=1−0.027x, (8)

Along the convex surface it was defined as:

$${j}_{2 T} ( x ) = \{ \begin{matrix}1 - 0.041 x & x \leq 27 \\ 0.1 , & x > 27\end{matrix} , \qquad ( 9 )$$

where x was the distance from each surface origin in mm. The difference between the target and simulated flux profiles was then minimized using:

ΔJ=|j_{Leading}−1|+Σₙ₌₁⁴⁰(|j_{1,n}−j_{1T}(Δxn)|+|j_{2,n}−j_{2T}(Δxn)|), (10)

where Δx is the distance between simulation surface regions (1.13 mm and 1.07 mm for the convex and concave surfaces respectively) and j_{Leading} is j at the single leading edge surface region. During optimization the rotation rate was bounded between 0.5 and 10 times the constant rotation rate value, while the normalized evaporation rate was allowed to vary by no more than a factor of 5 (from 0.2 to 1.0), consistent with experimental observations ¹⁸. The optimization was performed at a chamber pressure of 0.015 (PVD-like conditions).

The resulting optimized flux profiles are shown in FIG. 17B along with their respective target flux profiles. The optimized profiles achieved the flux objectives fairly well, especially near the leading edge. However, both surfaces exceeded the thickness objective as the trailing edge was approached. The rotation pattern and evaporation rate variation used to obtain the optimized coating are shown in FIG. 17D. Wider bars indicate a larger dwell fraction, while taller bars indicate a higher evaporation rate. The plot shows that the majority of deposition flux was concentrated at 45 and 225° orientations. Significant additional deposition occurred at the 0° orientation. Both the evaporation rate and the dwell fraction were minimized for all other orientations. Finally, it is noted that the ability of the optimization process to meet this thickness objective gradually decreased with increasing chamber pressure. This is shown in FIGS. 17C and 17E for chamber pressures of 22 Pa and pressure ratio of 5.45. The resulting flux profiles poorly matched the objective profiles due to a rapid decrease in flux from the leading edge and an increased flux near the trailing edge on both surfaces. The use of more simulated substrate orientations (beyond the eight used here) might improve the optimization at high pressures by providing additional variable coefficients.

The combination of DSMC simulations to analyze vapor phase transport in a rarefied, gas jet assisted deposition process has been combined with a KMC method to enable prediction of the thickness and structure of a porous coating applied to an airfoil. Coatings applied to substrates that were not rotated during deposition were found to have non-uniform thickness and contained acute growth column inclination angles. Rotation of the substrate was found to result in uniform thickness coatings grown under EB-PVD like conditions, but the coating microstructure varied substantially with location. Introducing a gas jet and raising the pressure during deposition led to the growth of coatings whose growth columns were almost all oriented perpendicular to the airfoil surface. However, under constant rate rotation, the thickness of the coating on the concave surface was only a half that on the convex surface. The simulation method has shown that by modulating the rate of evaporation, it is possible to deposit coatings with both uniform thickness and the majority of the growth columns oriented normal to the local airfoil surface. Dynamic modulation of deposition also offers opportunities to “tune” the local coating thickness and structure to potentially better resist the damage mechanisms associated with specific locations on the airfoil surface.

### Physical Vapor Deposition on Doublet Airfoil Substrates: Simulation of Coating Microstructure

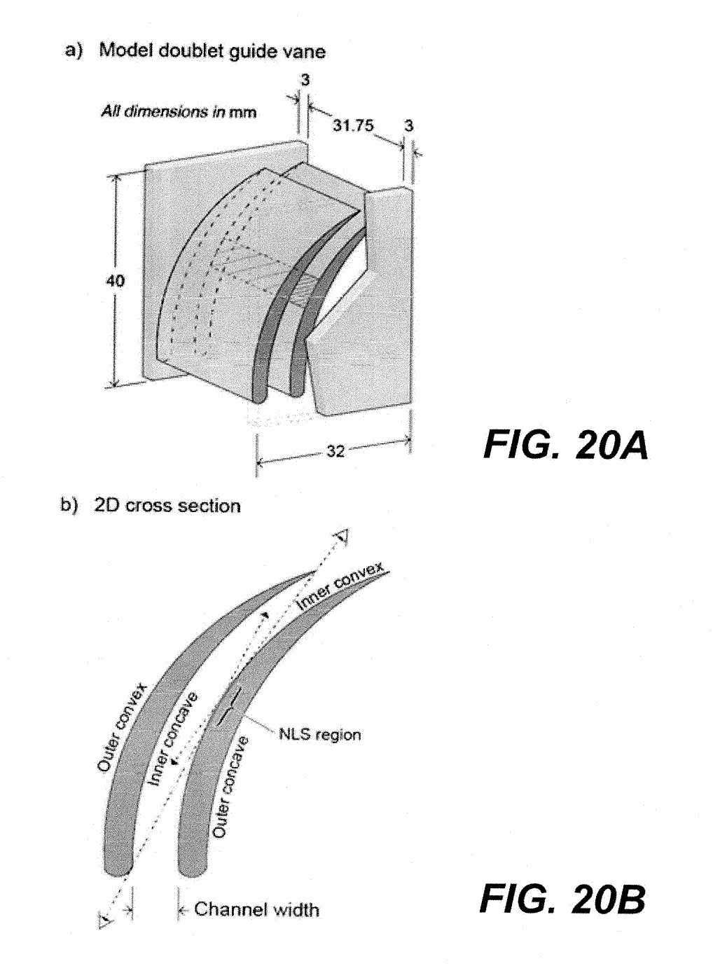

A schematic illustration of a model doublet airfoil guide vane substrate is shown in FIG. 20A. The inner surfaces of such a doublet substrate present an interesting coating challenge. Vapor atoms can only be deposited onto a NLS surface region (shown in red) if they have first undergone a scattering collision from the straight-line travel paths of a low-pressure PVD process. If condensation after scattering is accomplished, the broadened incidence angle distribution (IAD) of the resulting vapor flux that impinges upon this region might still allow the deposition of a porous, columnar coating structure.

Insufficient physical understanding of the coating process currently exists to design a process for control of the microstructure and thickness of a coating onto a component containing NLS regions. Recently, a plasma-spray physical vapor deposition technique (PS-PVD) has been proposed as a possible solution to the problem. Rezanka et al. and Góral et al. have both recently reported experimental studies of PS-PVD deposition onto airfoil substrates. Additionally, von Niessen et al. have demonstrated the ability to deposit coatings on doublet guide vane substrates. However, none of these studies addressed the fundamental phenomena controlling the resulting coating microstructure, nor investigated the best way of achieving a uniform coating on all the doublet guide vane airfoil surfaces.

The preferred TBC microstructure for coatings subjected to severe thermal cycling is columnar, with wide pores present between the columns to accommodate thermal expansion. The columnar growth angle of a TBC can also affect coating performance. Inclined columns with a high internal porosity have been shown to reduce the coating thermal conductivity by increasing the thermal transport distance. They might permit the use of thinner (more delamination resistant) coatings, inclined columns may suffer from more rapid erosion during impact by small particles. Wellman et. al found that the erosion rate increased with increasing growth column angle of departure from perpendicular to the substrate surface, due to increased columnar buckling and cross contact between individual columns. The absence of fundamental insight into the factors governing coating microstructure during vapor deposition onto substrates containing NLS regions is a substantial impediment to the design of improved deposition processes.

A recent study has used a direct simulation Monte Carlo (DSMC) method to investigate the thickness of a Ni atom coating on a doublet airfoil with the geometry shown in FIG. 1. It indicated that during vapor deposition onto a rotated guide vane substrate, the mid-regions of the interior convex and convex surfaces received a much smaller fraction of the evaporated flux than the outer surfaces, and led to significant disparities in coating thickness. The study found that the thickness uniformity along the curved inner channel surfaces could be improved by using a gas jet assisted deposition process. It found that by increasing the chamber pressure into the 10-40 Pa range, and using high velocity gas jet assisted vapor transport, the time for the vapor to be transported through the inter-airfoil channel could be made commensurate with that for transverse diffusion to the channel surface. Under these conditions, remarkably thickness uniformity could be achieved, especially when used in conjunction with a variable rotation rate strategy originally developed for improving the uniformity of coatings deposited upon single airfoils. Whilst, the DSMC simulation method was able to connect phenomena at the deposition reactor length and time scales to the flux locally incident on a substrate surface, it was incapable of simulating the ensuing atomic scale structure of the coatings.

Here, the DSMC method is combined with a kinetic Monte Carlo (kMC) multiscale simulation methodology and explore control of coating microstructure on a doublet guide vane surface. Since the microstructure on the outer surfaces were very similar (for all but the widest channel width substrates) to those of a recent study of deposition on single airfoils, we focus the study on the interior channel surfaces, as shown in FIG. 20B. We first investigate the vapor flux deposited upon the interior surfaces at various orientations during rotated deposition. The IAD along these surfaces will then be determined and used to simulate the deposition of coatings on the surfaces. The variation in columnar growth angle and coating porosity as the deposition conditions were varied is then systematically investigated. Finally, the rotation optimization method previously proposed for controlling coating thickness uniformity, is investigated for reducing variations of coating microstructure between the inner and outer airfoil surfaces.

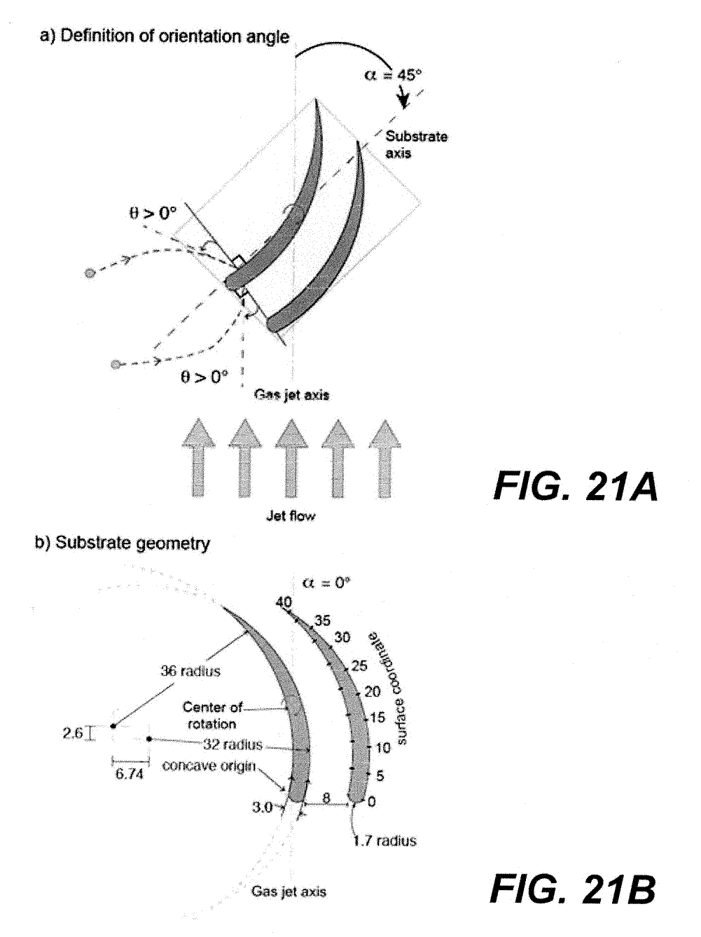

A combination of both experimental and simulated studies was used to investigate the microstructure of coatings deposited upon the doublet substrate shown in FIG. 20A. The multiscale direct simulation Monte Carlo (DSMC) and kinetic Monte Carlo (kMC) simulation scheme used to simulate the coating microstructure on single airfoils, was used to simulate the coating microstructure over the surfaces of the doublet airfoil substrate shown in FIG. 20A. The substrate orientation with respect to that of a gas jet flow, is shown in FIG. 21A. FIG. 21B shows the geometry of the deposition problem analyzed. This model problem allowed both the chamber pressure and the ratio of the pressure upstream of the jet forming nozzle and the chamber to be varied. The inter-vane channel width was also varied between 8, 12, and 16 mm (as measured between the leading edges), as shown in FIG. 20B.

Three (3) angles play important roles in microstructure development within the coating. In two (2) of these, the substrate orientation angle, and vapor incident angle, θ, are defined in FIG. 21A. The substrate orientation angle was defined as the angle between the gas jet axis and the orientation axis of the substrate as indicated in the figure. These axes are collinear at and both pass through the center of rotation of the substrate. The Incidence angle of the vapor was defined using the normal to the local surface as shown in FIG. 21A. The columnar growth angle φ, was defined identically to the vapor incident angle, θ, with a value of zero corresponding to columnar growth perpendicular to the local surface. The φ and θ angles were defined as positive when oriented towards the leading edge of the substrate and negative when directed towards its trailing edge. Vapor atoms depositing from similar trajectories onto different substrate surface (as shown in FIG. 21A) will have the same value of θ.

Both the simulation and the experiment utilized the same doublet airfoil substrate. The design of the two individual airfoils was identical to that previously used in an investigation of single airfoil deposition and a study of coating thickness on a doublet guide vane. During the simulations, the doublet airfoils were assumed perfectly two-dimensional. For experiments, the airfoils were 31.75 mm high (in the out of plane direction) and were capped on each side by a thin backing plate, as shown in FIG. 20A. This height was sufficient that the sides did not influence deposition profiles at the midline cross-section of the doublet. The circular arc length of each airfoil surface was approximately 41 mm. A surface coordinate was defined for each of the four (4) airfoil surfaces as shown in FIG. 21B. Its origin was defined as the intersection of the circular leading edge circumference with that of the airfoil, as shown in FIG. 21A.

The numerical simulation method combined the gas-phase direct simulation Monte Carlo method with a coating assembly kinetic Monte Carlo modeling approach to simulate the deposition of a nickel coating. The procedure was identical to that recently described by Rogers et. al. As in earlier studies of deposition nickel upon a single airfoil, the vapor flux incident upon the substrates was determined using the DSMC method embodied in the Icarus code (ref). It propagated atoms from a nickel vapor-emitting source to the substrate by tracking binary collisions between the vapor atoms and those of an inert gas jet in which they were entrained. This gas jet was created by a previously DSMC modeled expansion of a helium-10% O₂ gas mixture through a nozzle that encircled the vapor source.

The ratio of the gas pressure upstream of the nozzle to that in the chamber into which it was flowed then governed the speed of the jet that flowed towards the substrate. The DSMC simulations enabled the vapor flux incident upon a substrate and the local angle of incidence distribution to be computed at all locations around the substrate. Each substrate surface region was divided into 40 (1.07 mm length) subsections, and the flux and IAD data for each of these regions recorded during a simulation. To simulate substrate rotation, eight stationary DSMC simulations were performed with a 45° orientation difference between each of them.

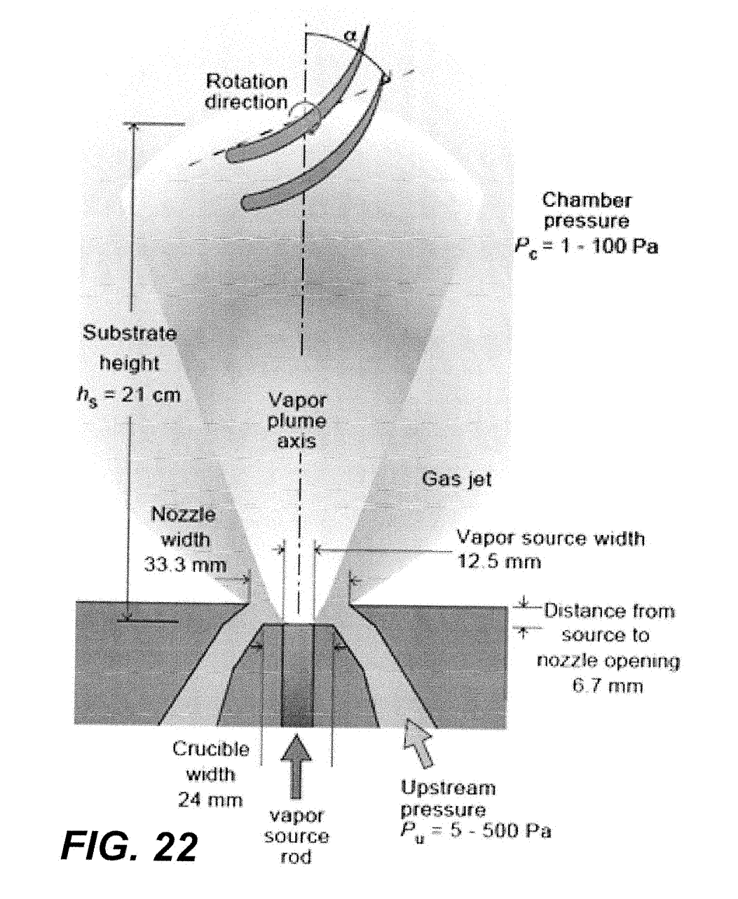

The kMC simulations of nickel deposition were performed on a substrate that was rotated about the axis of rotation shown in FIG. 21B at a rotation rate of six (6) revolutions per minute (rpm); the same as that used for experiments. This was implemented by assigning a fixed dwell time of 1.25 s at each of the eight simulated substrate orientations during the 10 s period of a single rotation. Atoms were deposited using the flux and IAD input parameters calculated by the DSMC method for each substrate orientation until the dwell time had elapsed, whereupon the input variables were changed to the next orientation's properties, and the simulation resumed until the total desired number of deposited atoms was reached. A typical IAD is shown in FIG. 22.

The kMC deposition rate was determined by assigning the surface region with the highest deposition flux as calculated by DSMC a deposition rate of Dₘₐₓ=4.3 μm/min. The deposition rate, D at each surface region along the remainder of the substrate was determined by normalizing the DSMC calculated fluxes by the maximum value;

D=Dₘₐₓ(f/fₘₐₓ) (11)

where f is the DSMC determined vapor flux at a surface region and fₘₐₓ is the maximum vapor flux at each orientation. When rotated deposition was simulated, D was calculated at each orientation. The total number of atoms deposited in each simulation region, N, was also scaled by the total DSMC flux;

N=Nₘₐₓ(f/fₘₐₓ) (12)

where Nₘₐₓ=9,000,000. During rotated deposition, f and fₘₐₓ were determined by summation of DSMC fluxes from all orientations.

Experimental depositions using a nickel source were performed using an EB-DVD method and were conducted in an identical manner to that described in the previous study of coating thickness uniformity on the same substrate. Doublet airfoil substrates with a height of 31.75 mm and a channel width (measured between the origins of the inner convex and concaves surfaces) of 16 mm were mounted between 3 mm wide flat mounting plates, as shown in FIG. 20A. The substrates were made from 303 stainless steel and shaped by wire-cut electric discharge machining. Depositions were performed for approximately 70 minutes. The substrates were not intentionally heated during deposition, however radiative heat from the electron beam-vapor source interaction resulted in the substrate reaching a temperature of 150° C. (T/Tₘ=0.243) during the depositions. Experimental depositions were performed at a chamber pressure of 22 Pa and pressure ratio of 5.45. After deposition, samples were cross-sectioned at the midpoint between the pair of 40 mm×32 mm rectangular mounting plates, polished, and imaged in an SEM.

An investigation of coating thickness variations over both the inner and outer surfaces of the doublet substrate coating investigated here has been recently reported. ¹⁴ Furthermore, the microstructure of the coating deposited on the outer surfaces of the doublet substrate investigated here were found to be very similar to those observed on a single airfoil substrate as long as the doublet airfoil channel width (8-16 mm here), FIG. 20A, remained smaller than the incident vapor plume whose width ranged from 110 mm at 1 Pa to 75 mm at 100 Pa. The reader is referred to the earlier study for a discussion of the microstructural variation around the exterior surfaces of a single airfoil substrate.

The nickel vapor IAD determined from DSMC simulations was used to determine the average skew and breadth of the impact angles of depositing vapor atoms. For stationary vapor deposition onto a flat sample oriented at right angles to source—sample direction and placed directly over the epicenter of the source, the IAD changes slowly with position across the substrate surface (ref). However, the introduction of substrate rotation causes the distribution to vary with the angle of the rotation. Furthermore, when deposition is performed on a complex shaped substrate, significant IAD variation across the substrate also occurs during both stationary and rotated deposition. This IAD variation in turn, results in microstructure variations over the substrate surface.

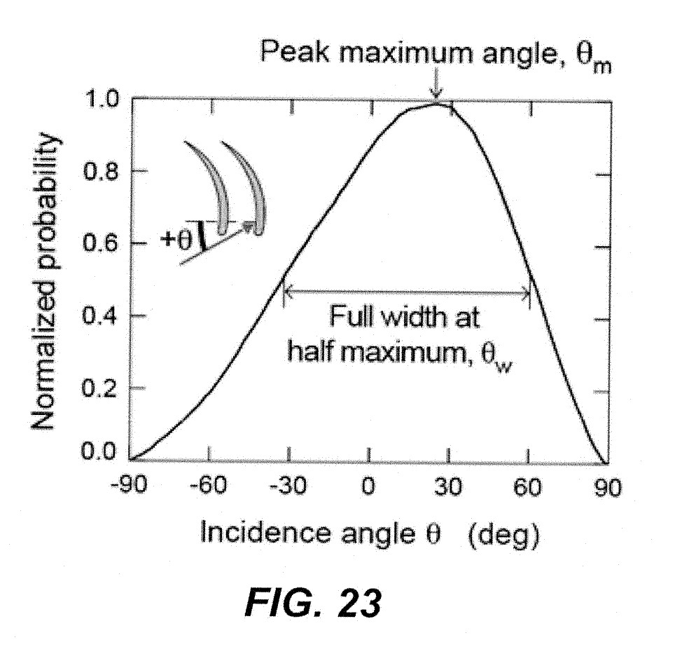

The IADs at two locations (3.39 and 42.9 mm from the origin) along the inner convex surface for a stationary simulation at α=0 are shown in FIG. 23. The IAD can be reasonably well characterized by its full width at half maximum, θ_{w} and the angle, θₘ of most probable impact, FIG. 23. It can be seen that that the IAD parameters go through a gradual transition between the two locations shown. From the leading to trailing edges, θ_{w} slowly increases while θₘ gradually approaches the local surface normal. Even though the surface region along this surface trajectory changes from being directly within line-of-sight of the vapor source through a NLS configuration, gas phase scattering from the confined jet flow through the channel prevents any sudden variations in the IAD.

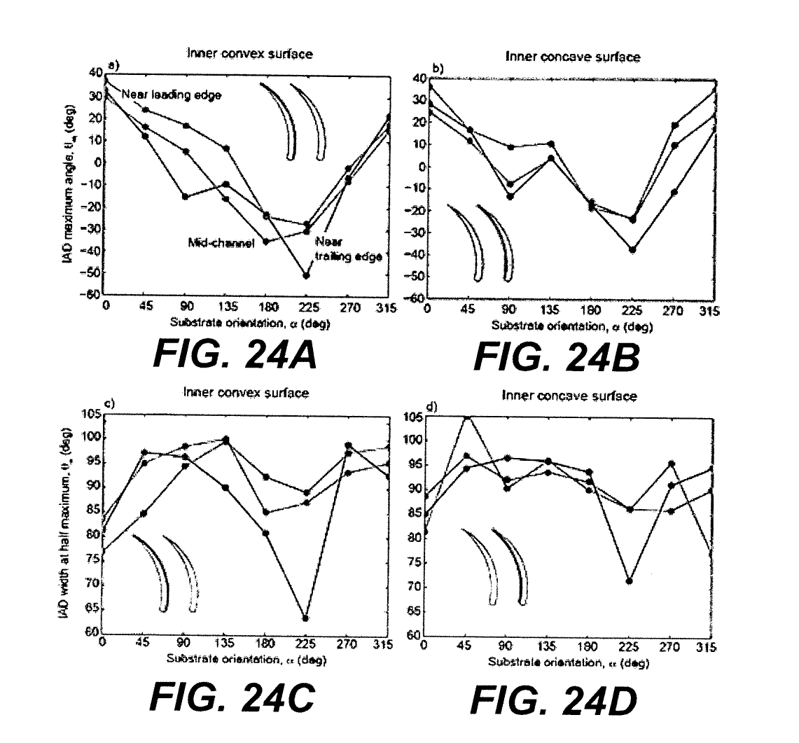

The variation of θₘ and θ_{w} are shown along the inner surfaces at the eight (8) stationary substrate orientations used for simulations of rotated deposition at a chamber pressure of 22 Pa, pressure ratio of 5.45, and channel separation of 16 mm are shown in FIGS. 24A-24D. To simplify presentation of the results, the inner substrate surfaces were divided into thirds. For orientations where one of the channel openings was reasonably well aligned with the gas jet axis (α=0, 45, 180, and)315°, significant channel penetration by the gas jet occurs and θₘ was quite large (up to ˜30°) but varied little along the entire surface, as shown in FIGS. 24A and 24B. At orientations where the channel was perpendicular to the gas jet (α=90° and 270°), θₘ was more strongly dependent upon position and typically oriented towards the nearest channel opening. The average magnitude of θₘ was also reduced.

FIGS. 24C and 24D show distribution width, θ_{w} for each orientation. At orientations where significant vapor flow penetrated into the channel (α=0 and 225°) the distribution was narrowest near the channel opening closest to the vapor source. The most notable case was found at α=225° where θ_{w} near the trailing edge (the black line) was 20° less than further along the channel. This decrease in θ_{w} also corresponds with an increase in magnitude of θₘ. Many vapor atoms were deposited on this surface from trajectories roughly parallel to the jet flow direction within the channel. At orientations with minimal channel penetration (α=90 and 270°), θ_{w} was typically large and remained mostly uniform along the channel length.

The IAD maximum and width values along the surface show that the vapor plume's properties quickly equilibrate as a flow entered the channel. Near the channel endpoints, the distribution was narrower and more skewed from the local substrate normal. Deposition in these regions was highly influenced by the specific gas jet environment, as vapor atoms near the substrate surfaces required few scattering collisions to deposit on the substrate and their trajectories retained much of their pre-channel entry character. Along channel regions far from either endpoint, vapor atoms had typically experienced multiple scattering collisions before deposition, and arrived from a broad range of incident angles.

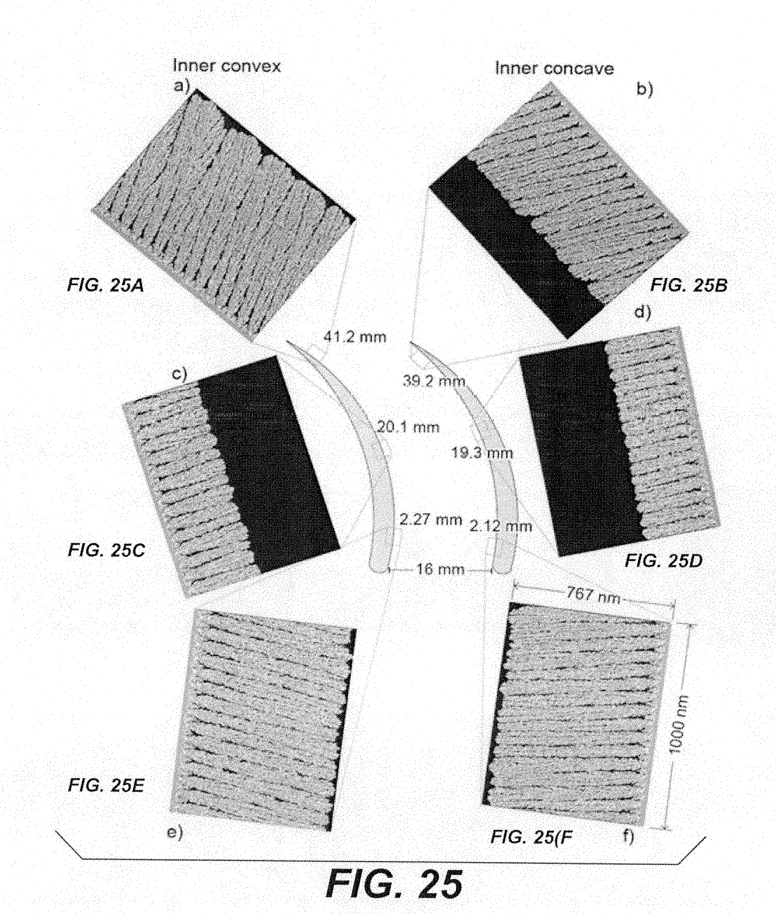

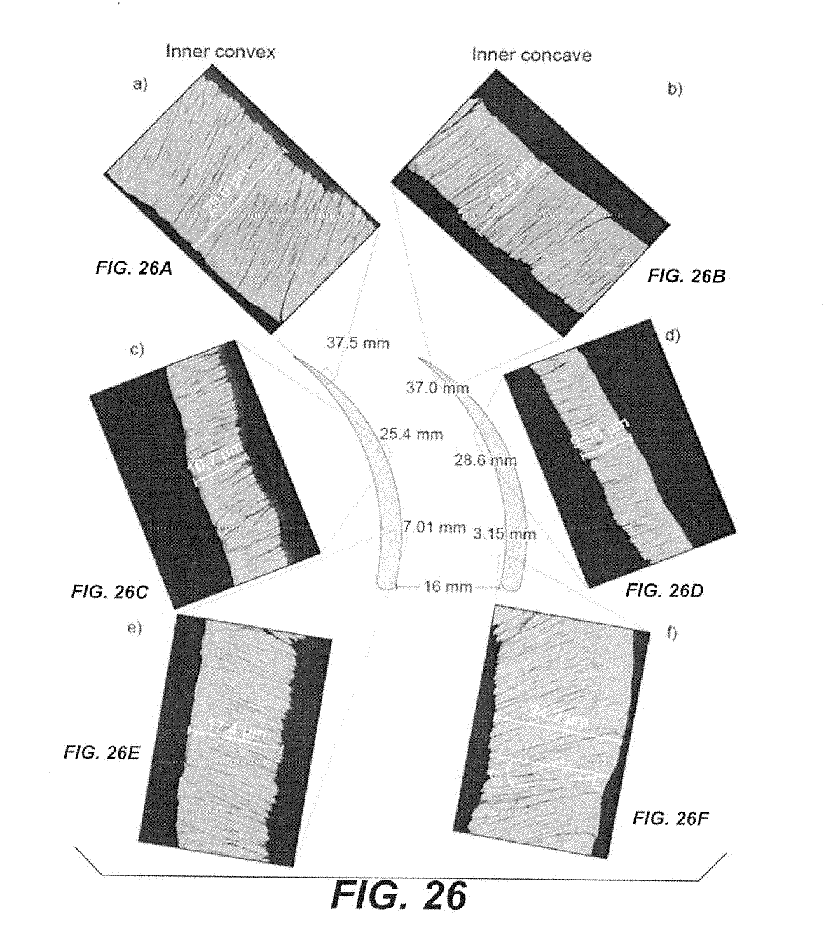

Examples of kMC simulated coating microstructures at three locations along the inner convex and concave surfaces are shown in FIG. 25. The simulations were performed at a chamber pressure of 22 Pa, with a pressure ratio of 5.45, and a channel width of 16 mm using a simulated rotation rate of 6 rpm. A continuous coating was deposited along the inner surfaces. However, there were variations in the coating thickness and microstructure along each surface. Under these deposition conditions, the coatings were thickest near the channel endpoints, while the thinnest regions occurred at the midpoints of both interior surfaces. The coatings were columnar everywhere, but the columnar growth angle varied with location. The growth columns were oriented towards the nearest endpoint, and the magnitude of φ decreased away from these endpoints resulting in columns oriented perpendicular to the airfoil surface near the channel midpoint.

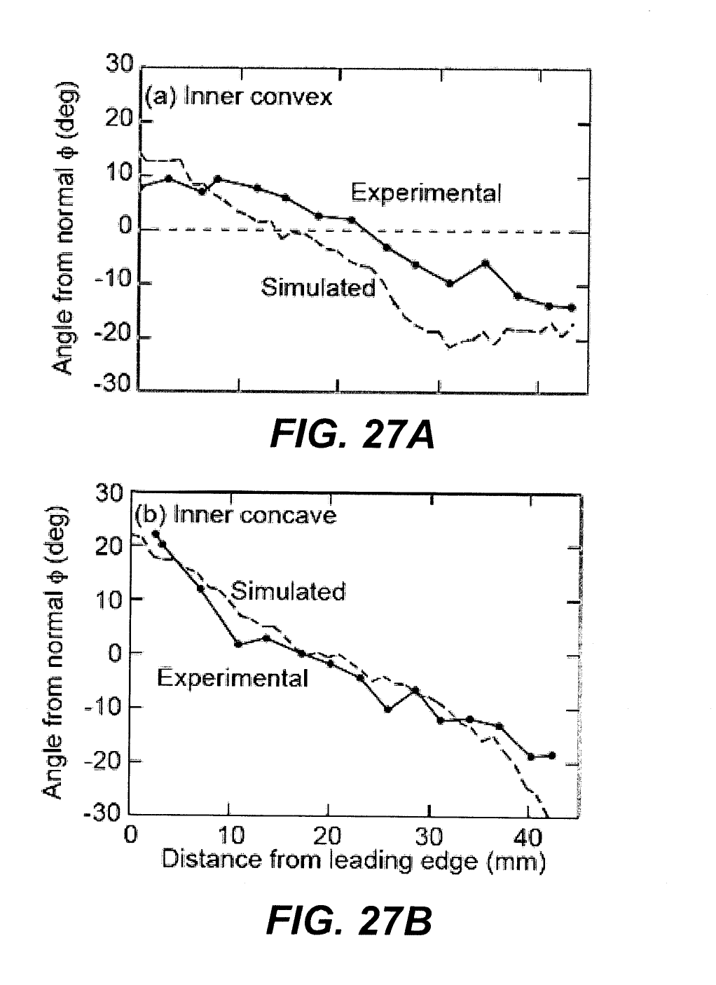

Experimental depositions were performed using the same deposition conditions to verify the simulation results. The resulting experimental microstructures are shown in FIGS. 27A and 27B. Like the simulation results, the coatings had a columnar structure. The coating thickness was greatest at the leading edge and trailing end of the airfoils, and thinner near the midpoint of the airfoils. Again, like the simulations, the growth columns were inclined towards the nearest end of the airfoil and were approximately perpendicular to the airfoil surface near the airfoil midpoints.

The average growth column angle has been measured for the experimental coatings as a function of the location coordinate along the two interior surfaces of the doublet and is shown in FIGS. 27A and 27B. The orientation angle of the experimental coatings had a standard deviation of 5° at each location of measurement. This variability appeared to be a consequence of the substrates surface roughness. A comparison with the simulated coatings columnar growth angle distribution is also shown in FIGS. 27A and 27B for comparison. The growth angle profiles for the simulation and experiment were in good agreement. The largest growth angles (of approximately 30° on the inner concave surface) occurred near the channel endpoints and progressively decreased to zero degrees at the midpoints of the airfoil surfaces. The growth columns of both the experimental and simulated coatings were less inclined at the leading and trailing end of the convex airfoil surface (approximately)10-15° but again, this decreased to zero at the convex surface midpoint.

Previous studies have shown that the thickness uniformity on the interior surface of the doublet airfoil substrate was strongly dependent upon the channel width and so its influence upon the coating microstructure is investigated in the following section. Many studies have also shown that columnar coating structure can by modified by manipulation of the process parameters used during deposition. The DVD method simulated here allows the deposition chamber pressure and the pressure ratio upstream/downstream of the choked inlet nozzle to be independently varied, and their effects upon the microstructure are also investigated.

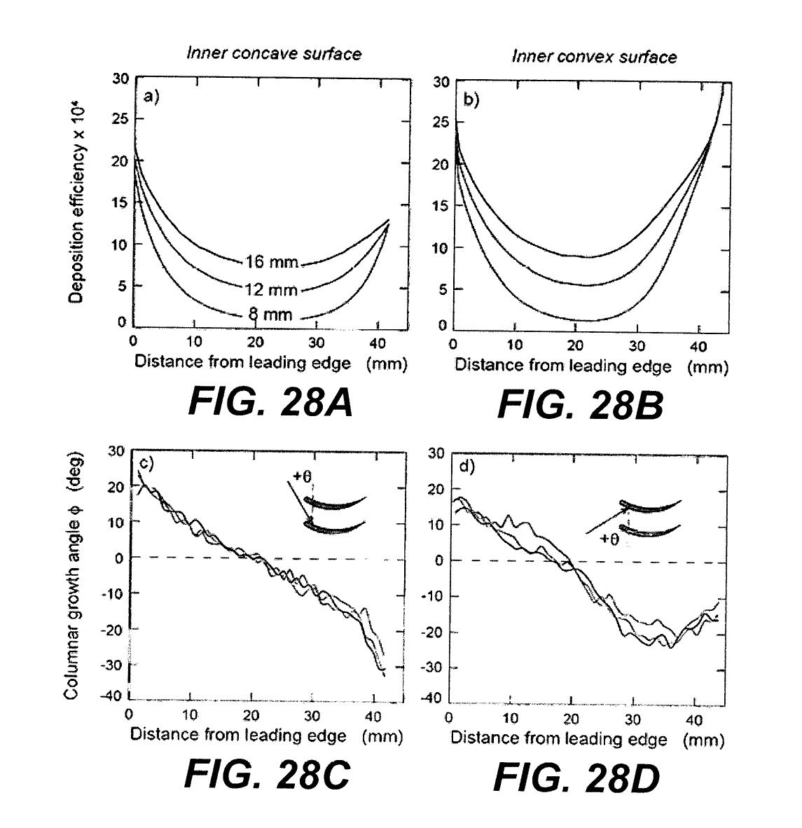

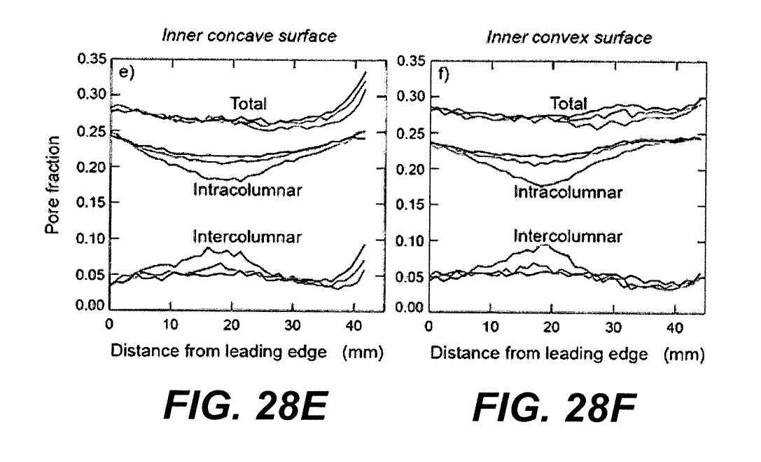

The fraction of evaporated material that is deposited on inner doublet surfaces is highly dependent on the channel width between the pair of airfoils. The simulation procedure described above have therefore been repeated using doublet substrates with channel widths of 8, 12 and 16 mm. FIGS. 28A-28F show the variation in local deposition efficiency, the columnar growth angle, and coatings porosity as a function of position along the two interior airfoil surfaces. During the simulations, the chamber pressure was fixed at 16 Pa, the upstream/downstream pressure ratio was 5, and a simulated rotation rate of 6 rpm was used. The deposition efficiency is shown in FIGS. 28A-28F for the inner concave and convex surfaces. Since the local deposition efficiency scales the local thickness (provided the porosity remains constant), the profiles are surrogates for the coating thickness. The results show that the coating thickness at the leading edge and trailing ends of the airfoils is unaffected by the channel width, that thickness at the channel midpoint is strongly dependent upon this parameter. The non-uniformity of the thickness decreases progressively with increase in channel width on both surfaces.

The variation of the columnar growth angle along each interior surface is shown in FIGS. 28C and 28D. Changing the airfoil separation distance had little effect upon the variation of growth column angle with position on the interior surface. FIGS. 28E and 28F show the total pore fraction as well as the intercolumnar and smaller-diameter intracolumnar porosity as functions of location along each interior surface for the three airfoil separation distances. The total pore fraction showed little variation with channel width. However, the intra-and-intercolumnar pore fraction components showed a more significant variation near the midpoint of the airfoils. The smallest 8 mm channel width substrate (with the most severe NLS region) showed a modest decrease in small-scale intracolumnar porosity and complimentary increase in large intercolumnar pore fraction near the channel midpoint where the NLS effect was most significant. This variation is consistent with the coatings in these regions having slightly denser columns and slightly wider gaps intercolumnar gaps. The coatings on all channel width substrates exhibited an increase in total porosity near the concave surface's trailing edge. This increase corresponded with the region of increased columnar growth angle.

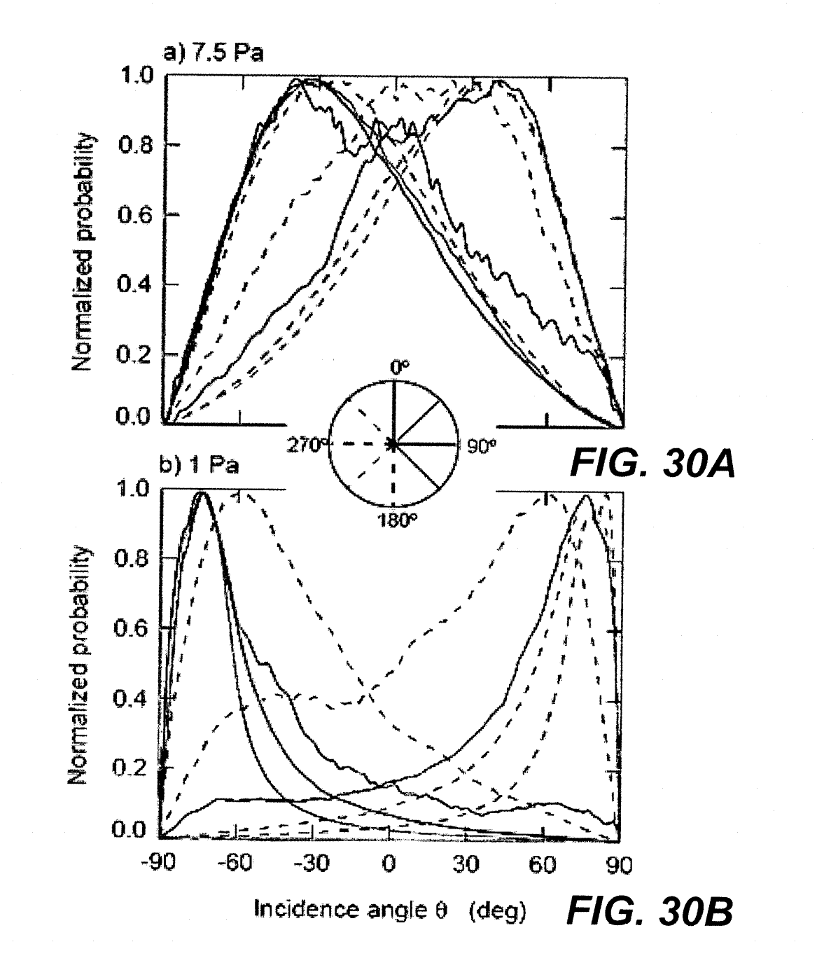

Simulations were conducted using chamber pressures of 1, 7.5, 16, 45, and 100 Pa. A channel width of 12 mm, a rotation rate of 6 rpm, and a pressure ratio of 5 was used for all simulations. The effects of deposition chamber pressure upon deposition efficiency, columnar growth angle and pore fraction versus location on the airfoil surface are summarized in FIGS. 30A and 30B. Deposition efficiency profiles along the inner concave and convex surfaces are shown in FIGS. 30A and 30B. They indicate that the coating thickness at the leading edge and trailing ends of the airfoils increases with the deposition pressure while that near the midpoint of the surfaces is maximized at chamber pressures of 16 to 45 Pa. Within this pressure range, the midpoint thickness was typically 25-30% that deposited at the airfoil ends.

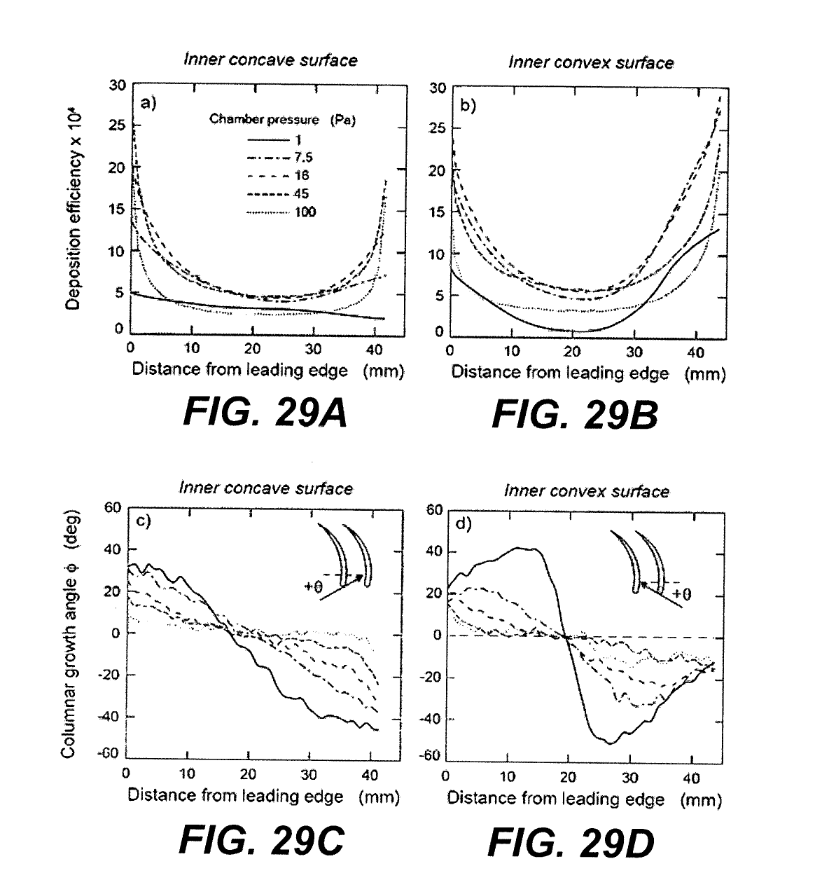

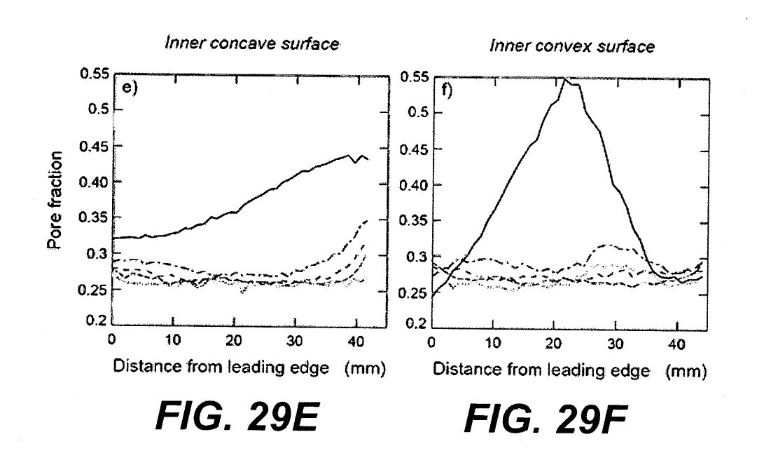

The coating's growth column angle was also significantly affected by chamber pressure. FIGS. 29C and 29D show the variation in growth angle with position on the two airfoil surfaces At all the pressures the highest growth column angles were found at the leading edge and trailing end of the airfoils, and the columns at the midpoint locations remained perpendicular to the airfoil surface all pressures. However, the angle of the growth columns at the leading edge and trailing end of the concave was inversely dependent upon the deposition pressure. There was almost no change in this growth angle along this airfoil surface for the highest (100 Pa) pressure deposition. The growth column angles on the convex surface also tended to decrease with pressure, but at the lowest pressures investigated, the location of the maximum angle shifted from the leading and trailing edges towards the interior of the airfoil. As a result, the convex surface coating applied at 1 Pa had a very short region near the midpoint where the growth columns were perpendicular to the coating surface.

The total pore fraction is plotted along the two surfaces in FIGS. 29E and 29F. In general, the porosity on both sides of the channel decreased as the pressure increased with the majority of the decrease occurring as the pressure was increased from 1 to 7.5Pa. On the concave surface, porosity increases with decreasing chamber pressure. The coating deposited near the midpoint of the convex surface at 1 Pa (the region most hidden from the vapor source) had a very high pore fraction (55%), almost double the value at any other condition. This porosity resulted from the growth of wide columns, with large columnar pore between them.

The significant variation in coating thickness, column orientation and pore fraction occurred as the chamber pressure was decreased from 7.5 and 1 Pa. At 7.5 Pa, the gas-phase mean free path length between collisions (MFP) was approximately 1 mm, while at 1 Pa, the MFP increased to ˜8 mm, leading to a significant reduction in the frequency of gas-phase scattering collisions within the channel. FIGS. 30A and 30B show the IADs for the eight simulation orientations at the midpoint of the inner convex surface for chamber pressures of 7.5 and 1 Pa (in subplots (a) and (b) respectively). An increase in θₘ and a corresponding decrease in θ_{w} is observed at all orientations as the pressure was decreased from 7.5 to 1 Pa. At 1 Pa, incident atoms primarily deposit from glancing angle-trajectories from both the leading and trailing edges of the channel (depending on orientation). This leads to significant increase in flux shadowing and a corresponding increase in the coating porosity.

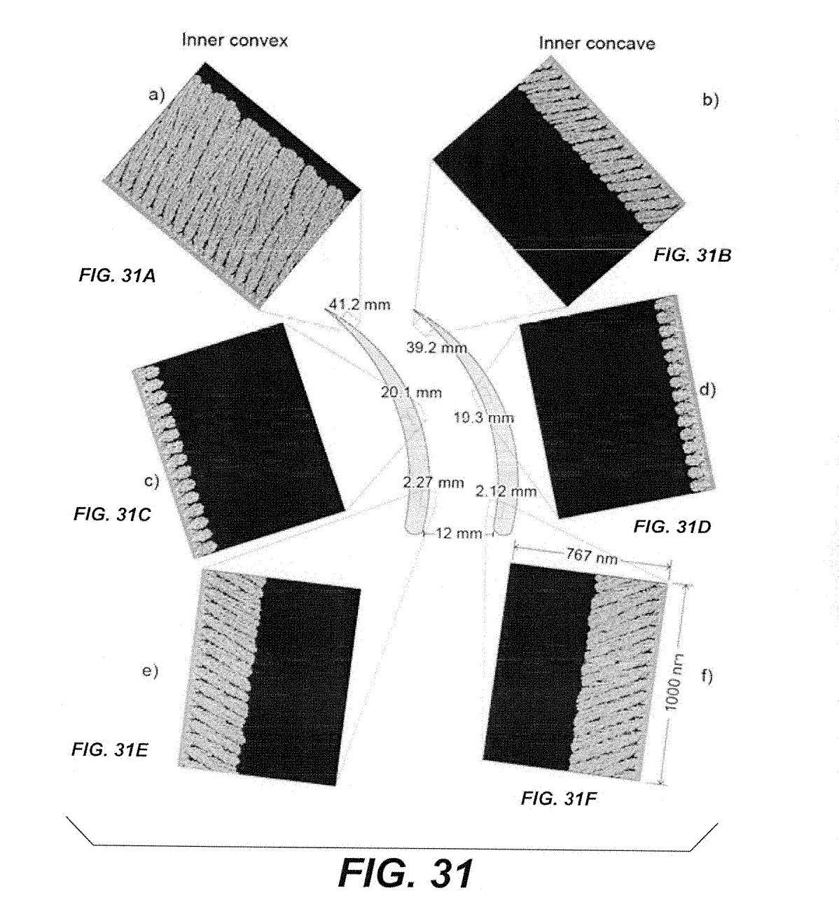

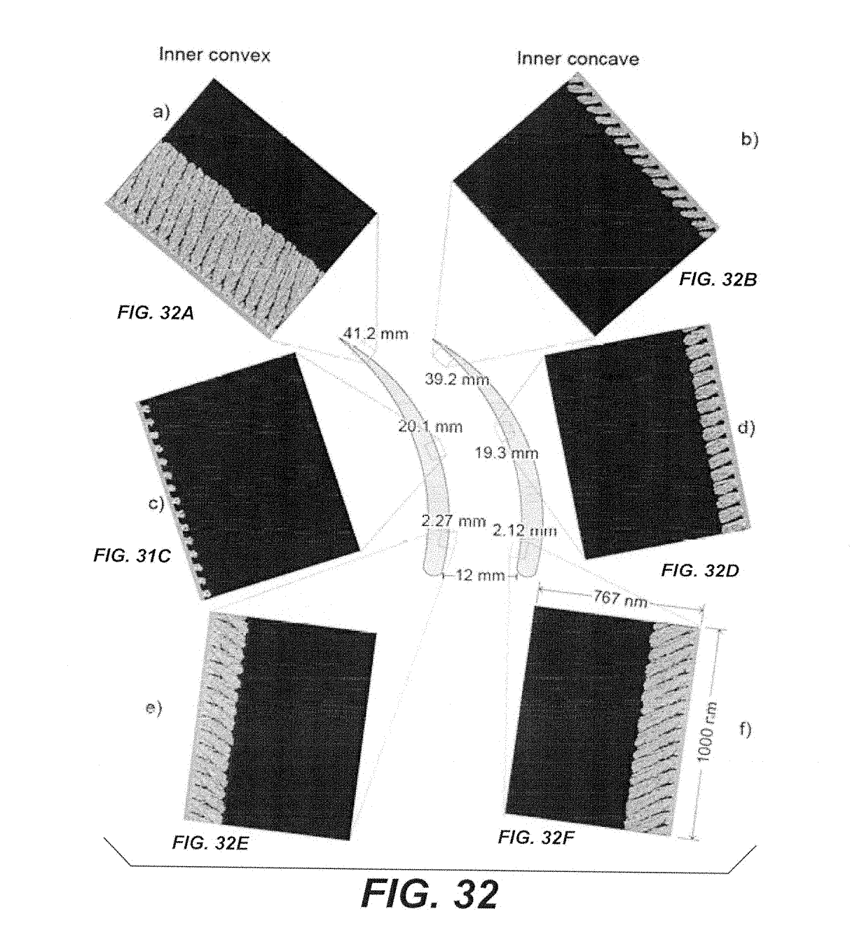

The simulated coating microstructure for coatings deposited at 7.5 Pa are shown in FIG. 31, while those deposited at 1 Pa are shown in FIG. 32. While the coatings show similarities in coating structure at many of the regions near the channel openings, significant differences can also be seen. At the midpoint of the convex surface (location (c) in FIGS. 31 and 32), both coatings are thin compared to the ends of the airfoils. However, the coating deposited at 7.5 Pa had a thin but continuous coating along the central region of its surface. However, the coating deposited at 1 Pa received very few atoms in this central region, resulting in widely separated column nucleation events and very large intra columnar gaps with poor substrate coverage. Large columnar gaps are also present at other locations on the coating deposited at 1 Pa; notably locations (b) and (d) where the incident flux was again very low. It is also evident that depositions at the end locations was dominated by flux that penetrated the leading or trailing edge gaps (whichever was closest to the source during rotation), resulting in significant inclination of the column growth angle towards the nearest opening.

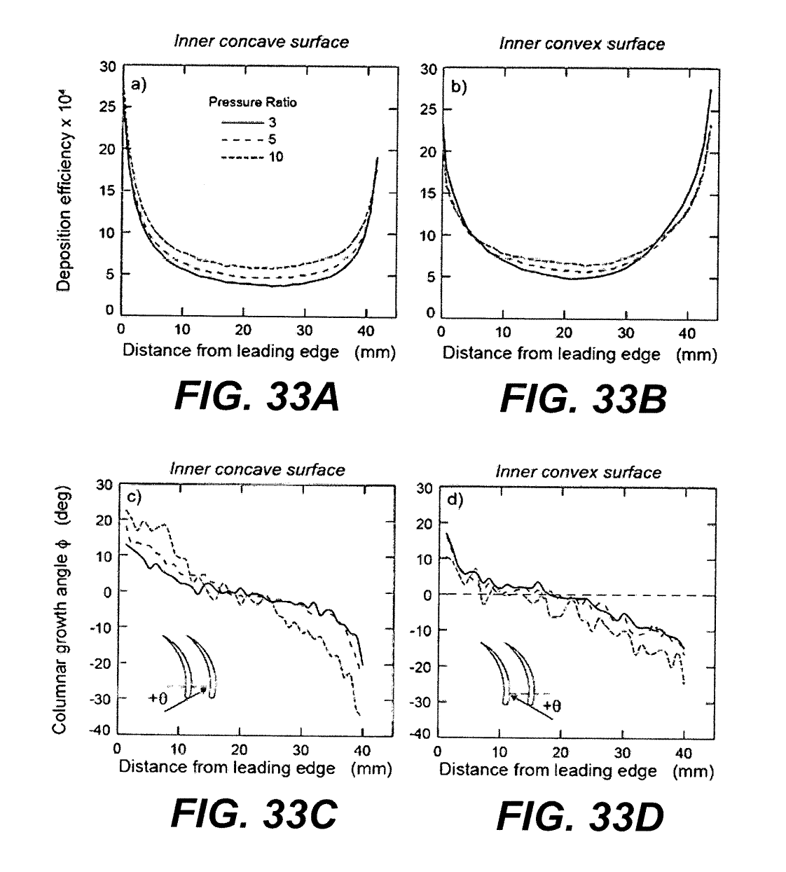

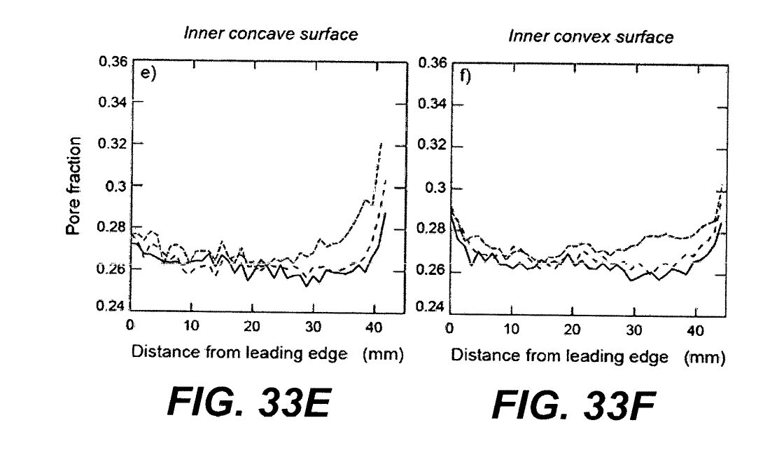

The pressure ratio upstream and downstream of the carrier gas inlet controls the gas jet velocity with higher pressure ratios resulting in faster jet velocities. The effects of varying the pressure ratio from 3, to 5 and finally 10 up on deposition efficiency, columnar growth angle, and pore fraction are shown in FIGS. 33A-33F. All simulations were performed with a chamber pressure of 45 Pa, channel width of 12 mm, and rotation rate of 6 rpm. The deposition efficiency profiles are shown along the inner surfaces for the three pressure ratios in FIGS. 33A and 33B. Increasing the pressure ratio slightly reduced the coating thickness at the ends of the airfoils but increased that at the midpoint locations, especially on the concave inner surface. This resulted from a reduction in the time available for vapor atom scattering onto the interior surfaces as the gas flow started to propagated through the channel between the airfoils. ¹⁴ This led to a higher retained vapor atom concentration at the midpoint locations and a thicker coating.

The effect of increasing the pressure ratio upon the columnar growth angle is shown in FIGS. 33C and 33D. The growth angle, especially at the airfoil ends, increased with increasing pressure ratio, and resulted from increasingly skewed IADs at higher pressure ratios. Increasing the pressure ratio resulted in a higher fraction of the vapor impacts with a highly inclined trajectory at these faster flow velocities. The porosity variation with pressure ratio is shown in FIGS. 33E and 33F, and shows that the pore fraction was highest at the ends of the airfoils where the incident flux was more likely to make a glancing impact with the surface. Increasing the pressure ratio in these regions then further increased the fraction of glancing impacts and thus the likely hood of local flux shadowing by locally high features (growth column tips) on the growth surface.

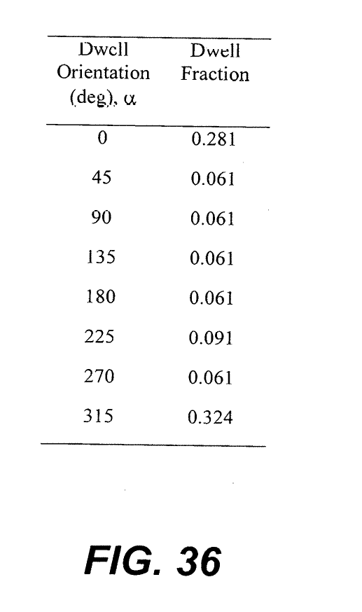

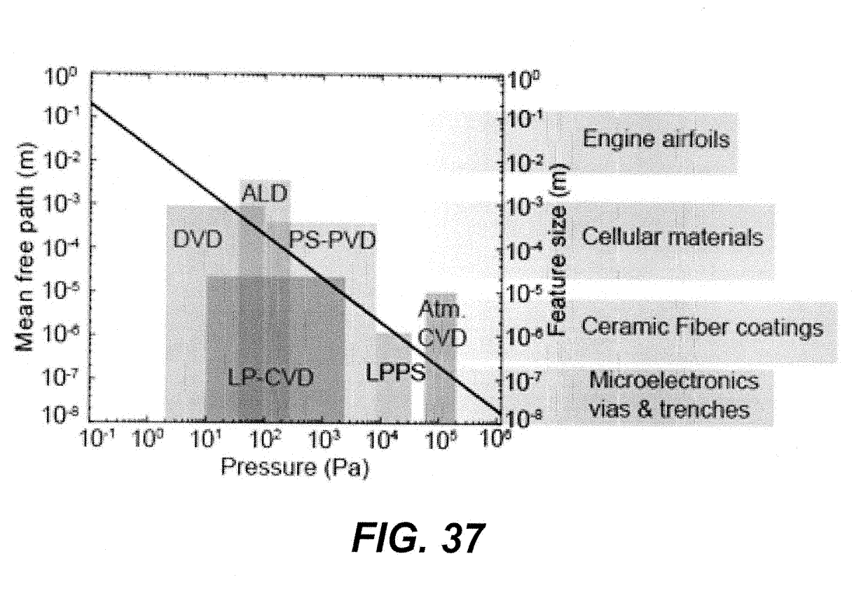

A recent study showed that by varying the rate of rotation during a rotational period, it was possible to deposit coatings whose variation in coating thickness between inner and outer airfoil surfaces was almost the same. This modified (optimized) rotation scheme increased the flux received from a few substrate orientations while decreasing it for others. To evaluate if this adversely affected the coating microstructure, a simulated coating was deposited using the optimized dwell fractions for a chamber pressure of 45 Pa, a pressure ratio of 5.0, and airfoil channel width of 12 mm, as shown in FIG. 36. This optimized rotation scheme varied the rotation rate between 2 and 32 rpm.

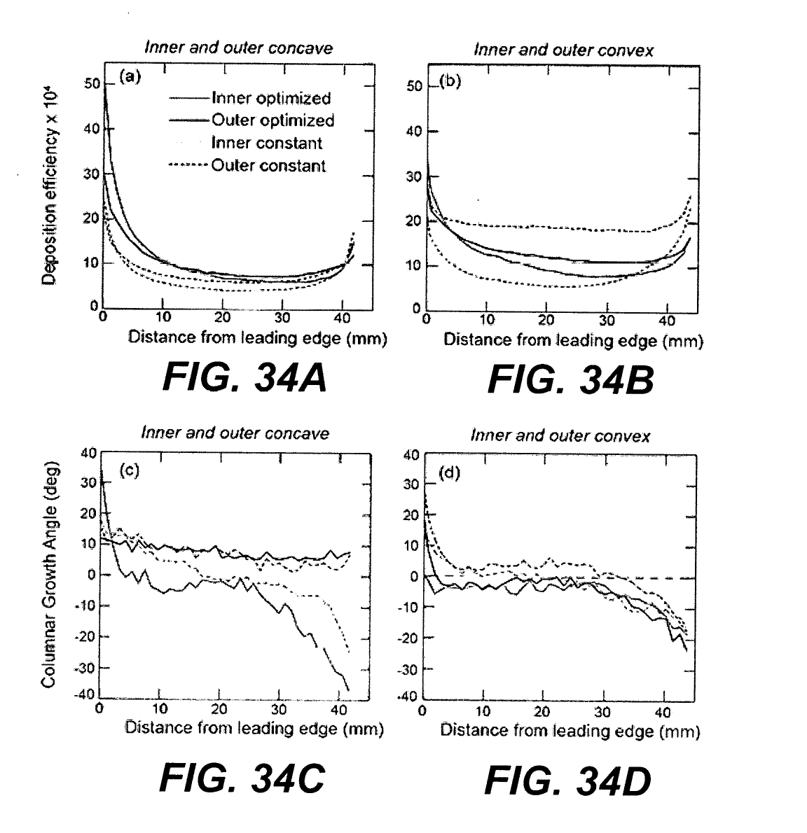

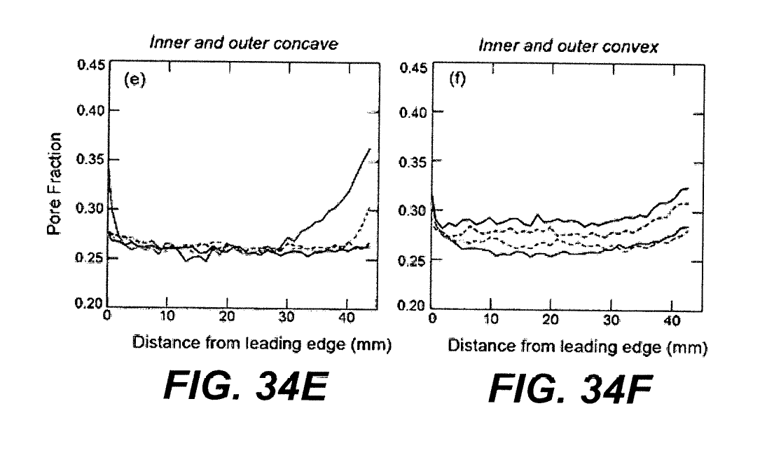

The resulting deposition efficiency, growth angle, and pore fraction profiles for both the inner and outer surfaces are shown in FIG. 34A-34F and compared to an otherwise identical simulation that used a constant rotation rate of 6 rpm. The coating deposited on the inner and outer concave surfaces using the optimized rotation pattern were both thicker than of those of the constant rotation coating. This arose because the optimized rotation increased the dwell fraction while the ends of the airfoils were close to, and in the line-of-sight of the vapor source, the leading edge coating thickness was substantially increased over the constant rotation case. Deposition of a coating the convex surfaces using the optimized rotation procedure increased the deposition efficiency on the inner surface and decreased it on the outer surface. These changes then combined to significantly decrease the coating thickness differences between the four surfaces.

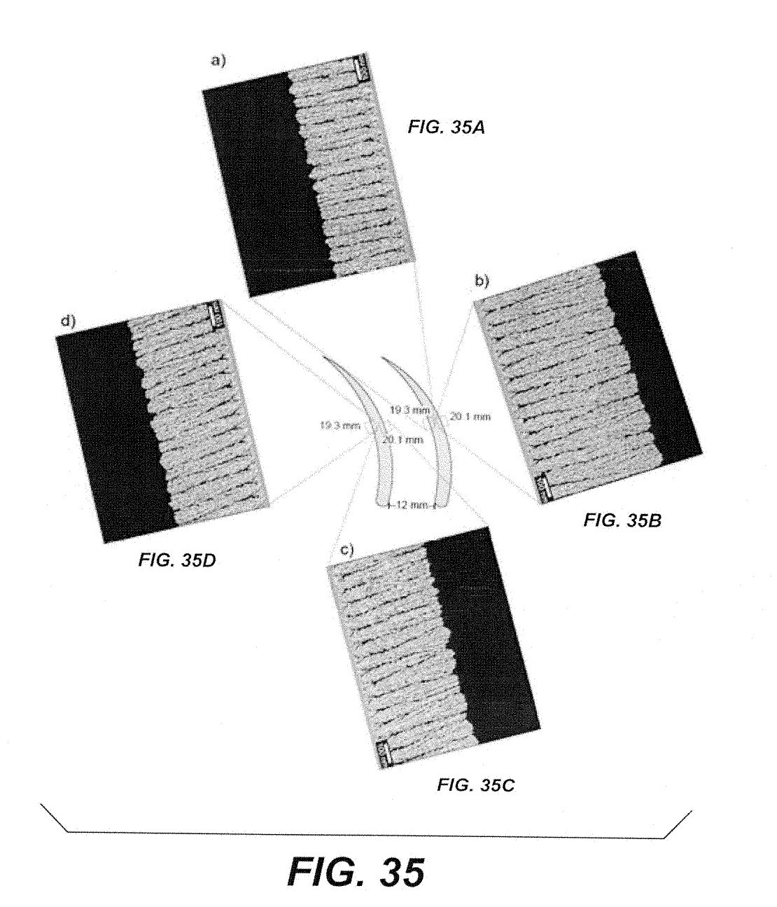

The columnar growth angles as a function of position along the airfoil surfaces is in FIGS. 34C and 34D. The optimization resulted a modest increase in the columnar growth angle at the end of the inner concave surface (from 35 to) 45°, but otherwise had little effect along all other surfaces. FIGS. 34E and 34F shows that the pore volume fraction in the optimized coating also increased in regions of the coating where the column inclination also increased. The most apparent new variation is near the ends of the inner concave surface. At the trailing edge, porosity increases by 7% over the uniform rotation result. Examples of the simulated microstructures at the four surface midpoints are shown in FIG. 35. They show that very similar thicknesses on all four surfaces are achieved by this optimized rotation scheme when practiced at this high pressure and pressure ratio. The coatings growth columns are also confirmed to be oriented normal to the substrate surface and contain similar levels of porosity.

Gas jet assisted physical vapor deposition (PVD) techniques operate at higher pressures than conventional PVD processes, and have been shown enable the coating of complex shaped substrates including those with non-line-of-sight (NLS) surface regions. The NLS regions were shown to receive a broader vapor atom incident angular distribution but with a lower flux. To investigate the consequence of such effects, the thickness and microstructure variation along the inner (curved channel) surfaces of a model doublet airfoil substrate containing NLS regions was investigated.
1. Both atomistic simulations and an experimental deposition using a nickel vapor source have confirmed that the coating's thickness in flux-shadowed regions is thinner than other regions.
2. The simulations and experimental deposition indicated that the coatings columnar microstructure and pore volume fraction varied slowly along the inner airfoil surfaces during the transition from LS to NLS deposition.
3. Largely NLS regions on the substrate are shown to contain extremely uniform porosity, while surface areas that spent a substantial amount of time in (or near) the line-of-sight of the source showed a greater variation in growth column angle and porosity content.
4. A substrate rotation strategy for maximizing the coating thickness uniformity successfully reduced the variation of coating thickness along all doublet airfoil surfaces and incurred only small changes to the columnar growth angle and pore volume fraction.

Physical Vapor Deposition on Doublet Airfoil Substrates: Controlling the Coating Thickness

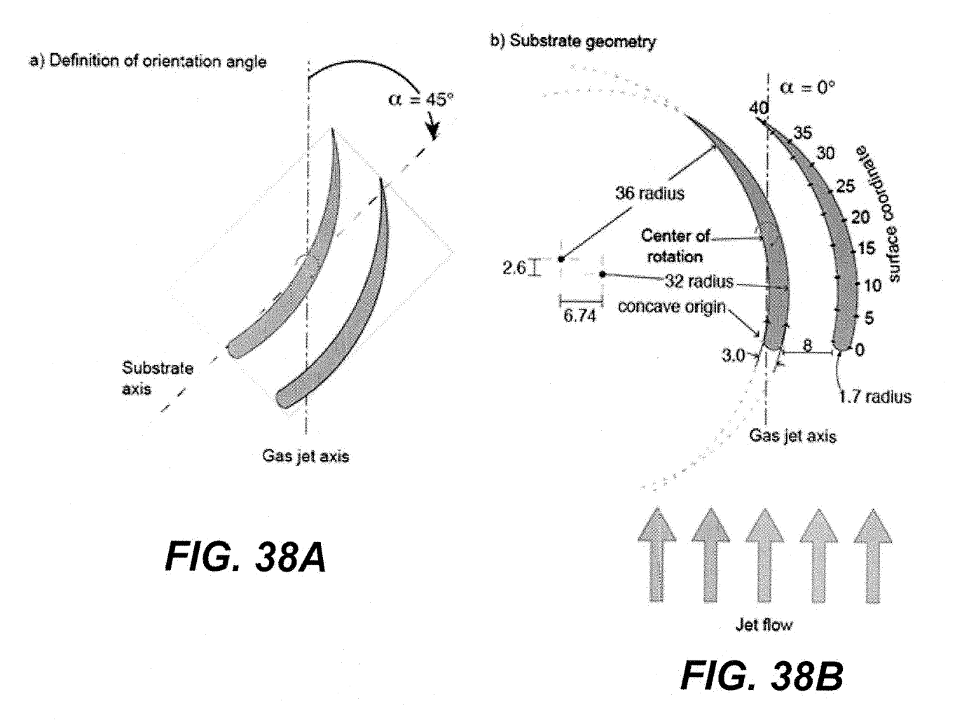

A doublet guide vane substrate geometry was designed for use in both experiments and simulations. Each airfoil was identical in design to that used in previous studies of deposition on single airfoil substrates. The geometry and dimensions of the 2D doublet substrate are shown in FIGS. 38A and 38B. The airfoils were placed parallel to each other and attached to flat mounting plates along their sides during experimental depositions. The channel width between the airfoils was defined as the distance between the inner convex and concave surface origins (indicated on the schematic). The width was varied between 8, 12 and 16 mm. The local channel width varied slightly along the channel due to the differing radii of the convex and concave surfaces. During deposition, the substrate was rotated clockwise around the center of rotation, defined as the center of the rectangle that completely encompassed the airfoil pair. A rotation angle □ was defined between the center of the gas jet and airfoil axis (both pass through the center of rotation) defined as shown in FIG. 2(a). At α=0° the two axes are coincident.

Surface regions along the interior of the doublet substrate experience a significant portion of the deposition process out of the line-of-sight of the vapor source. The degree of shadowing experienced by these regions varies significantly with the channel width of the substrate. The strictest definition of a NLS region is a surface area that is inaccessible to any vector originating outside of the substrate's volume. The only substrate configuration studied here that meets this criteria is the 8 mm channel width, which has a permanently NLS area approximately 1 mm in width. However, the inner channel regions at all channel widths are shadowed from the material source for most of a rotation cycle. These “near-non-line-of-sight” conditions appear more common in doublet vane geometries. When the gas phase MFP is significantly smaller than the substrate's characteristic length (e.g., the channel width in this study), deposition into NLS regions is controlled by the dynamics of the flow.

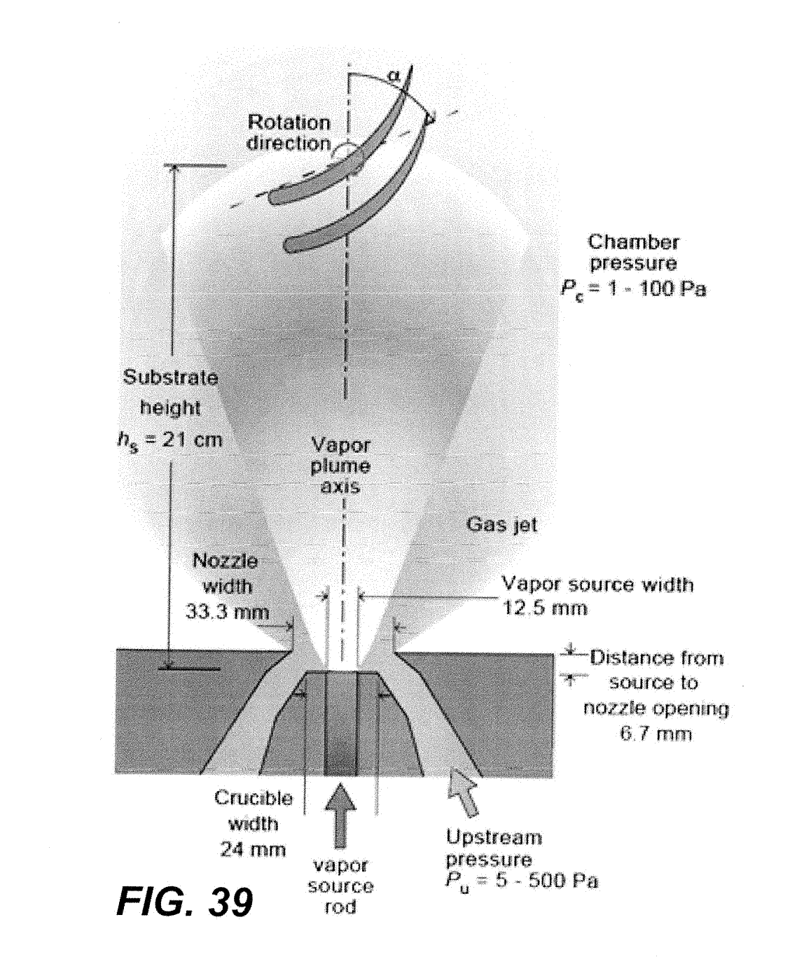

A schematic of the EB-DVD deposition geometry used for experimental and computational studies is shown in FIG. 39. Detailed descriptions can be found in references. Briefly, the system used a high-voltage electron beam gun to evaporate a solid source rod located in the throat of a gas jet inlet nozzle. The evaporant was entrained in a carrier gas jet and accelerated towards the substrate. The velocity of the gas jet (composed of 90 at. % He and 10 at. % O₂) was controlled by the pressure ratio upstream and downstream of the gas inlet nozzle. Larger pressure ratios result in higher jet velocities. ^{15,36,37} The maximum jet velocity is given by:

$${V}_{max} = \sqrt{γ {R}_{s} {T}_{d}} \sqrt{\frac{2}{γ - 1} ( {( \frac{{P}_{u}}{{P}_{d}} )}^{\frac{γ - 1}{γ}} - 1 )} , \qquad ( 14 )$$

where γ is the ratio of specific heats (5/3 for helium), Rₛ is the gas constant (2077 J/(kg K)) for helium, T_{d} is the gas temperature in K downstream of the nozzle, Pᵤ is the upstream pressure, and P_{d} is the deposition chamber pressure (downstream of the nozzle).

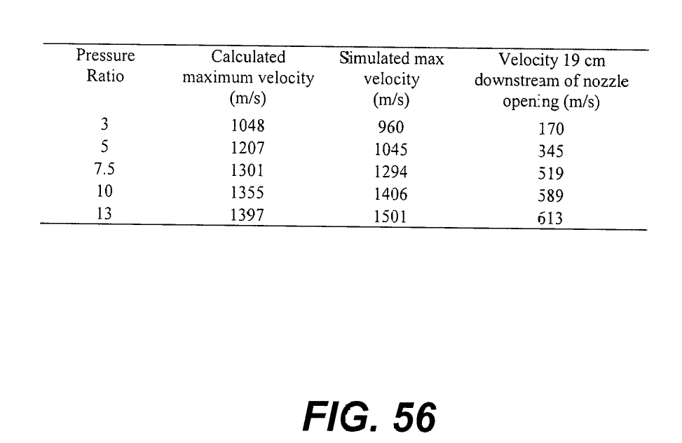

Flow velocities calculated with Equation 1 and measured from DSMC simulations at several pressure ratios are shown in FIG. 56. The DSMC simulations were performed at 45 Pa and used the simulation configuration shown in FIG. 39. Only carrier gas atoms were present in the simulations; no vapor was emitted from the source. The maximum velocities show good agreement between the calculated and simulated values. The simulated velocities on the flow axis 17 cm downstream of the inlet nozzle are also shown in FIG. 56, and demonstrate a significant reduction from the maximum jet velocity. These downstream velocities are more representative of flow conditions near the substrates.

The direct simulation Monte Carlo (DSMC) code Icarus developed by T. J. Bartel was used for the deposition simulations. DSMC is an atomistic method that models rarefied gas dynamics via direct simulation of the Boltzmann equation. The method uses a subset of virtual “test” molecules to model the behavior of the full ensemble of real molecules. Flow behavior is determined through a cyclic procedure of independent interatomic collision and collision-free propagation time steps. Icarus uses the variable hard sphere (VHS) molecular collision model, which simulates gas molecules as hard spheres with velocity dependent radii. The DSMC simulation method and its application to the simulation of vapor deposition has been described in detail elsewhere. ^{15,33,44}

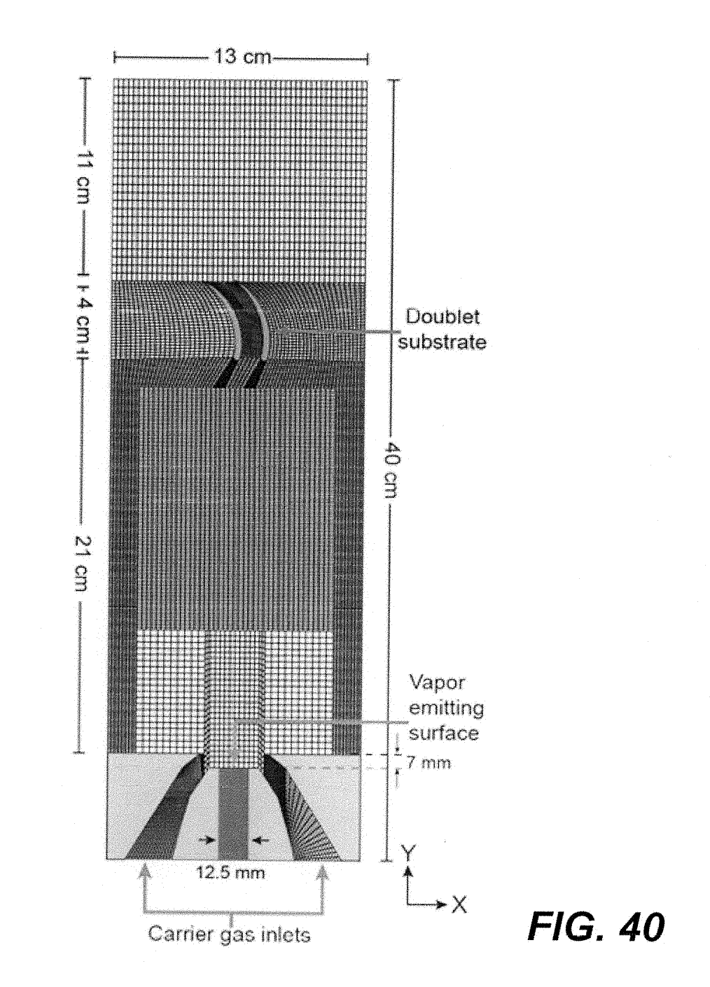

A simulation grid for the α=0° substrate orientation is shown in FIG. 40. The gas jet was formed by inserting gas molecules from the lower grid boundary into the high-pressure inlet region. These then entered the lower pressure deposition chamber through a choked nozzle. The vapor species were nickel atoms and were input as a constant flux of 8.8×10²⁰ atoms/m²s from the 12.5 mm wide solid grid boundary labeled as “vapor emitting surface” near the exit of the gas inlet nozzle. The VHS parameters for the Ni atoms were determined from their Lennard-Jones potential parameters using the procedure of Venkattraman. Chamber pressure was set by applying freestream boundary conditions along the vertical and upper grid boundaries. A two-dimensional Cartesian X-Y grid was used to model the doublet substrates.

During analysis of the simulation results, each convex and concave substrate surface was divided into forty grid regions. Each region on the concave surfaces had a width of 1.06 mm. The regions on the (longer) convex surface were 1.14 mm wide. As a surrogate for coating thickness, a local deposition efficiency for each surface region was determined. The local deposition efficiency was calculated as the number of atoms deposited in each region divided by the total number of atoms emitted from the vapor source. Summation of the deposition efficiency along the entire substrate results in the total fraction of emitted vapor that was deposited on the substrate.

Deposition onto rotating substrates was simulated by performing independent simulations at eight stationary substrate orientations (each separated by 45° of rotation). The resulting coating properties were then determined by summing the results from each orientation with equal weighting; equivalent to assuming a constant rotation rate. Simulations were performed for 75,000 unsteady time steps to reach steady-state conditions and then an additional 250,000 to accumulate flow statistics. They were performed on a Linux cluster and required approximately 24 hours of wall time using 16 Intel Xeon processor cores.

To verify simulation results, nickel coatings were deposited onto grade 303 stainless steel doublet airfoil using the EB-DVD technique. Experimental deposition conditions were quite similar to those used for deposition on a single airfoil. A 70 kV/2.45 kW electron beam was used for all depositions. A channel width of 16 mm was used, and substrates were rotated at 6 rpm. This rate was determined to be high enough to create a columnar microstructure with a constant morphology through the thickness of the coating. After deposition, the substrates were cross-sectioned, polished and examined in a scanning electron microscope (SEM).

The experimental substrate incorporated a pair of mounting plates to hold the airfoils in place and restrict access to the substrate channel only through the two ends of the doublet pair. These plates are neglected in the DSMC simulations, due to the two-dimensionality of the simulations. However, these plates will provide an additional vapor-sink in experimental depositions, resulting in less vapor depositing on the inner channel surfaces than predicted by the 2D simulations. To minimize this effect, the airfoil thickness (and spacing between mounting plates) was set at 31.75 mm; significantly larger than the inter-airfoil channel width, and the coating thickness was measured at the midline between mounting plates.

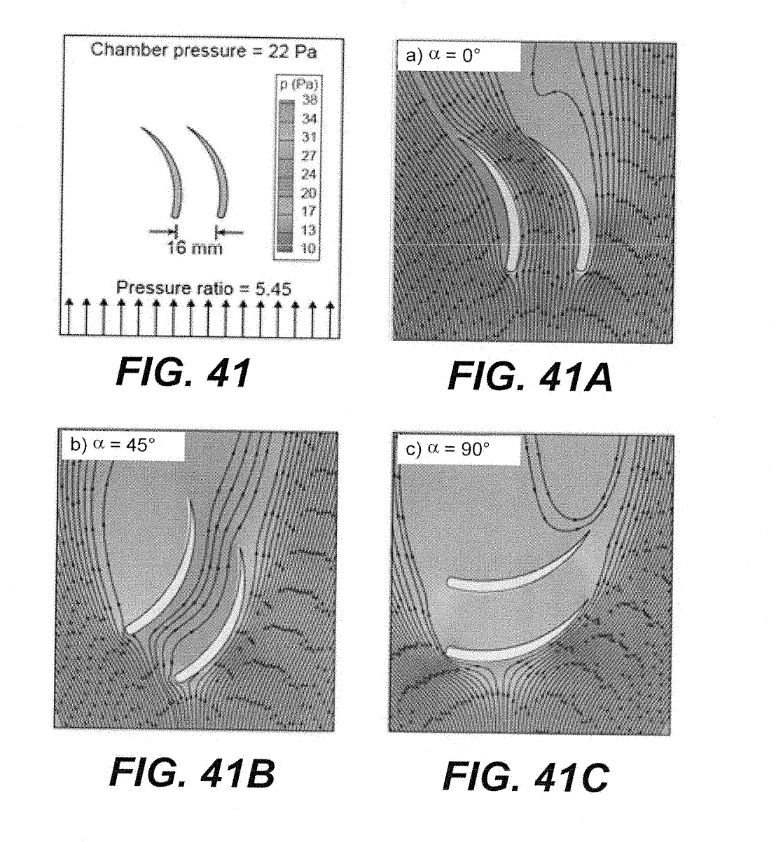

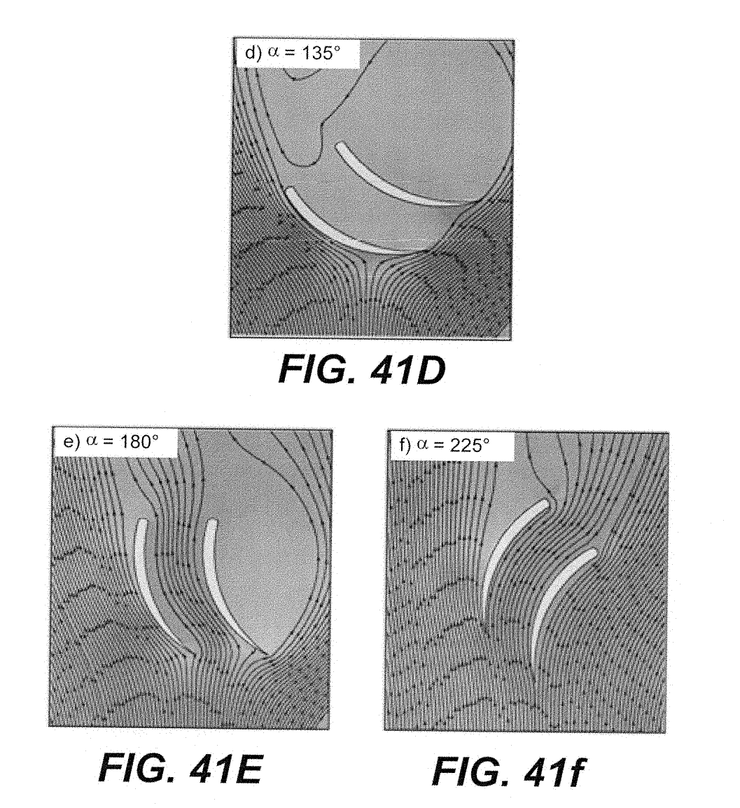

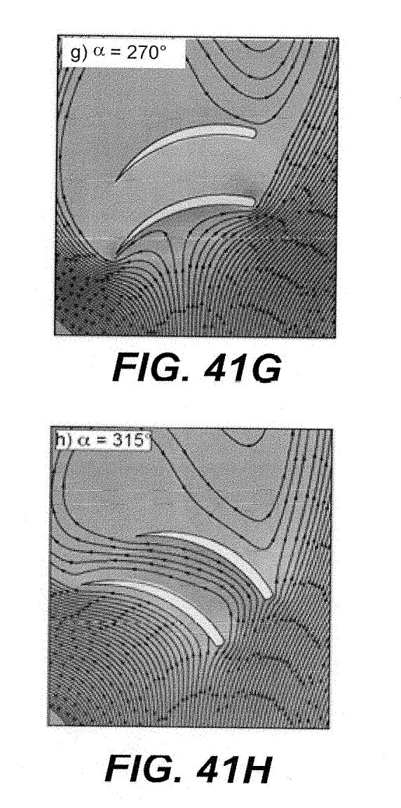

FIGS. 41-41H show DSMC calculated pressure contours and streamlines for the carrier gas jet near the substrate at the eight orientations used to simulate rotated deposition at a chamber pressure of 22 Pa, an upstream/downstream pressure ratio of 5.45, and channel width of 16 mm. The pressure contours show that the local pressure was slightly increased in the inter-airfoil region for those orientations that allowed significant flow through the channel. The in-channel pressure decreased significantly at orientations where the channel was perpendicular to the flow direction (α=90° and 270°). The highest pressures was observed at the outer substrate surface nearest the nozzle α=90° and 270°. In these regions, the flow stagnated against the substrate surface and led to an increase in local pressure. This dependence of the pressure near the external surfaces of the airfoils is very similar to that recently observed during deposition on a single airfoil substrate. FIGS. 41-41H also show streamlines corresponding to locally averaged carrier gas atom trajectories. Streamlines were calculated with an initially uniform spacing of 0.96 mm along a line perpendicular to the gas jet located 50 mm upstream of the substrate's leading edge. The streamlines show that laminar flow was maintained around the doublet at all orientations, even when the flow met a nearly perpendicular substrate surface, FIGS. 41C and 41G. At these orientations, there is very little flow into the inner channel region of the substrate. In addition, the chamber region immediately downstream of the substrate is shadowed from the gas jet at all orientations, and gas flow in this region is reduced. At locations where a channel opening faces the gas jet (as in α=315°), there is significant flow through the channel. Upon exiting the channel, the gas continues to flow primarily along the jet's axis.

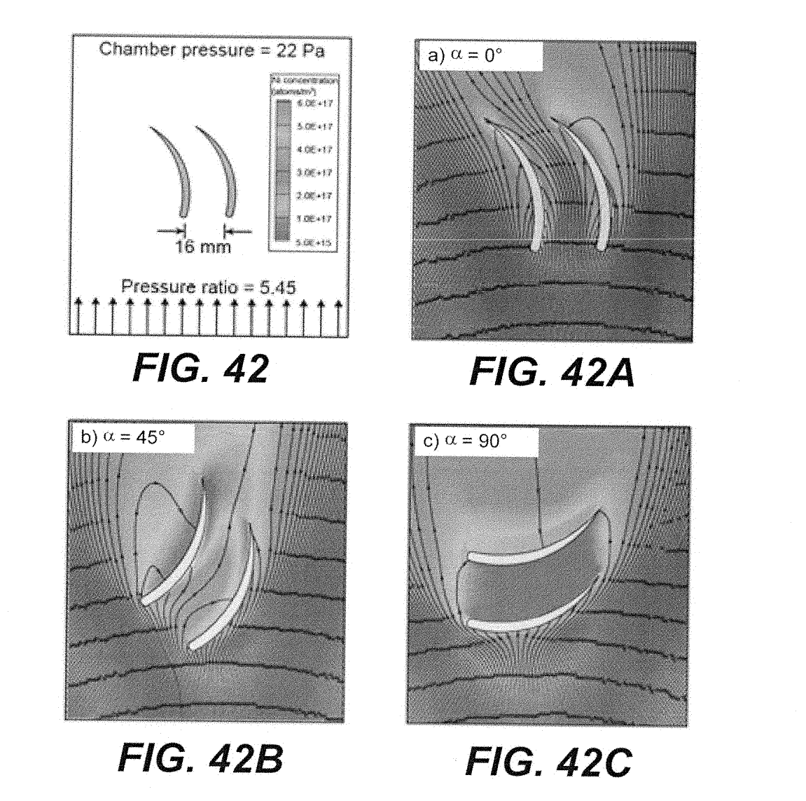

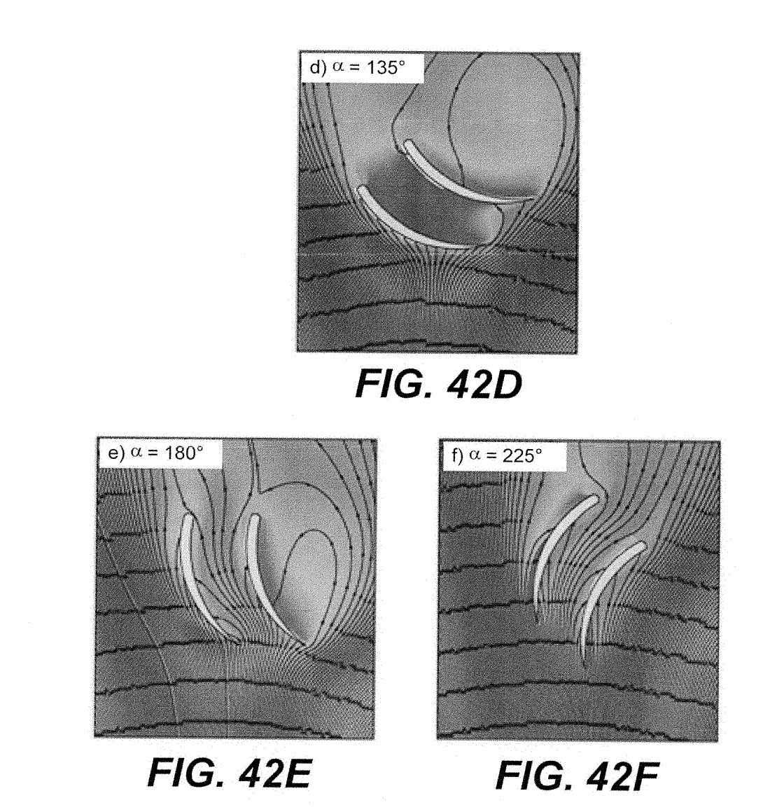

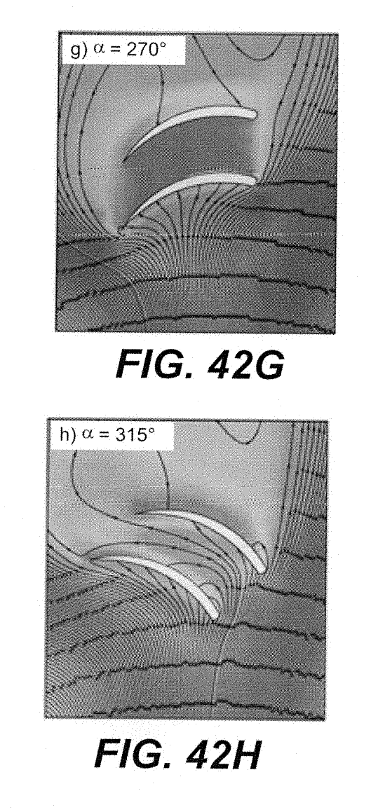

Contour plots of the vapor concentration at the eight substrate orientations are shown in FIGS. 42-42H for the same deposition conditions used for FIG. 5. Significant penetration of vapor into the channel occurred at α=0, 45, 180, 225, and 315° orientations. At these orientations, the vapor concentration was highest at the channel opening. The vapor concentration gradually decreased with distance along the channel's length as vapor was depleted by condensation onto the inner surfaces of the substrate. At the other orientations (α=90, 135, and 270°), line-of-sight deposition onto the exterior surfaces was dominant, with very little vapor entered the inter-channel region. Note that in all cases, a steep gradient in vapor concentration existed near the substrate surface.

Vapor atom streamlines representing locally averaged trajectories of vapor atoms are also shown in FIGS. 42-42H. The streamlines show that the vapor travels along laminar flow lines before depositing onto the substrate surface. In many cases, a significant amount of the vapor plume travelled beyond the substrate without depositing. Several streamlines also travel through the entire inter-airfoil channel without being deposited. At orientations where the channel was transversely aligned to the gas jet (α=90, 135 and 270°), very few vapor atom streamlines were present in the inter-airfoil channel region.

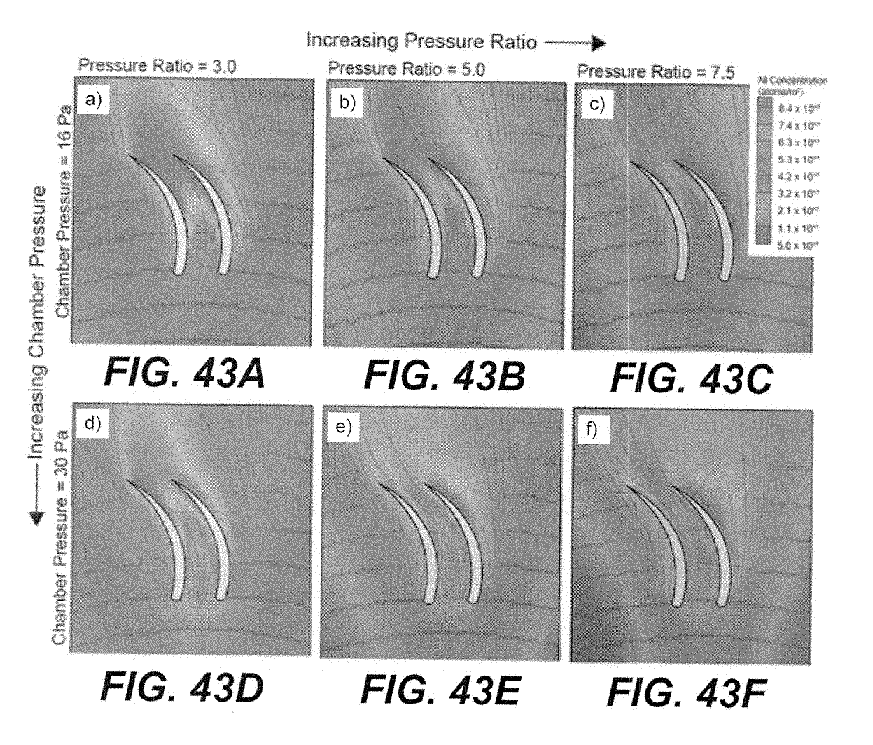

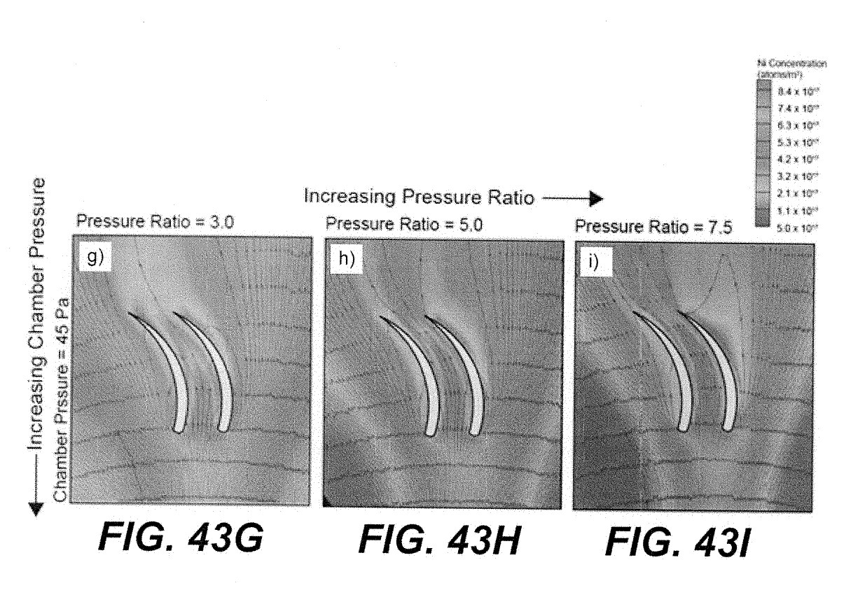

The variation in vapor atom concentration with deposition conditions is shown in FIGS. 43A-43I for the α=0° orientation case. The figure shows the effects of chamber pressure (which increases from the top to bottom) and pressure ratio (which increases from left to right). The concentration contours show that vapor penetration into the channel increased with both increasing pressure and pressure ratio. However, significant vapor concentration remains in the flow at the airfoil exit for the highest combinations of these variables, FIG. 43I.

Vapor atom streamlines are also shown in FIGS. 43A-43I. At the lowest pressure ratio and chamber pressure, as shown in FIG. 43A, few if any streamlines travelled the entire interior channel length, indicating rapid depletion of the vapor by condensation onto the interior airfoil surfaces. At high-pressure ratios, as shown in FIG. 43C, more of the vapor streamlines traveled through the channel, indicating some vapor was not deposited on the interior walls. For high chamber pressures and low-pressure ratios, FIG. 43G, significant vapor concentration existed through most of the channel, while little vapor travelled through the channel without condensing upon the interior surfaces of the doublet substrate.

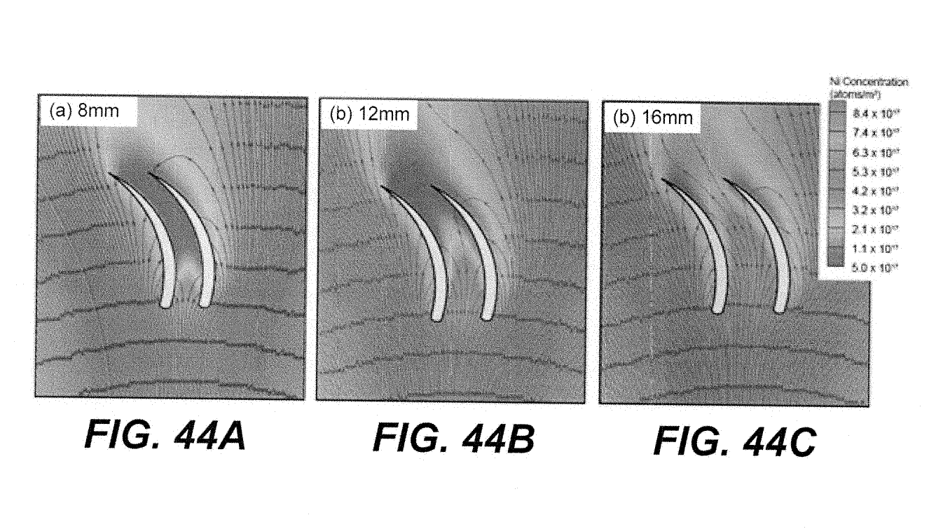

Variation of the inter-airfoil channel width also resulted in significant changes to the vapor flow. The vapor concentration contours and streamlines at channel widths of 8, 12 and 16 mm are shown in FIGS. 44A-44C. A pressure ratio of 3 and chamber pressure of 16 Pa was used for all simulations. At a width of 8 mm, the vapor concentration in the inter-airfoil region is quickly depleted onto the inner surfaces. As the channel width increased, vapor traveled further along the channel. At a width of 16 mm, some vapor streamlines traveled through the entire channel without depositing on the substrate surface.

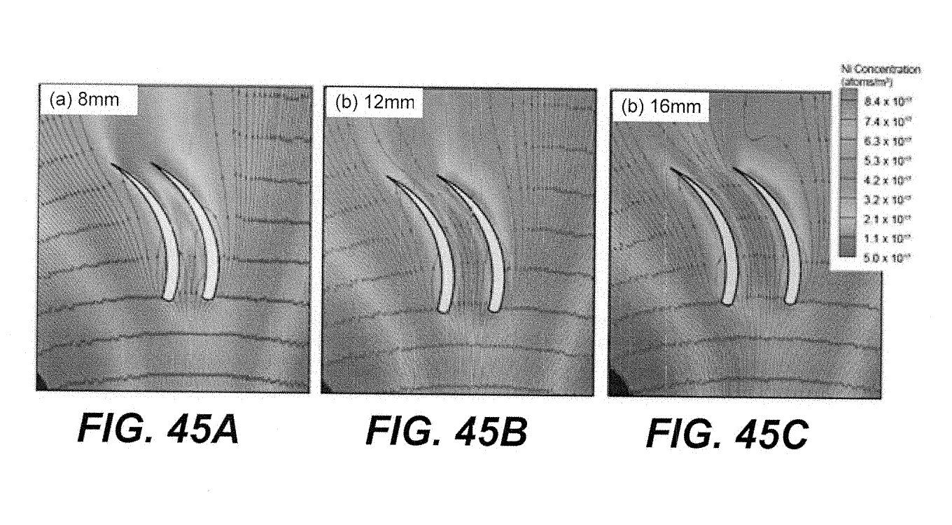

FIGS. 43A-43I indicated that greater vapor penetration into the channel occurs at increased chamber pressures and pressure ratios. FIGS. 45A-45C show the variation of vapor concentration contours and streamlines with channel width at a pressure ratio of 5 and chamber pressure of 45 Pa. At a channel width of 8 mm, vapor penetration is significantly improved over the 16 Pa conditions used in FIGS. 44A-44C. As in FIGS. 44A-44C, as channel width increased vapor propagated further down the channel. At the 16 mm channel width, a large fraction of the vapor in the inter-airfoil region travels through the channel without depositing.

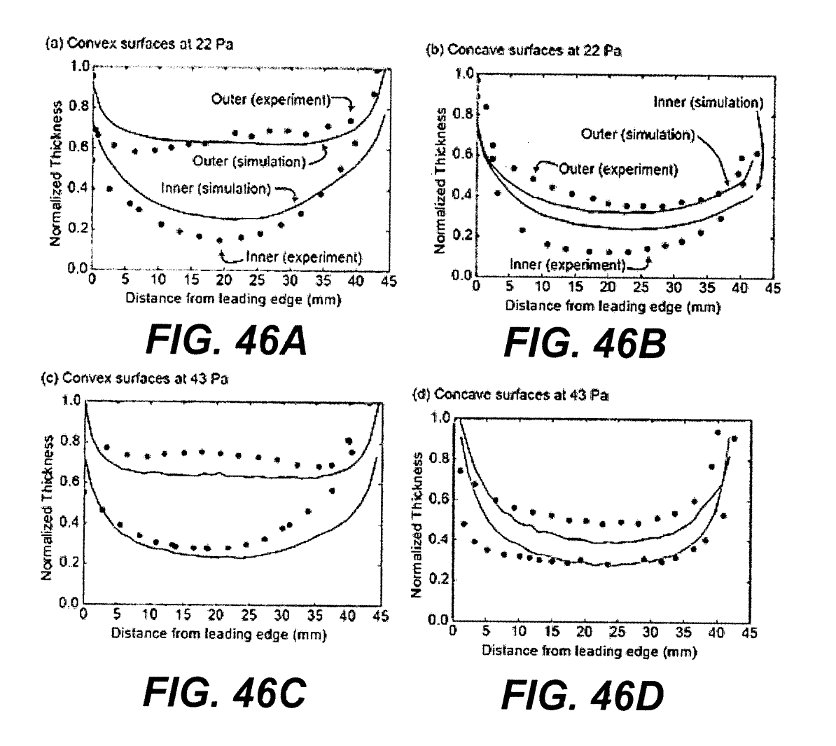

Experimental and DSMC simulation results can be compared by normalizing the experimental thickness and simulated deposition flux profiles by a thickness at the leading edge. All values along the surfaces were normalized by the maximum thickness value at the outer convex surface's trailing edge (found at the upper right corner of FIGS. 46A and 46C. The normalized profiles on the four coated surfaces for a deposition performed at a chamber pressure of 22 Pa with a 5.45 pressure ratio and doublet separation distance of 16 mm are shown in FIGS. 46A and 46B, while normalized profiles simulated and measured at a chamber pressure of 43 Pa and pressure ratio of 4.5 are shown in FIGS. 46C and 46D. The experimental and simulated profiles are in reasonable agreement, including the shape differences between the inner surfaces mentioned above.

Each surface has a thickness—position profile with a minimum value near the surface's midpoint and a maximum value at either the trailing or leading edge of the airfoil. The profiles on the exterior substrate surfaces have a higher average deposition efficiency and are more uniform than those along the interior surfaces. Deposition on these external surfaces is dominated by line-of-sight deposition. The coating thickness profiles on these surfaces are similar to those deposited on rotated single airfoils; especially when the channel width was small. Along the interior surfaces, the profiles have similar shapes but with much larger variation between minimum and maximum values. The inner concave surface has a maximum near the leading edge, while the inner convex surface has a maximum near the trailing edge. These two surface regions experiences an spent a significant fraction of a rotation period within line-of-sight of the vapor source. The minimum deposition efficiencies along the interior concave and convex surfaces occur in NLS regions where diffusion is the dominant deposition mechanism.

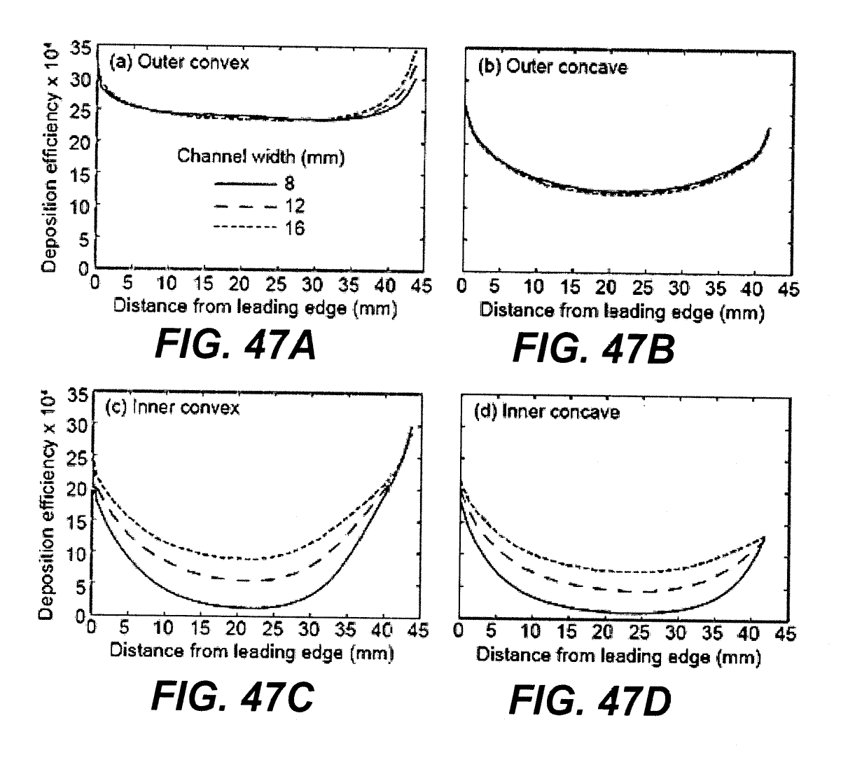

The three (3) variables that most affected deposition uniformity were the channel width, pressure ratio, and chamber pressure. A local vapor deposition efficiency can be defined as the ratio of the number of vapor atoms condensed upon a 1.06 mm (along the concave surfaces) or 1.14 mm (on the convex surfaces) wide segment of an airfoil surface to the number of atoms emitted by the source. The variation of this local efficiency with position along each doublet substrate surface for three channel width substrates is shown in FIGS. 47A-47D for deposition into a chamber at a pressure of 16 Pa using a pressure ratio of 5.0. The profiles along the outer surfaces, FIGS. 47A and 47B, varied little as the channel width was changed, and were quite similar to those along a single airfoil, until the substrate width exceeded that of the impinging vapor plume. Along the inner substrate surfaces, FIGS. 47C and 47D, the deposition efficiency profiles are more significantly affected by channel width. The lowest deposition efficiency on each inner surface was located near the midpoint of the surface. This local deposition efficiency minimum exhibited a nearly tenfold increase as the airfoil separation width was increased from 8 to 16 mm, while the maximum deposition efficiencies on the inner surfaces (near the surface endpoints) remained similar for all channel widths.

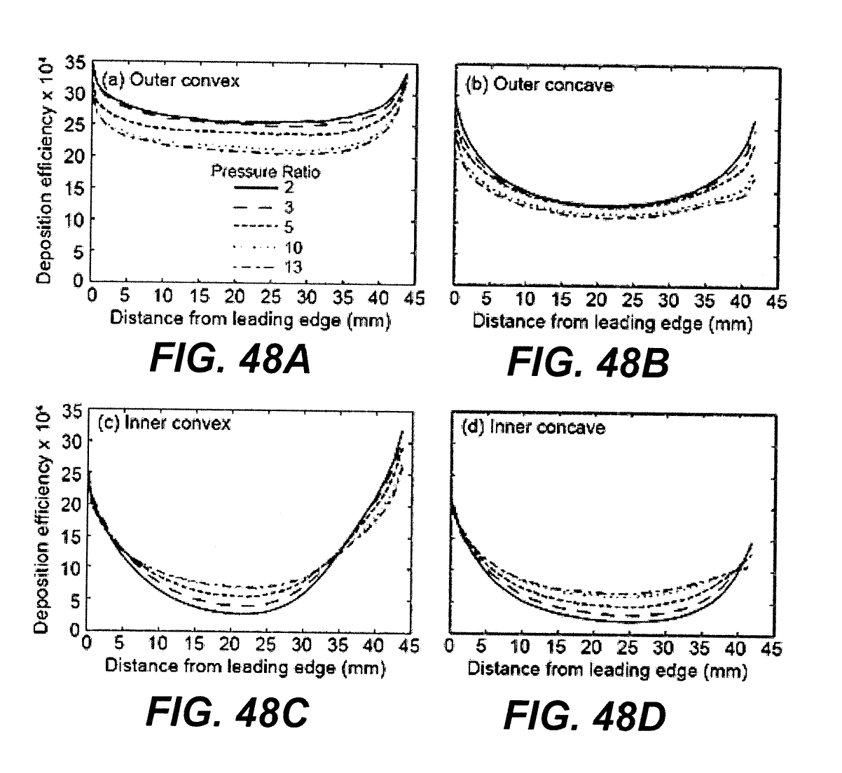

The effects of varying the upstream/downstream pressure ratio upon the local deposition efficiency along both the inner and outer surfaces of a doublet substrate with a fixed 12 mm channel width and chamber pressure of 16 Pa are shown in FIG. 12. Along the exterior surfaces, FIGS. 48A-48D, the fraction of vapor that condensed upon the surfaces decreased with increasing pressure ratio. However, along the inner surfaces, FIGS. 48C and 48D, the fraction of vapor that condensed near the surface midpoint increased with increase in pressure ratio. Increasing the pressure ratio increased the jet velocity, Equation 1, enabled deeper penetration of the vapor plume into the channel, while simultaneously increasing the fraction of vapor that flowed past the external doublet surfaces without condensing.

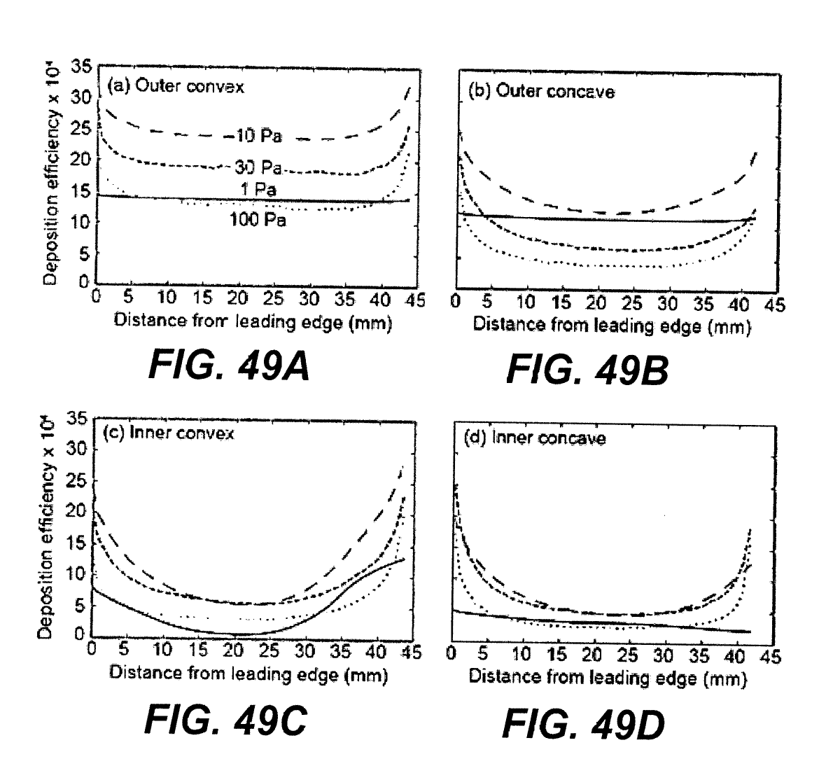

The effect of chamber pressure upon the local deposition efficiency is shown in FIGS. 49A-49D for a fixed channel width of 12 mm and pressure ratio of 5.0. The chamber pressure controls the rate of diffusion of the vapor atoms in the gas flow, and has a large effect on both the magnitude and shape of the local deposition efficiency profile on all of the surfaces. FIGS. 49A-49D show that the most uniform deposition profiles on all surfaces occur at the lowest chamber pressure of 1 Pa. However, the deposition efficiency along the inner surface was extremely small compared to that on the external surfaces, and virtually no vapor was deposited near the midpoint of the inner convex surface, FIG. 49C. Increasing the chamber pressure to 10 Pa increased deposition efficiency on all surfaces. As the pressure was further increased towards 30 Pa, the exterior surface deposition efficiency decreased, but the inner surface minimum efficiency remained unchanged. Increasing the pressure to 100 Pa greatly reduced the surface deposition efficiency on all surfaces. The average vapor deposition efficiency is much lower than the other profiles along the outer concave surface, and is quite similar to the 1 Pa results along the other surfaces. It is noted that this high pressure simulation neglects gas-phase cluster formation, which can be a significant factor as the chamber pressure rises.

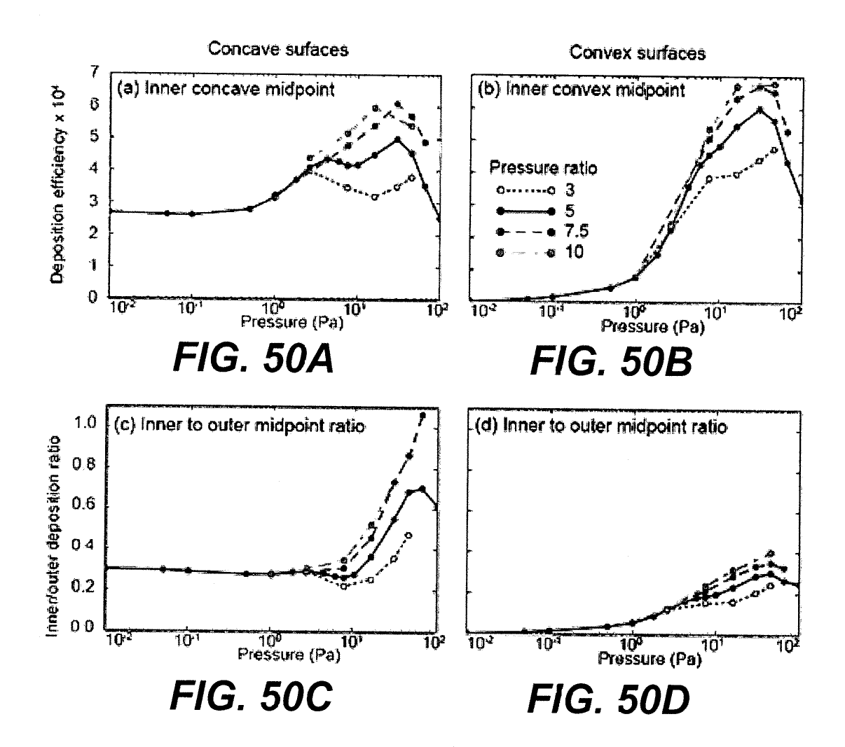

To more comprehensively investigate the effect of both chamber pressure and pressure ratio upon a coating's thickness uniformity, the local deposition efficiency has been determined midway along the two the inner and outer surfaces of the doublet substrate. The midpoint deposition efficiency was calculated by dividing the number of simulated vapor atoms that deposit in the 1.06 mm wide midpoint surface region by the total number of atoms evaporated from the source. This is shown as a function of chamber pressure (from 0.01 to 100 Pa) in FIGS. 50A and 50B for the inner concave and inner convex surfaces for pressure ratios of 3 to 10 a channel width of 12 mm.

The midpoint deposition efficiency on the inner concave surface, FIG. 50A, varied between 0.025% and 0.06% of the total evaporated vapor per each 1.06 mm-wide region. At the lowest PVD-like chamber pressure (0.01 Pa), 0.027% of the total evaporated vapor was condensed upon the 1.06 mm-wide midpoint surface region. This efficiency improved with increasing chamber pressure, reaching a maximum at a chamber pressure of 40 Pa before decreasing rapidly with further increase in pressure. The deposition efficiency also increased with increases in the pressure ratio for pressures near that where the peak in deposition efficiency occurred.

The variation of the midpoint deposition efficiency on the inner convex surface exhibited a much larger variation, FIG. 50B. This surface region was only very briefly in the line of sight of the vapor source during rotation (near □=180°). At the lowest pressure, the midpoint deposition efficiency was very close to zero, with almost no atoms reaching this surface region. The deposition efficiency then increased, at first slowly with chamber pressure before rapidly increasing between a pressure of 1 and 10 Pa. The deposition efficiency reached a maximum at ˜40 Pa, before rapidly decreasing at higher pressures. Near the pressure of maximum efficiency, the midpoint deposition efficiency increased with pressure ratio and exceeded that on the inner concave surface.

Ideally, the ratio of surface midpoint deposition efficiency for the inner and outer convex (and concave) surfaces should also be as close to unity as possible to achieve uniformity of thickness. These ratios are shown in FIGS. 50C and 50D for the concave and two convex surfaces. The figures show that this ratio is also highly sensitive to deposition conditions. On the concave surfaces, deposition efficiency is largely constant until a chamber pressure of ˜7 Pa is reached. Above this pressure, the ratio rapidly increases due to a much faster increase in deposition efficiency on the inner surface than on the exterior. The deposition efficiency ratio also shows a strong sensitivity to pressure ratio. However, on the convex surfaces, the deposition efficiency ratio is much less sensitive to deposition conditions (to chamber pressure or pressure ratio). The deposition efficiency ratio increases very slowly until a pressure of ˜1 Pa is reached. It then increases slowly before declining as the highest chamber pressures were approached. The slow increase is due to an increase in efficiency along both the inner and external surfaces with pressure.

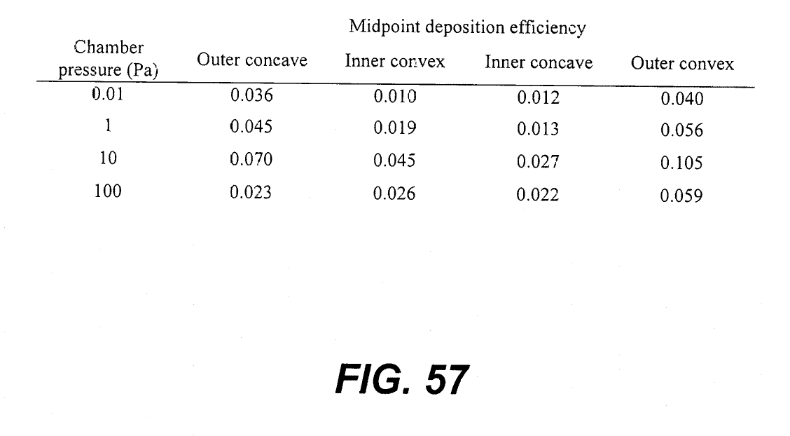

The midpoint deposition efficiencies along the four surfaces is shown for several chamber pressures in FIG. 57 for a pressure ratio of 5 and channel width of 12 mm. The table shows a similar trend to the midpoint deposition efficiencies in FIGS. 50A-50D. For this set of conditions, the highest deposition efficiency was achieved at a pressure of 10 Pa. The results in the table indicate that the continued rise in ratio of midpoint deposition efficiency found in FIGS. 50C and 50D at the highest pressure ratios is a result of a decrease in deposition efficiency on the external surfaces, rather than an increase in efficiency on the inner surfaces.

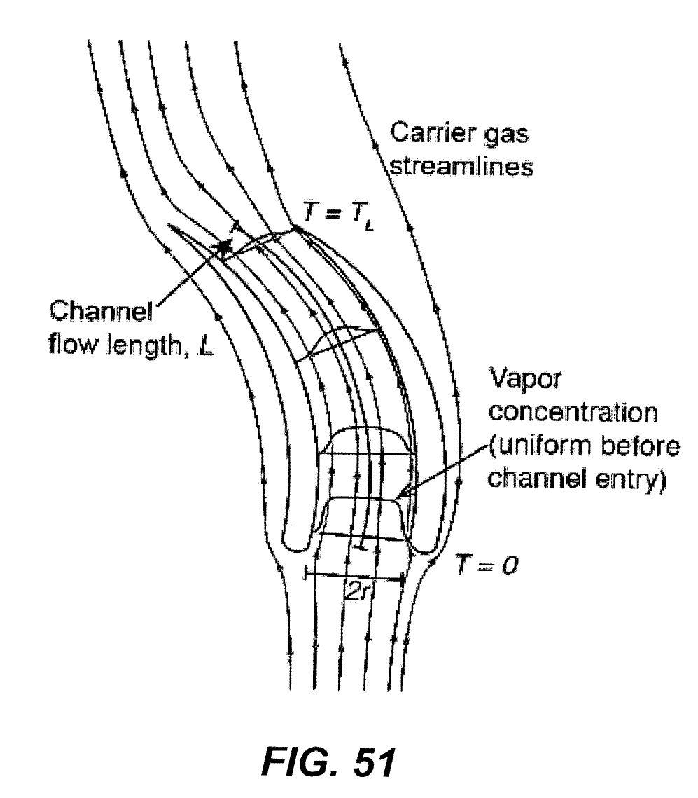

The deposition conditions resulting in best coating uniformity along the inner substrate surfaces occurred when the vapor in the inter-airfoil channel had been fully depleted just as the flow reached the exit of the channel (either the trailing or leading edge, depending on substrate orientation). This situation is schematically illustrated in FIG. 51, where the vapor concentration profile between the two interior channel surfaces are shown. The vapor is first depleted by gas phase scattering induced condensation from the streamlines nearest to the substrate surfaces. This created a concentration gradient across the channel width. As the flow progressed through the channel, multiple gas phase scattering events enabled transverse diffusion of the vapor into the vapor-depleted region, and this then condensed upon the interior surfaces further along the interior surface.

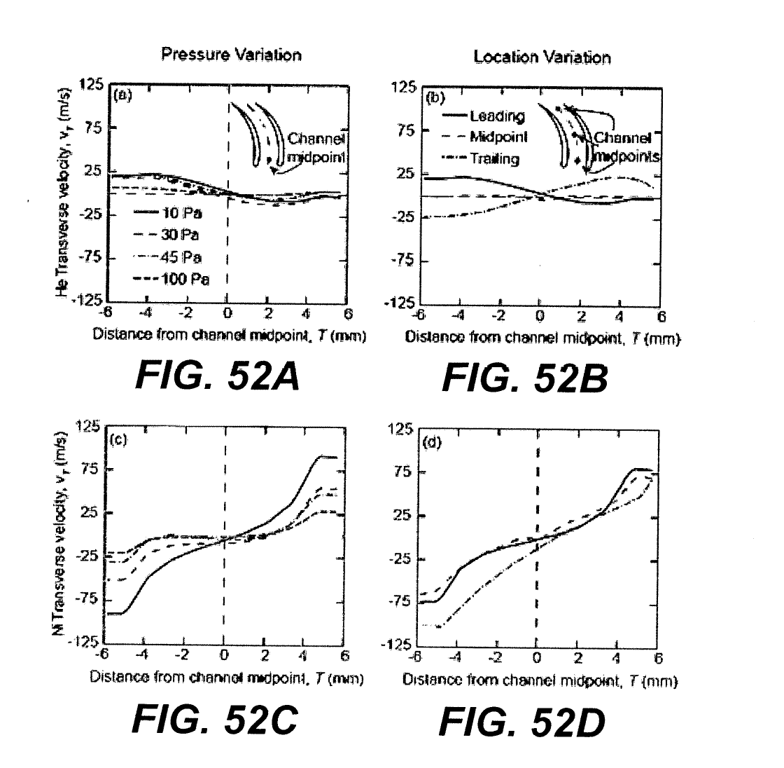

Deposition onto the interior surfaces is therefore controlled by a balance between vapor atoms that transversely diffuse to the substrate surface and those that are transported with the carrier flow down the channel length. The average vapor atom velocities in these two directions are shown in FIGS. 52A-52D for several chamber pressures (left column) and three locations along the inner channel (right column). The positive transverse direction was defined as being to the right of the channel midline. For all pressures, the vapor atom velocity is significantly higher than carrier gas velocity. The transverse vapor atom velocities increased with decreasing pressure, due to the increase in diffusion coefficient with decreasing pressure.

In a gas turbine, doublet airfoils are often used in the first stationary vane stage after the gas flow exits the combustion chamber. During engine use, the four surfaces of such a doublet experience similar environmental conditions regardless of their location along the interior or exterior surface of each individual airfoil component. If the coating at all points on the surface of a doublet guide vane are subjected to the same thermal boundary condition during operation, and the internal cooling is independent of position, the coating thickness over the entire surface should be as uniform as possible to avoid locally hotter locations. It is clear from the results shown above that is never achieved using a constant rotation rate deposition at any pressure or nozzle pressure ratio investigated. However, a recent study has shown that the thickness on the two sides of a single airfoil could be made more uniform through dynamic manipulation of the substrate rotation rate during each rotational period. It is therefore interesting to ask if an optimized non-uniform rotation rate could be found that minimizes the difference in coating thickness (i.e. deposition efficiency) between the inner and outer convex, and inner and outer concave surfaces of the doublet airfoil substrate.

To allow the substrate dwell time to be varied during a rotation, the simulated vapor deposition efficiencies at the eight stationary orientations were assigned a variable weight coefficient. The total deposition efficiency, j on each simulated surface region was then calculated as;

j=Σₘ₌₁⁸aₘfₘ, (15)

where fₘ is the deposition efficiency at each of the eight (8) orientation angles of the substrate, and aₘ is the orientation dwell time coefficient to be determined. The total deposition efficiency difference between each convex or concave pair of inner and outer airfoil surfaces is then expressed by summing the local efficiencies at the 40 measurement locations along each airfoil surface pair;

ΔJ=Σₙ₌₁⁴⁰ |j_{outer,m}−j_{inner,m}|, (16)

where j_{inner,n} and j_{outer,n} are the total deposition efficiency at each of the n substrate regions along the concave and convex surfaces(n=1-40 surface regions). The summation began at the convex and concave surface origins (near the leading edge) and proceeded along each surface towards the trailing edge (increasing n). The coefficients were constrained so that each deposition had maximum allowable dwell coefficient that was eight times larger than the minimum. Finally, the total deposition efficiency differences between each pair of inner/outer surfaces were summed to create the objective function;

ΔJₜₒₜ=wₓΔJ_{convex}+wᵥΔJ_{concave}, (17)

where ΔJ_{convex} is the total deposition efficiency difference between the inner and outer convex surfaces, ΔJ_{concave} is the total deposition efficiency difference between the inner and outer concave surfaces, and wₓ and wᵥ are weighting coefficients for the deposition efficiency difference for each surface pair. For the optimizations performed here, both wₓ and wᵥ were set to 1.0.

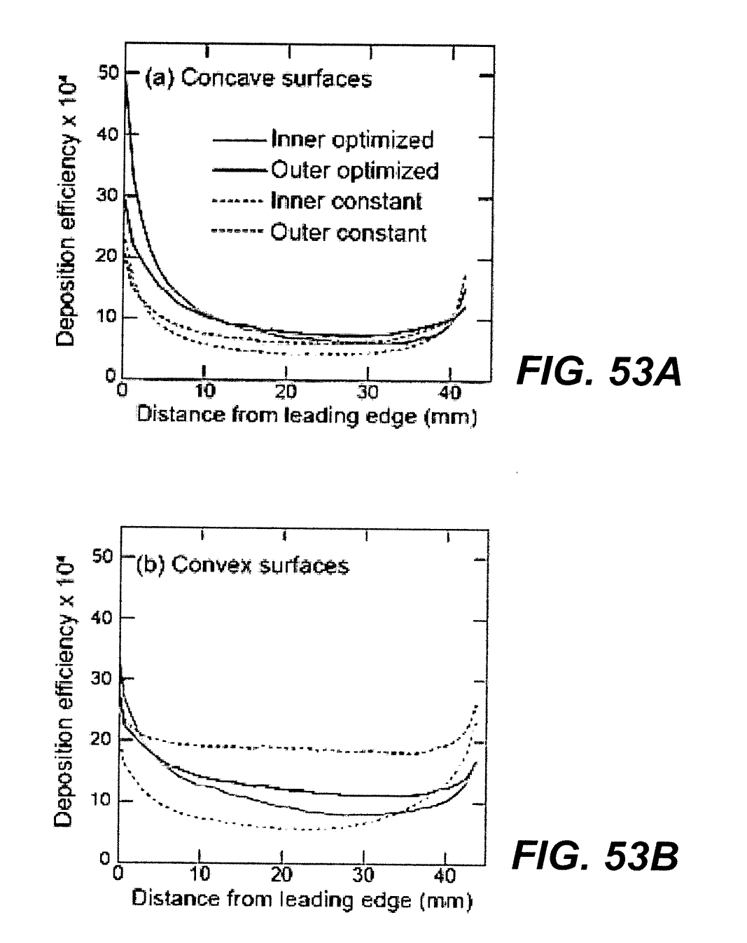

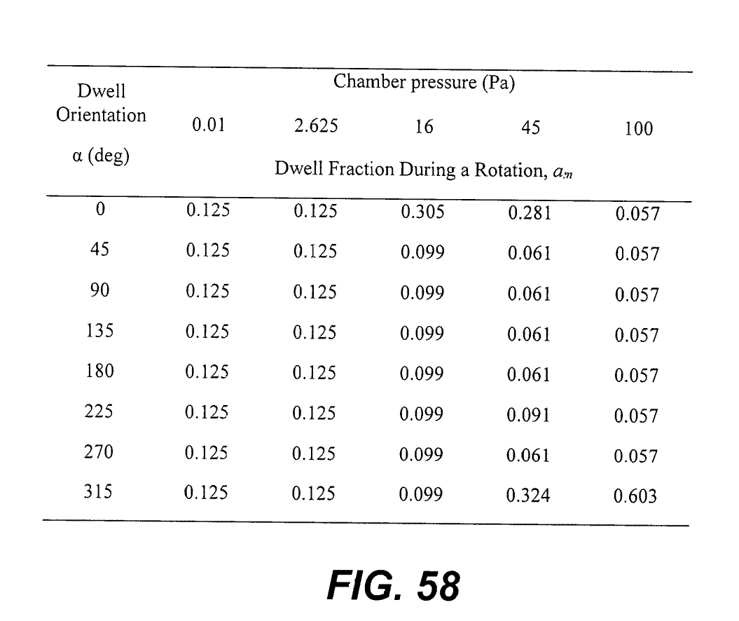

The resulting deposition efficiency profiles using the optimized rotation for a coating deposited at a chamber pressure of 45 Pa, a pressure ratio of 5.0, and channel width of 12 mm are shown in FIGS. 53A and 53B and compared with the constant rotation result. The dwell fraction coefficients are given in FIG. 58. The concave surface coating thicknesses, as shown in FIG. 53A obtained using the optimal rotation rate sequence were thicker, and near the middle of the airfoils, more similar in thickness than those for deposition using a constant rate of rotation. However, the deposition efficiency near the leading edge on the concave surface was much higher than the constant rotation case because of the additional time that it remained in proximity to the vapor source, as shown in FIG. 58. The deposition efficiency along the inner and outer convex surfaces is shown in FIG. 53B. Again, the optimized rotation increased the deposition efficiency on the inner surface while decreasing that on the outer surface. These variations combined to improve the deposition uniformity everywhere on the two surfaces. By comparing the optimized thickness profiles in FIGS. 53A and 53B it is clear that the optimized process resulted in similar thickness coatings on all four surfaces with the exception of the leading edge of the inner concave surface, FIG. 53A.

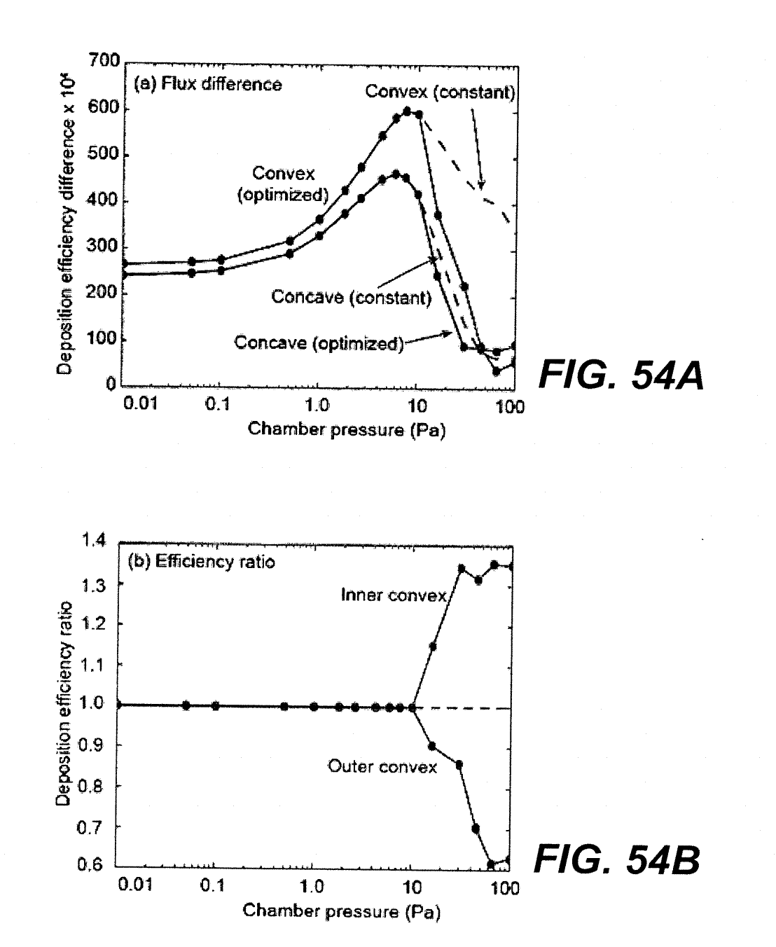

The difference in thickness of coating deposited upon either the inner and outer concave or inner and outer convex surfaces can be obtained using Equation (2) applied to data such as that shown in FIGS. 53A and 53B. As an example, FIG. 54A shows this difference in deposition efficiencies (integrated along the airfoil surface length) for concave and concave surfaces whose coatings were deposited at various chamber pressures using either a constant or optimized rate of rotation. Below a chamber pressure of 10 Pa, the constant rate and optimized rotation depositions resulted in identical differences in deposition efficiency between the inner and outer surface pairs. This can be seen clearly in FIG. 54B where the ratio of optimized to constant rotation rate deposition efficiencies (again integrated over the length of the airfoil surface) for the inner and outer convex surface pair is unity below a chamber pressure of 10 Pa (i.e. the total deposition efficiency along each of the airfoil surfaces obtained using constant rotation was the same as that using the optimization approach). The results in FIG. 54A also show that the difference in coating thickness between the inner and outer surface pairs increased as the chamber pressure rose towards 10 Pa, and this could not be corrected by the optimization scheme. However, when the chamber pressure was increased above 10 Pa, difference in integrated deposition efficiency between the inner and outer airfoil pairs, FIG. 54A, began to rapidly decrease towards zero. The decrease in thickness difference between the inner and outer surfaces also decreased more rapidly with increasing pressure when the optimized rotation scheme was used. The optimization procedure also resulted in a larger reduction in the deposition efficiency difference for the convex surfaces. During constant rotation, the outer convex surface had the highest deposition efficiency, while the inner convex surface had the lowest. Optimizing the rotation sequence greatly reduces this difference, often to a level that was below the difference between the outer and inner concave surfaces. These results indicate that this simple optimization scheme is best applied to deposition processes that operate at higher chamber pressures. It was unable to overcome the consequences of a long (compared to the channel width) vapor atom mean free path encountered with deposition at low pressures.

An undesirable reduction in total deposition efficiency along both the inner and outer surfaces was sometimes encountered with the optimized rotation scheme. In these cases, the efficiency difference was minimized by a reduction of the deposition efficiency on both surfaces. FIG. 54B shows the ratio of optimized to constant rotation deposition efficiencies integrated along the inner and outer convex surfaces. A ratio less than unity indicates that the optimization procedure reduced the amount of vapor deposited during deposition. It can be seen that the improved coating uniformity in FIG. 54A for the convex surfaces was actually accomplished by a reduction of the thickness on the outer convex surface when the optimization scheme was used.

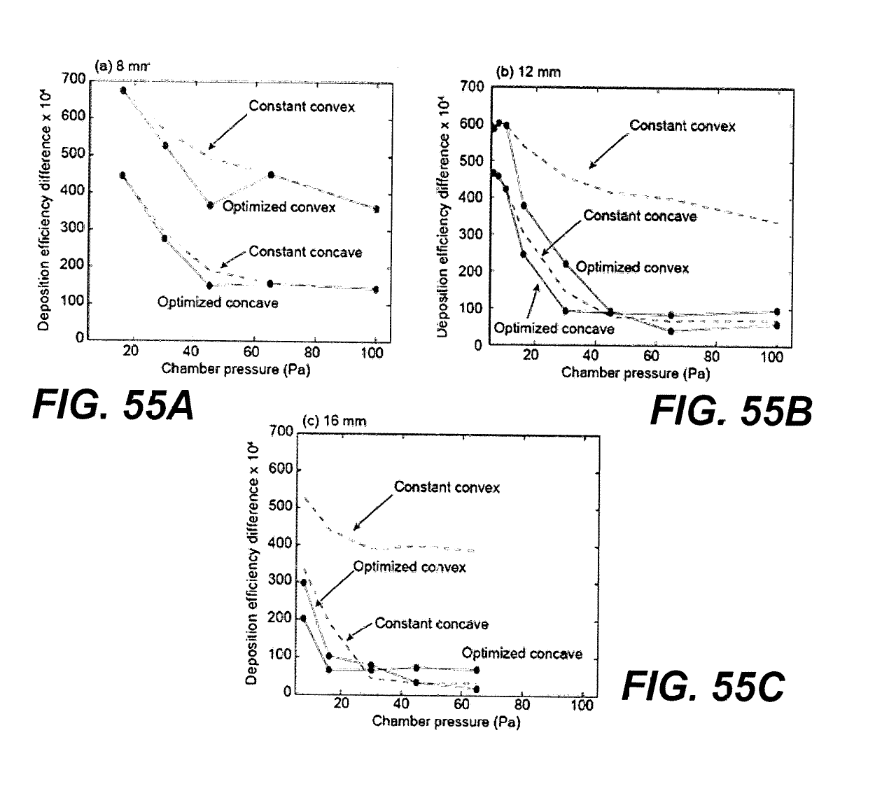

The difference is the thickness of the coatings deposited upon the inner and outer concave and convex surfaces of the airfoils (using either the constant or optimized rotation scheme) varied both with pressure and with the channel width between the airfoil pairs. To illustrate this, simulations using both optimized and constant rotation were conducted for the three doublet airfoil substrates with channel widths of 8, 12 and 16 mm as a function of chamber pressure (between 1 and 100 Pa) using a pressure ratio of 5, as shown in FIGS. 55A-55C. It can be seen that in all cases the difference in thickness decreased with chamber pressure, and the optimized depositions usually exhibit smaller differences in thicknesses than constant rotation counterparts. The most significant reductions (by up to a factor of 4) occurred for the convex surfaces. Improvements through use of the optimization scheme were substantially reduced on the concave surfaces. It is also evident that as the channel gap decreased to 8 mm, the utility of the optimization scheme decreased. For a channel width of 8 mm it can be seen that the optimization scheme advantage over constant rate deposition was only significant at chamber pressures between 30 and 50 Pa. During all these optimizations, wₓ and wᵥ were both set to 1.0. Tests using other values of wₓ and wᵥ could result in improved uniformity for one pair of surfaces, but this was incurred at the expense of decreased uniformity for the other.

The optimized dwell fractions calculated for several representative chamber pressures are shown in FIG. 58. At all pressures, the optimization process led to increases of the dwell time fraction at orientations where the substrate's channel was at least partially aligned with the incident vapor jet (0, 45, 225, and 315°). The dwell time fraction was correspondingly reduced for the orientations where the axis of the inner channel was predominantly transverse to the gas jet axis. It is also evident that those orientations with the largest dwell time fractions had dwell times that varied the most with changing chamber pressure.

The above optimization method demonstrates an important issue with deposition onto complex substrates: it is difficult (or sometimes impossible) to isolate deposition onto a subset of substrate surfaces. For example, to improve deposition onto the inner convex surface, the substrate must be oriented for vapor to pass between the leading or trailing edges. However, at these orientations there is significant deposition onto other surface regions near the leading or trailing edges. Optimizing coating thickness along comparable surfaces is possible, but may not result in optimum total uniformity. The small Reynolds numbers found at these deposition conditions (Re<10) prevents the manifestation of non-laminar flow patterns that might enable more selective deposition patterns. Finally, while the use of higher chamber pressures enables more confined vapor plumes with better tuned flow patterns, it also promotes the formation of vapor clusters that may be detrimental to the coating process ¹⁰.

The mechanisms controlling deposition in doublet guide vane channels have been studied. The results show that deposition uniformity can be improved by varying the gas velocity, substrate geometry, and chamber pressure. The directed vapor deposition was shown to be capable of depositing a compliant thermal barrier coating around the entire surface of a model doublet guide vane. Coating uniformity can be adjusted by modifying the deposition conditions and was found to trend with the ratio of flow along the channel and transverse diffusion to the channel walls.
1. Substrate rotation was necessary to obtain a continuous coating around a doublet guide vane surface.
2. For a channel width of 12 mm, deposition efficiency on the inner surfaces was greatest near a deposition chamber pressure of 45 Pa and high carrier gas velocities.
3. Deposition efficiency on the inner surfaces decreased dramatically when the channel width between airfoils was similar in magnitude to the gas-phase mean free path.
4. A non-uniform rotation pattern can improve coating thickness uniformity between interior and exterior substrate surfaces.

### REFERENCES (1)

The following patents, applications and publications as listed below and throughout this document are hereby incorporated by reference in their entirety herein.
¹ J. H. Perepezko, Science 326, 1068 (2009).
² H. Zhao, F. Yu, T. D. Bennett, and H. N. G. Wadley, Acta Materialia 54, 5195 (2006).
³ A. G. Evans, D. R. Clarke, and C. G. Levi, J. Eur. Ceram. Soc. 28, 1405 (2008).
⁴ S. Mihm, T. Duda, H. Gruner, G. Thomas, and B. Dzur, J. Therm. Spray Tech. 21, 400 (2012).
⁵ D. R. Clarke, M. Oechsner, and N. P. Padture, MRS Bull. 37, 891 (2012).
⁶ S. Sampath, U. Schulz, M. O. Jarligo, and S. Kuroda, MRS Bull. 37, 903 (2012).
⁷ B. J. Harder and D. Zhu, Advanced Ceramic Coatings and Materials for Extreme Environments: Ceramic Engineering and Science Proceedings, Volume 32 32, (2011).
⁸ K. von Niessen and M. Gindrat, J. Therm. Spray Tech. (2011).
⁹ J. F. Groves, S. H. Jones, T. Globus, L. M. Hsiung, and H. N. G. Wadley, J. Electrochem. Soc. 142, L173 (1995).
¹⁰ D. Hass, A. Slifka, and H. N. G. Wadley, Acta Materialia 49, 973 (2001).
¹¹ R. Darolia, International Materials Reviews 58, 315 (2013).
¹² J. Rosler, M. Baker, and M. Volgmann, Acta Materialia 49, 3659 (2001).
¹³ R. W. Steinbrech, V. Postolenko, J. Mönch, J. Malzbender, and L. Singheiser, Ceramics International 37, 363 (2011).
¹⁴ S. Kumar and A. C. F. Cocks, Journal of the Mechanics and Physics of Solids 60, 723 (2012).
¹⁵ M. R. Begley and H. N. G. Wadley, J. Am. Ceram. Soc. 94, S96 (2011).
¹⁶ M. R. Begley and H. N. G. Wadley, Acta Materialia 60, 2497 (2012).
¹⁷ H. Zhao, M. R. Begley, A. Heuer, R. Sharghi-Moshtaghin, and H. N. G. Wadley, Surf. Coat. Tech. 205, 4355 (2011).
¹⁸ D. Hass, Thermal Barrier Coatings via Directed Vapor Deposition, University of Virginia, 2001.
¹⁹ D. Hass, P. Parrish, and H. N. G. Wadley, J. Vac. Sci. Technol. A 16, 3396 (1998).
²⁰ J. F. Groves and H. N. G. Wadley, Compos. Part B-Eng. 28, 57 (1997).
²¹ R. G. Wellman and J. R. Nicholls, Tribology International 41, 657 (2008).
²² V. Lughi, V. K. Tolpygo, and D. R. Clarke, Materials Science and Engineering: A 368, 212 (2004).
²³ T. M. Rodgers, H. Zhao, and H. N. G. Wadley, J. Vac. Sci. Technol. A (2013).
²⁴ S. Baek and V. Prabhu, Mater. Manuf. Process. 24, 1331 (2009).
²⁵ M. Matsumoto, K. Wada, N. Yamaguchi, and T. Kato, Surf. Coat. Tech. (2008).
²⁶ D. D. Hass, Y. Marciano, and H. N. G. Wadley, Surf. Coat. Tech. 185, 283 (2004).
²⁷ D. T. Queheillalt, D. D. Hass, D. J. Sypeck, and H. N. G. Wadley, Journal of Materials Research 16, 1028 (2001).
²⁸ R. G. Wellman, M. J. Deakin, and J. R. Nicholls, Tribology International 38, 798 (2005).
²⁹ R. G. Wellman and J. R. Nicholls, J. Phys. D Appl. Phys. 40, 293 (2007).
³⁰ J. J. Quan, X. W. Zhou, and H. N. G. Wadley, Surface Science 600, 4537 (2006).
³¹ X. W. Zhou, R. A. Johnson, and H. N. G. Wadley, Acta Materialia (1997).
³² Y. Yang, D. D. Hass, and H. N. G. Wadley, Thin Solid Films 471, 1 (2005).
³³ J. Cho, S. Terry, R. LeSar, and C. Levi, Mat. Sci. Eng. a-Struct 391, 390 (2005).
³⁴ S. Baek and V. Prabhu, Journal of Manufacturing Processes (2009).
³⁵ K. Bobzin, E. Lugscheider, and R. Nickel, Comp. Mater. Sci. (2007).
³⁶ M. Gupta, N. Curry, N. Markocsan, and R. Vaβen, Surf. Coat. Tech. (2012).
³⁷ G. Hu, J. Huang, G. Orkoulas, and P. D. Christofides, Phys. Rev. E 80, 041122 (2009).
³⁸ G. Hu, G. Orkoulas, and P. D. Christofides, Chem. Eng. Sci. 64, 3903 (2009).
³⁹ T. P. Schulze and P. Smereka, Phys. Rev. B 86, 235313 (2012).
⁴⁰ C.-H. Lam, J. Appl. Phys. 108, 064328 (2010).
⁴¹ C. C. Battaile, Comput. Method. Appl. M. 197, 3386 (2008).
⁴² G. A. Bird, Molecular Gas Dynamics and the Direct Simulation of Gas Flows, 2^{nd} ed. (Oxford University Press, Oxford, 1994).
⁴³ A. Venkattraman and A. A. Alexeenko, Vacuum 86, 1748 (2012).
⁴⁴ D. D. Hass, Y. Y. Yang, and H. N. G. Wadley, J. Porous Mater. 17, 27 (2010).
⁴⁵ Y. Yang, X. Zhou, R. Johnson, and H. N. G. Wadley, J. Vac. Sci. Technol. B 20, 622 (2002).
⁴⁶ R. A. Johnson, Phys. Rev. B (1988).
⁴⁷ Y. Yang, The Monte Carlo Simulation of Physical Vapor Deposition, University of Virginia, 2000.
⁴⁸ M. Pelliccione, Evolution of Thin Film Morphology: Modeling and Simulations, 1^{st} ed. (Springer, 2008).
⁴⁹ H. Zhao, C. G. Levi, and H. N. G. Wadley, Surf. Coat. Tech. 1 (2014).
⁵⁰ R. O. Duda and P. E. Hart, Communications of the ACM (1972).
⁵¹ B. Tanto, G. Ten Eyck, and T. M. Lu, J. Appl. Phys. 108, 026107 (2010).
⁵² A. G. Dirks and H. J. Leamy, Thin Solid Films 47, 219 (1977).
⁵³ T. Smy, D. Vick, M. J. Brett, S. Dew, A. Wu, J. Sit, and K. Harris, J. Vac. Sci. Technol. A 18, 2507 (2000).
⁵⁴ K. Robbie and M. J. Brett, J. Vac. Sci. Technol. A 15, 1460 (1997).
⁵⁵ R. N. Tait, T. Smy, and M. J. Brett, Thin Solid Films 226, 196 (1993).
⁵⁶ S. Lichter and J. Chen, Phys. Rev. Lett. 56, 1396 (1986).
⁵⁷ P. Meakin, Physics Reports (1993).
⁵⁸ M. M. Hawkeye and M. J. Brett, J. Vac. Sci. Technol. A (2007).
⁵⁹ D. D. Hass and H. N. G. Wadley, J. Vac. Sci. Technol. A 27, 404 (2009).
⁶⁰ E. Jones, T. Oliphant, and P. Peterson, editors, SciPy: Open Source Scientific Tools for Python (2001).

### REFERENCES (2)

The following patents, applications and publications as listed below and throughout this document are hereby incorporated by reference in their entirety herein.
¹ D. R. Clarke, M. Oechsner, and N. P. Padture, MRS Bull. 37, 891 (2012).
² N. D. Cardwell, N. Sundaram, and K. A. Thole, J. Turbomach. 128, 62 (2006).
³ T. M. Rodgers, H. Zhao, and H. N. G. Wadley, J. Vac. Sci. Technol. A 31, 0651509 (2013).
⁴ T. M. Rodgers, H. Zhao, and H. N. G. Wadley, J. Vac. Sci. Technol. A (n.d.).
⁵ A. Venkattraman and A. A. Alexeenko, J. Vac. Sci. Technol. A 28, 916 (2010).
⁶ D. D. Hass, Y. Y. Yang, and H. N. G. Wadley, J. Porous Mater. 17, 27 (2010).
⁷ S. Rezanka, G. Mauer, and R. Vaβen, J. Therm. Spray Tech. 23, 182 (2013).
⁸ M. Góral, J. Sieniawski, and S. Kotowski, Arch Mater Sci . . . 22 (2012).
⁹ K. von Niessen and M. Gindrat, J. Therm. Spray Tech. 20, 736 (2011).
¹⁰ D. Hass, A. Slifka, and H. N. G. Wadley, Acta Materialia 49, 973 (2001).
¹¹Y. Yang, D. D. Hass, and H. N. G. Wadley, Thin Solid Films 471, 1 (2005).
¹² D. D. Hass and H. N. G. Wadley, J. Vac. Sci. Technol. A 27, 404 (2009).
¹³ R. G. Wellman and J. R. Nicholls, Tribology International 41, 657 (2008).
¹⁴ T. M. Rodgers, H. Zhao, and H. N. G. Wadley, (n.d.).
¹⁵ H. Zhao, C. G. Levi, and H. N. G. Wadley, Surf. Coat. Tech. 1 (2014).
¹⁶ D. Hass, J. F. Groves, and H. N. G. Wadley, Surf. Coat. Tech. 146, 85 (2001).
¹⁷ H. Zhao, F. Yu, T. D. Bennett, and H. N. G. Wadley, Acta Materialia 54, 5195 (2006).
¹⁸ D. D. Hass, Y. Marciano, and H. N. G. Wadley, Surf. Coat. Tech. 185, 283 (2004).
   The following patents, applications and publications as listed below and throughout this document are hereby incorporated by reference in their entirety herein.

### REFERENCES (3)

¹ R. Darolia, Int. Mater. Rev. 58, 315 (2013).
² S. Sampath, U. Schulz, M. O. Jarligo, and S. Kuroda, MRS Bull. 37, 903 (2012).
³ H. Zhao, F. Yu, T. D. Bennett, and H. N. G. Wadley, Acta Materialia 54, 5195 (2006).
⁴ C. Levi, Curr. Opin. Solid St. M. 8, 77 (2004).
⁵ H. Zhao, C. G. Levi, and H. N. G. Wadley, Surf. Coat. Tech. 203, 3157 (2009).
⁶ C. G. Levi, J. W. Hutchinson, M.-H. Vidal-Sétif, and C. A. Johnson, MRS Bull. 37, 932 (2012).
⁷ G. S. Fox-Rabinovich, K. Yamamoto, B. D Beake, I. S Gershman, A. I Kovalev, S. C Veldhuis, M. H Aguirre, G. Dosbaeva, and J. L Endrino, Sci. Technol. Adv. Mater. 13, 043001 (2012).
⁸ M. Vallet-Regí and E. Ruiz-Hernández, Adv. Mater. n (2011).
⁹ S. M. Best, A. E. Porter, E. S. Thian, and J. Huang, J. Eur. Ceram. Soc. 28, 1319 (2008).
¹⁰ D. D. Hass and H. N. G. Wadley, J. Vac. Sci. Technol. A 27, 404 (2009).
¹¹ C. Viazzi, J. P. Bonino, and F. Ansart, Surf. Coat. Tech. 201, 3889 (2006).
¹² H. Zhao, C. G. Levi, and H. N. G. Wadley, Surf. Coat. Tech. 1 (2014).
¹³ S. M. George, Chem. Rev. 110, 111 (2010).
¹⁴ N. Cheimarios, G. Kokkoris, and A. G. Boudouvis, Chem. Eng. Sci. 65, 5018 (2010).
¹⁵ D. D. Hass, Y. Marciano, and H. N. G. Wadley, Surf. Coat. Tech. 185, 283 (2004).
¹⁶ K. von Niessen and M. Gindrat, J. Therm. Spray Tech. 20, 736 (2011).
¹⁷ H. N. G. Wadley, A. Zhou, R. Johnson, and M. Neurock, Prog. Mater. Sci. 46, 329 (2001).
¹⁸ R. A. Adomaitis, J Process Control 18, 9 (2008).
¹⁹ K. L. Choy, Prog. Mater. Sci. 48, 57 (2002).
²⁰ R. F. Bunshah, J. Vac. Sci. Technol. 11, 814 (1974).
²¹ S. Baek and V. Prabhu, Mater. Manuf. Process. 24, 1331 (2009).
²² E. Reinhold, P. Botzler, and C. Deus, Surf. Coat. Tech. 120, 77 (1999).
²³ S. Cho, I. Fuke, and V. Prabhu, Surface Eng. 21, 279 (2005).
²⁴ J. Webb, B. Casaday, B. Barker, J. P. Bons, A. D. Gledhill, and N. P. Padture, J. Turbomach. 135, 021033 (2013).
²⁵ S. Slater, A. Leeming, and J. Young, Int. J. Multiphas. Flow 29, 721 (2003).
²⁶ S. Chapman and T. G. Cowling, The Mathematical Theory of Non-Uniform Gases, 3rd ed. (Cambridge University Press, 1970).
²⁷ H. O. Pierson, Handbook of Chemical Vapor Deposition: Principles, Technology and Applications, 1st ed. (William Andrew, 1999).
²⁸ B. Mitrovic, A. Gurary, and W. Quinn, J. Cryst. Growth 303, 323 (2007).
²⁹ A. Dollet, Surf. Coat. Tech. 177-178, 245 (2004).
³⁰ D. J. Broer and W. Luijks, Journal of Applied Polymer Science 26, 2415 (1981).
³¹ R. A. Adomaitis, Chemical Vapor Deposition (2011).
³² D. T. Queheillalt, D. D. Hass, D. J. Sypeck, and H. N. G. Wadley, Journal of Materials Research 16, 1028 (2001).
³³ T. M. Rodgers, H. Zhao, and H. N. G. Wadley, J. Vac. Sci. Technol. A 31, 0651509 (2013).
³⁴ T. M. Rodgers, H. Zhao, and H. N. G. Wadley, J. Vac. Sci. Technol. A (n.d.).
³⁵ D. Hass, Thermal Barrier Coatings via Directed Vapor Deposition, University of Virginia, 2001.
³⁶ J. F. Groves and H. N. G. Wadley, Mrs 2000 1 (2000).
³⁷ S.-W. Jin, Directed Vapor Deposition of Lithium Manganese Oxide Films, University of Virginia, 2008.
³⁸ J. F. Groves and H. N. G. Wadley, Compos. Part B-Eng. 28, 57 (1997).
³⁹ T. Bartel, S. Plimpton, and M. A. Gallis, Sandia Report (2001).
⁴⁰ G. A. Bird, Molecular Gas Dynamics and the Direct Simulation of Gas Flows, 2nd ed. (Oxford University Press, Oxford, 1994).
⁴¹ A. Venkattraman and A. A. Alexeenko, J. Vac. Sci. Technol. A 28, 916 (2010).
⁴² J. Fan, I. Boyd, and C. Shelton, J. Vac. Sci. Technol. A 18, 2937 (2000).
⁴³ A. Venkattraman and A. A. Alexeenko, Vacuum 86, 1748 (2012).
⁴⁴ D. Hass, J. F. Groves, and H. N. G. Wadley, Surf. Coat. Tech. 146, 85 (2001).
⁴⁵ J. F. Groves, S. H. Jones, T. Globus, L. M. Hsiung, and H. N. G. Wadley, J. Electrochem. Soc. 142, L173 (1995).
⁴⁶ Y. Yang, D. D. Hass, and H. N. G. Wadley, Thin Solid Films 471, 1 (2005).
⁴⁷ J. Cho, S. Terry, R. LeSar, and C. Levi, Mat. Sci. Eng. a-Struct 391, 390 (2005).

We claim:

1. A method of coating complex shaped substrate such as engine components, comprising
conducting simulations of deposition on rotated substrate yielding multiple variables that subsequently govern a thickness and structure variation across the rotated substrate; and
selecting a thickness of a coating by balancing a thickness of a coating without increasing a risk of delamination using the simulations of deposition.

2. The method according to claim 1, further comprising comparing the simulations of deposition on rotated substrate with depositions performed using an electron beam-physical vapor deposition (EP-DVD) method.

3. The method according to claim 2, wherein simulated and experimental columnar growth angles, φ, are plotted versus position on the substrate.

4. The method according to claim 3, wherein the columnar inclination angle, φ, formed on flat substrates by condensation of a collimated, monoangular flux with an incident angle, θ are fitted by a Tangent rule given by:
2 tan φ=tan(θ). (4)
wherein using the IAD peak angle, θₘ for θ, the Tangent rule prediction is plotted to predict that growth columns.

5. The method according to claim 1, further comprising controlling the deposition to locally control the thickness and microstructure of the coating deposited on the substrate.

6. The method according to claim 5, wherein the deposition is controlled by modifying an evaporation rate, controlling a dwell time at each substrate orientation, or controlling a standoff distance.

7. The method according to claim 6, wherein the evaporation rate is controlled by modulating an electron beam power.

8. The method according to claim 6, wherein the dwell time is controlled to provide a variable rotation rate.

9. The method according to claim 6, wherein the standoff distance is controlled by eccentric substrate rotation.

10. The method according to claim 6, wherein the deposition is controlled by rapidly varying parameters of a jet flow, including pressure ratio or gas composition.

11. The method according to claim 6, wherein the dwell time at specific angles of substrate rotation are varied for eliminating a difference in coating thickness between concave and convex surfaces of an airfoil substrate, and
wherein simulated incident vapor fluxes at eight stationary orientations are used to simulate a rotation and each assigned a variable weight coefficient, a total flux incident on each surface region, j, is then given by:
j=Σₘ₌₁⁸aₘfₘ, (5)
where fₘ is an incident flux at each orientation, and aₘ is the orientation coefficient to be determined, and a minimize function in a Scipy Python suite is then used to determine the aₘ resulting in a minimum total flux difference between the two airfoil surfaces expressed by:
ΔJ=Σₙ₌₁⁴⁰ |j_{1,n}−j_{2,n}|, (6)
where j_{1,n} and j_{2,n} is the total flux at each of the n substrate regions along the concave and convex surfaces, and a summation begins at the convex and concave surface origins and proceeds along each surface towards the trailing edge (increasing n).

12. The method according to claim 11, wherein the coefficients are constrained so that each deposition has a maximum/minimum rotation rate ratio of 8 so that a maximum allowable dwell coefficient has eight times larger than a minimum dwell coefficient.

13. The method according to claim 12, further comprising optimizing a local coating by varying the dwell time at specific angles of airfoil rotation for eliminating the difference in coating thickness between the concave and convex surfaces of the airfoil substrate,
wherein simulated incident vapor fluxes at eight stationary orientations are used to simulate a rotation were each assigned a variable weight coefficient, a total flux incident on each surface region, j, was then given by:
j=Σₘ₌₁⁸aₘfₘ, (5)
where fₘ is an incident flux at each orientation, and aₘ is an orientation coefficient to be determined; and
wherein a minimize function in a Scipy Python suite is then used to determine the aₘ resulting in a minimum total flux difference between the two airfoil surfaces expressed by:
ΔJ=Σₙ₌₁⁴⁰ |j_{1,n}−j_{2,n}|, (6)
where j_{1,n} and j_{2,n} are the total flux at each of the n substrate regions along the concave and convex surfaces.

14. The method according to claim 13, wherein a summation begins at convex and concave surface origins near a leading edge, and proceeds along each surface towards a trailing edge of increasing n, and wherein coefficients are constrained so that each deposition had a maximum/minimum rotation rate ratio of 8 so that the maximum allowable dwell coefficient is eight times larger than the minimum dwell coefficient.

15. The method according to claim 1, wherein the multiple variables include a local deposition rate and an incident angle distribution (IAD) of vapor atoms,
wherein the deposition rate influences a number of diffusional jumps possible between vapor atom arrivals, and
wherein the incident angel distribution (IAD) specifies a likelihood that an incident vapor atom impacts a substrate at a specific incidence angle, θ, measured from a local surface normal.

16. The method according to claim 1, wherein the simulations of deposition on the rotated substrate is performed by sequentially combining date from a set of stationary direct simulation Monte Carlo (DSMC) simulations with substrate orientation specified by an angle α.

17. The method according to claim 16, wherein the DSMC simulations are each separated by 45° of rotation, used as input for each rotated kinetic Monte Carlo (kMC) simulation.

18. The method according to claim 17, wherein kMC deposition rate was determined by assuming a maximum deposition rate of Dₘₐₓ=4.3 μm/min at a surface region with a highest deposition flux as calculated by DSMC, and a deposition rate, D at each surface region along the remainder of the substrate is determined by normalizing the DSMC calculated fluxes by the maximum value:
D=Dₘₐₓ(f/fₘₐₓ) (2)
where f is the DSMC determined vapor flux at a surface region and fₘₐₓ is the maximum vapor flux at each orientation, and when rotated deposition is simulated, D is calculated at each orientation, and the total number of atoms deposited in each simulation region, N, was also scaled by the total DSMC flux:
N=Nₘₐₓ(f/fₘₐₓ) (3)
where Nₘₐₓ=9,000,000. During rotated deposition, f and fₘₐₓ were determined by summation of DSMC fluxes from all orientations.

19. The method according to claim 1, including simulating a vapor deposition of the coating to permit prediction of a thickness and microstructure of a coating grown at realistic deposition rates, angle of atom impacts, and substrate temperatures.

20. The method according to claim 1, wherein the simulation is conducted by a kinetic Monte Carlo (kMC) method.

21. The method according to claim 1, wherein the simulation is conducted by a direct simulation Monte Carlo (DSMC) method.

22. The method according to claim 21, wherein a relationship between deposition rate and surface diffusion is determined by linking a sum of all single atom diffusional jump probabilities with a vapor atom arrival rate obtained from the DSMC simulation.

23. The method according to claim 22, wherein a probability of a diffusional jump occurring is determined by a jump attempt frequency, activation energy of the jump, and temperature.

24. The method according to claim 23, wherein for a jump over a barrier with activation energy Eᵢ, a successful probability is given by:
Pᵢ=vₒe^{-E}^{_{i/kT}} (1)
where vₒ is the effective vibrational frequency of atoms in the solid (fixed at 5×10¹² s⁻¹), Eᵢ is the activation barrier for the specific jump/in Ev, k is Boltzmann's constant in Ev/K, and T is the absolute temperature in kelvin.
wherein the simulation advances by adding (ΣPᵢ)⁻¹ to a simulation time after each jump is performed, and when the elapsed simulation time is greater than a time interval between vapor atom arrivals, which is an inverse of the deposition rate, an additional vapor atom is added to the simulation and the cycle repeats until a desired number of atoms have been deposited.

25. The method according to claim 24, wherein during a simulation each occupied lattice site can possess several activation energies and jump probabilities corresponding to different, atomic configuration dependent, diffusional pathways, all possible pathways for a given lattice configuration are stored in memory, a Monte Carlo algorithm is used to select a specific jump, and energy barrier values are stored in a binary tree to minimize computational effort when selecting a jump and updating a grid afterwards.

26. The method according to claim 25, wherein convex surfaces or concave surfaces of an airfoil are divided into multiple independent kinetic Monte Carlo (kMC) simulation regions to allow for microstructure simulation along an entire substrate surface.

26. The method according to claim 26, wherein the multiple independent kinetic Monte Carlo (kMC) simulations regions is forty (40) independent kinetic Monte Carlo (kMC) simulations regions.

27. The method according to claim 26, wherein the multiple independent kinetic Monte Carlo (kMC) simulations regions are spaced apart by a predetermined distance.

28. The method according to claim 27, wherein the multiple independent kinetic Monte Carlo (kMC) simulations regions are spaced apart by a predetermined distance.

29. The method according to claim 28, wherein the predetermined distance is 1.13 mm along the convex surfaces and 1.07 mm along the concave surfaces.

30. The method according to claim 29, wherein the multiple independent kinetic Monte Carlo (kMC) simulation regions correspond to substrate surface elements used in input DSMC simulations.

31. The method according to claim 31, wherein each kMC simulation region is assigned a width of 4,000 virtual lattice sites of about 1 μm wide.

32. The method according to claim 32, wherein an initial substrate roughness is used for the simulations.

33. The method according to claim 32, wherein the roughness consists of flat-topped pyramidal asperities with a base width of 100 atoms, a height of 75 atoms, and a spacing of 256 lattice sites between asperity midpoints. 34 The method according to claim 1, wherein the complex shaped engine components one selected from the group consisting of turbine blades, vanes, and nozzles.
